(19) United States
(12) Patent Application Publication
(10) Pub. No.: US 2025/0280512 A1
(43) Pub. Date: Sep. 4, 2025

(54) STRETCHABLE VAPOR CHAMBER AND METHODS OF USING THE SAME

(71) Applicant: Meta Platforms Technologies, LLC, Menlo Park, CA (US)

(72) Inventors: Omar Awartani, Redmond, WA (US); Arman Boromand, Issaquah, WA (US); Thomas John Farrell Wallin, Redmond, WA (US); Mason Zadan, Pittsburgh, PA (US)

(21) Appl. No.: 19/057,832

(22) Filed: Feb. 19, 2025

Related U.S. Application Data
(60) Provisional application No. 63/559,514, filed on Feb. 29, 2024.

(51) Int. Cl. H05K 7/20; G06F 1/16

(52) U.S. Cl. CPC H05K 7/20336; G06F 1/163

(57) ABSTRACT

A deformable substrate includes first and second sets of layers. The first and second sets of layers encapsulate a channel. Spacers within the channel contact the first and second sets of layers. The channel is bounded by an interior layer of each of the first and second sets of layers that includes a wicking composition, an interior face, and an exterior face. An intermediate layer overlays the exterior face of each of the first and second sets of layers. An exterior layer overlays the intermediate layer of the first set of layers, and an exterior layer overlays the intermediate layer of the second set of layers. The exterior layer of each of the first and second sets of layers includes a first polymeric composition, and the intermediate layer of each of the first and second sets of layers includes a second polymeric composition.

### CROSS-REFERENCE TO RELATED APPLICATION

The present application claims priority to U.S. Provisional Patent Application No. 63/559,514, entitled “Stretchable Vapor Chamber and Methods of Using the Same,” filed Feb. 29, 2024, which is hereby incorporated by reference in its entirety for all purposes.

### FIELD OF THE PRESENT DISCLOSURE

The present Application relates to stretchable vapor chambers enabled by liquid metal based gas barrier films and methods of using or producing the same.

### BACKGROUND

Conventionally, a gas barrier film is utilized to prohibit water vapor and/or oxygen from permeating through the interior of the gas barrier film. Typically, such gas barrier films are formed from inorganic rigid materials, such as aluminium, copper, or various multilayer polymeric films. Yet, even though these rigid gas barrier films provide sufficient impermeability for oxygen and/or water vapor at zero strain, these rigid gas barrier films cannot perform under external deformation, such as axial strain.

For instance, with the continued development of wearable electronic devices for both input and output based functionality, more advanced computational and device lifetimes are needed for continuous and/or prolonged operation. Computational increases through faster processing, more advanced higher pixel-per-inch displays, and the need for multiple peripherals that can function for extended periods of time has led to increases in battery size and processing hardware for such devices. Moreover, these improvements have led to increases in functionality along with power consumption. However, with these improvements, a new host of thermal heat dissipation problems arise from this increased power consumption that needs to be addressed. In particular, heat from such power consumption needs to be dissipated in a manner that still allows for such devices to be comfortably worn on an everyday basis.

In this regard, prior thermal management solutions have failed on two fronts. First, prior thermal management solutions, such as plate fin heat sinks and thermal interface materials (e.g., thermal paste materials) are not suited for wearable applications due to their rigidity and lack of body conformability. Second, computation on the body has more stringent requirements compared with traditional electronic devices. For instance, the distance heat can be transferred away from the body is limited and the device temperature must be kept lower than traditional non-wearable electronics to ensure user comfort. Furthermore, wearable devices, such as frame hinges for digital reality eyewear, require substantial bending to maintain their form and function, thus precluding the use of plate in heat sinks.

### SUMMARY

Based on the above background, there is a need in the art for thermal management systems and gas barrier films that can be used in various wearable computational applications.

The present disclosure addresses the above-identified shortcomings.

In some embodiments, the present disclosure is directed to systems, methods, and devices that provide deformable electrical communication between a first and second circuit components of an electronic device having a deformable substrate. The deformable substrate generates heat. This enables the deformable substrate to provide thermal management by conveying heat and mass through its interior. Accordingly, the present disclosure provides a soft and flexible thermal management solution in the form of the deformable substrate. Moreover, due to the use of one or more polymeric compositions layered in two or more sets of layers, the deformable substrate of the present disclosure has minimal thickness (e.g., between 5 microns and 2,500 microns) while also providing impermeable layers to seal fluid within the deformable substrate, which is useful when incorporated into electronic devices that operate in confined spaces, such as wearable electronic devices.

For instance, in some embodiments, the systems, methods, and devices of the present disclosure provide a deformable substrate, such as a deformable substrate that forms a gas barrier film of a vapor chamber. In some embodiments, the deformable substrate of the present disclosure allows for maintaining electronic communication when the deformable substrate is subjected to strain. Moreover, in some embodiments, the deformable substrate of the present disclosure has minimal thickness (e.g., less than 5 microns) yet provides low water vapor transmission rates and/or oxygen transmission rates for a prolonged period of time (e.g., greater than three years, greater than five years, etc.) in order to act as the gas barrier film for the vapor chamber.

One aspect of the present disclosure provides a deformable substrate. The deformable substrate includes a first set of layers and a second set of layers. Moreover, the deformable substrate includes a channel that is encapsulated by the first set of layers and the second set of layers. The deformable substrate further includes a plurality of spacers within the channel and contacting the first set of layers and the second set of layers, which prevents the shape of the channel from collapsing when deformed. Additionally, the channel is bounded by an interior layer of the first set of layers and an interior layer of the second set of layers, which seals the channel between the first set of layers and the second set of layers. The interior layer of the first set of layers and the interior layer of the second set of layers each includes (i) a wicking composition and (ii) an interior face that faces the channel and an exterior face that opposes the channel, which allows for heat and mass transfer through the channel. Furthermore, a first intermediate layer of the first set of layers overlays the exterior face of the interior layer of the first set of layers, and a first intermediate layer of the second set of layers overlays the exterior face of the interior layer of the second set of layers. An exterior layer of the first set of layers overlays the first intermediate layer of the first set of layers, and an exterior layer of the second set of layers overlays the first intermediate layer of the second set of layers, which adds stretchability to the deformability substrate. Moreover, the exterior layer of the first set of layers and the exterior layer of the second set of layers each includes a first polymeric composition. Additionally, the first intermediate layer of the first set of layers and the first intermediate layer of the second set of layers each includes a second polymeric composition, which allows for the inclusion of metal based materials within the deformable substrate.

In some embodiments, the channel is configured to accommodate a medium. Moreover, the medium is a fluid or a porous solid.

In some embodiments, the medium of the channel includes water.

In some embodiments, the first set of layers and the second set of layers are coplanar with each other.

In some embodiments, the porosity of the wicking composition is between 50% and 99%.

In some embodiments, the first polymeric composition of the exterior layer of the first set of layers and the exterior layer of the second set of layers includes silicon.

In some embodiments, the first polymeric composition includes polydimethylsiloxane silicone (PDMS), polyurethane (PU), thermoplastic polyurethane (TPU), polystyrene-block-polyisoprene-block-polystyrene (SIS), or a combination thereof.

In some embodiments, the interior layer of the first set of layers and the interior layer of the second set of layers includes PDMS, polyvinyl alcohol (PVA), polyethylene glycol (PEG), hydroxyethyl methacrylate (HEMA), one or more polymer mesh weaves, one or more non-woven fiber mats, one or more surface modified hydrophobic polymers, polyolefin, one or more surface modified elastomers, or a combination thereof.

In some embodiments, the interior layer of the first set of layers and the interior layer of the second set of layers includes a contact angle of less than 50 degrees (°) when interfacing with a different composition.

In some embodiments, the interior layer of the first set of layers and the interior layer of the second set of layers covers the medium from the first end portion of the channel to the second end portion of the channel.

In some embodiments, the interior layer of the first set of layers and the interior layer of the second set of layers has a resistance under at most 100 Ohms per cm when the deformable substrate is subjected to 100% strain.

In some embodiments, the interior layer of the first set of layers and the interior layer of the second set of layers maintains conductivity when subjected to at least 15,000 strain cycles.

In some embodiments, the interior layer of the first set of layers and the interior layer of the second set of layers has a resistance under at most 100 Ohms per cm when the deformable substrate is subjected to 100% strain at a first strain cycle, and under at most 100 Ohms per cm when subjected to 100% strain at a second strain cycle.

In some embodiments, the second strain cycle is at least 15,000 strain cycles greater than the first strain cycle.

In some embodiments, the strain is uniaxial or biaxial.

In some embodiments, the first thickness of the deformable substrate is between 8 microns (μm) and 2,500 μm.

In some embodiments, the second thickness of the exterior layer of the first set of layers or the exterior layer of the second set of layers is between 1 μm and 200 μm.

In some embodiments, the third thickness of the first intermediate layer of the first set of layers or the first intermediate layer of the second set of layers is between 1 μm and 2,500 μm.

In some embodiments, the fourth thickness of the interior layer of the first set of layers and the interior layer of the second set of layers is between 1 μm and 500 μm.

In some embodiments, the deformable substrate further includes a second intermediate layer of the first set of layers that overlays an opening of the first intermediate layer of the first set of layers. Moreover, a second intermediate layer of the second set of layers overlays an opening of the first intermediate layer of the second set of layers.

In some embodiments, the second intermediate layer of the first set of layers or the second intermediate layer of the second set of layers includes liquid metal.

In some embodiments, the second intermediate layer of the first set of layers or the second intermediate layer of the second set of layers includes a metal composite polymer.

In some embodiments, the second intermediate layer of the first set of layers or the second intermediate layer of the second set of layers includes gallium.

In some embodiments, the second intermediate layer of the first set of layers or the second intermediate layer of the second set of layers includes gallium indium alloy, gallium tin alloy, gallium indium tin alloy, gallium indium tin zinc alloy, or a combination thereof.

In some embodiments, a fifth thickness of the second intermediate layer of the first set of layers or the second intermediate layer of the second set of layers is between 1 μm and 5 μm.

In some embodiments, the deformable substrate includes a third intermediate layer of the first set of layers disposed interposing between the first intermediate layer of the first set of layers and at least the exterior layer of the first set of layers. Moreover, a third intermediate layer of the second set of layers is disposed interposing between the first intermediate layer of the second set of layers and at least the exterior layer of the second set of layers. Accordingly, the third intermediate layer of the first set of layers or the third intermediate layer of the second set of layers includes a first composition having an affinity for a second composition of the second intermediate layer of the first set of layers or the second intermediate layer of the second set of layers.

In some embodiments, the first composition is metal.

In some embodiments, the first composition includes chromium, chromium alloy, copper, copper alloy, gallium, gallium(III) oxide, gallium indium alloy, gallium tin alloy, gallium indium tin alloy, gallium indium tin zinc alloy, or a combination thereof.

In some embodiments, a sixth thickness of the third intermediate layer of the first set of layers or the third intermediate layer of the second set of layers is between 5 nanometers (nm) and 500 nm.

In some embodiments, a seventh thickness of the channel is between 100 μm and 1,000 μm.

In some embodiments, the third intermediate layer of the first set of layers includes a shell layer that further includes gallium, gallium(III) oxide, gallium indium alloy, gallium tin alloy, gallium indium tin alloy, gallium indium tin zinc alloy, or a combination thereof. Moreover, the third intermediate layer of the first set of layers includes a core layer that further includes chromium, chromium alloy, copper, copper alloy, or a combination thereof. Furthermore, the third intermediate layer of the second set of layers includes a shell layer that further includes gallium, gallium(III) oxide, gallium indium alloy, gallium tin alloy, gallium indium tin alloy, gallium indium tin zinc alloy, or a combination thereof. Moreover, the third intermediate layer of the second set of layers that further includes a core layer that further includes chromium, chromium alloy, copper, copper alloy, or a combination thereof.

In some embodiments, at least one spacer of the plurality of spacers is spherical, substantially spherical, spheroidal, or substantially spheroidal.

In some embodiments, the plurality of spacers includes one or more stents.

In some embodiments, the plurality of spacers includes one or more protrusions.

In some embodiments, an exterior surface of the deformable substrate includes one or more folds, one or more creases, one or more openings, or a combination thereof.

Another aspect of the present disclosure is directed to providing a method for forming a deformable electrical communication between a first and second circuit component. The method includes forming an exterior layer in a first set of layers that includes a first thickness. Moreover, the method includes overlaying a first mask over a first portion of the exterior layer, which forms a first pattern on a first surface of the exterior layer. The method further includes immersing some or all of the first pattern in a solution, which forms a first intermediate layer of the first set of layers on the first surface of the exterior layer in accordance with a shape of the first pattern. Additionally, the method includes further overlaying a second mask over a second portion of the first intermediate layer, which forms a second pattern on a second surface of the first intermediate layer. Furthermore, the method includes applying a first material to some or all of the second pattern, which forms a second intermediate layer of the first set of layers on the second surface of the first intermediate layer in accordance with a shape of the second pattern. The method further includes disposing a third intermediate layer of the first set of layers on a third portion of the second intermediate layer, which forms a third pattern on a third surface of the second intermediate layer. Moreover, the method includes further disposing a plurality of spacers on some or all of the third pattern in order to form a portion of a channel between the first circuit component and the second circuit component for electrical communication between the first circuit component and the second circuit component.

In some embodiments, the applying of the first material includes impinging a plurality of ions of the first material at the second pattern on the second surface of the first intermediate layer.

In some embodiments, the applying of the first material includes forming a coating of the first material over the second pattern on the second surface of the first intermediate layer.

### BRIEF DESCRIPTION OF THE DRAWINGS

FIG. 1 illustrates an exemplary system topology including an electronic device, in accordance with some embodiments of the present disclosure;

FIG. 2 illustrates an exemplary electronic device that includes a deformable substrate, in accordance with some embodiments of the present disclosure;

FIG. 3A illustrates a cross-sectional view taken along line A-A of FIG. 2, in accordance with some embodiments of the present disclosure; and

FIG. 3B illustrates another cross-sectional view taken along line A-A of FIG. 2, in accordance with some embodiments of the present disclosure;

FIG. 4 illustrates a plan view of a set of layers of a deformable substrate of an electronic device, in accordance with some embodiments of the present disclosure;

FIG. 5 illustrates another cross-sectional view of a deformable substrate of an electronic device, in accordance with some embodiments of the present disclosure;

FIG. 6 is a flowchart illustrating a method for forming a deformable electrical communication between a first circuit component and a second circuit component, in accordance with some embodiments of the present disclosure; and

FIG. 7 illustrates various logic functions that are implemented by an electronic device in some embodiments of the present disclosure.

### DETAILED DESCRIPTION OF THE INVENTION

The present disclosure provides systems, methods, and devices for forming a deformable electrical communication between first and second circuit components, such as through a deformable substrate. For instance, in some embodiments, the first circuit component is a condenser and the second circuit component is an evaporator, which allows for the deformable substrate to convey a medium through the deformable subject and have a temperature gradient between portions of the deformable substrate. Accordingly, the deformable substrate includes a first and second set of layers, which collectively encapsulate a channel. Furthermore, a plurality of spacers is disposed within the channel, such that the plurality of spacers contacts both the first set of layers and the second set of layers. As such, by having both the first set of layers and the second set of layers encapsulate the channel with the plurality of spacers therebetween, the deformable substrate of the present disclosure is capable of maintaining the shape the channel while allowing the first set of layers and/or the second set of layers to conform to geometrics with complex (e.g., convex and concave) shapes. In this way, the channel is bounded by an interior layer of the first set of layers and an interior layer of the second set of layers. Each interior layer includes a wicking composition, an interior face, and an exterior face. Accordingly, in some such embodiments, the wicking composition is deformable, which allows the interior layer to convey the medium between the first and second circuit components.

As a non-limiting example, in some embodiments, the interior layer is configured to transport liquid medium and the channel is configured to transport vapor medium. Furthermore, both the first and second set of layers includes an intermediate layer that overlays the exterior face of the interior layer. Moreover, an exterior layer overlays the intermediate layer of the first set of layers, and an exterior layer overlays the intermediate layer of the second set of layers. The exterior layer of each of the first and second sets of layers includes a first polymeric composition. Moreover, the intermediate layer of each of the first and second sets of layers includes a second polymeric composition. Accordingly, the exterior layer and the intermediate layer of each of the first and second set of layers allows for the deformable substrate to provide minimal thermal contact between a heat source (e.g., the first circuit component and/or the second circuit component) and the channel.

Reference will now be made in detail to embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, components, circuits, and networks have not been described in detail so as not to unnecessarily obscure aspects of the embodiments.

Plural instances may be provided for components, operations or structures described herein as a single instance. Finally, boundaries between various components, operations, and data stores are somewhat arbitrary, and particular operations are illustrated in the context of specific illustrative configurations. Other forms of functionality are envisioned and may fall within the scope of the implementation(s). In general, structures and functionality presented as separate components in the example configurations may be implemented as a combined structure or component. Similarly, structures and functionality presented as a single component may be implemented as separate components. These and other variations, modifications, additions, and improvements fall within the scope of the implementation(s).

It will also be understood that, although the terms “first,” “second,” etc. may be used herein to describe various elements, these elements should not be limited by these terms. These terms are only used to distinguish one element from another. For example, a first layer could be termed a second layer, and, similarly, a second layer could be termed a first layer, without departing from the scope of the present disclosure. The first layer and the layer are both layers, but they are not the same layer.

The terminology used herein is for the purpose of describing particular implementations only and is not intended to be limiting of the claims. As used in the description of the implementations and the appended claims, the singular forms “a,” “an,” and “the” are intended to include the plural forms as well, unless the context clearly indicates otherwise. It will also be understood that the term “and/of” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The foregoing description included example systems, methods, techniques, instruction sequences, and computing machine program products that embody illustrative implementations. For purposes of explanation, numerous specific details are set forth in order to provide an understanding of various implementations of the inventive subject matter. It will be evident, however, to those skilled in the art that implementations of the inventive subject matter may be practiced without these specific details. In general, well-known instruction instances, protocols, structures and techniques have not been shown in detail.

The foregoing description, for purpose of explanation, has been described with reference to specific implementations. However, the illustrative discussions below are not intended to be exhaustive or to limit the implementations to the precise forms disclosed. Many modifications and variations are possible in view of the above teachings. The implementations are chosen and described in order to best explain the principles and their practical applications, to thereby enable others skilled in the art to best utilize the implementations and various implementations with various modifications as are suited to the particular use contemplated.

In the interest of clarity, not all of the routine features of the implementations described herein are shown and described. It will be appreciated that, in the development of any such actual implementation, numerous implementation-specific decisions are made in order to achieve the designer's specific goals, such as compliance with use case constraints, and that these specific goals will vary from one implementation to another and from one designer to another. Moreover, it will be appreciated that such a design effort might be complex and time-consuming, but nevertheless be a routine undertaking of engineering for those of ordering skill in the art having the benefit of the present disclosure.

For convenience in explanation and accurate definition in the appended claims, the terms “upper,” “lower,” “up,” “down,” “upwards,” “downwards,” “laterally,” “longitudinally,” “inner,” “outer,” “inside,” “outside,” “inwardly,” “outwardly,” “interior,” “exterior,” “front,” “rear,” “back,” “forwards,” and “backwards” are used to describe features of the exemplary embodiments with reference to the positions of such features as displayed in the figures.

Furthermore, when a reference number is given an “i^{th}” denotation, the reference number refers to a generic component, set, or embodiment. For instance, a circuit component “circuit component i” refers to the i^{th} circuit component in a plurality of circuit components (e.g., a circuit component 200-i in a plurality of circuit components 200).

As used herein, the term “deformable substrate” refers to a substrate or a portion of it (e.g., a layer) capable of altering its shape subject to pressure or stress.

Moreover, as used herein, the term “% porosity” or “percent porosity” porosity means a percent of the total volume of a material includes one or more voids (e.g., interconnected voids) or cavities of the material.

As used herein, the term “about” or “approximately” can mean within an acceptable error range for the particular value as determined by one of ordinary skill in the art, which can depend in part on how the value is measured or determined, e.g., the limitations of the measurement system. For example, “about” can mean within 1 or more than 1 standard deviation, per the practice in the art. “About” can mean a range of ±20%, ±10%, ±5%, or ±1% of a given value. Where particular values are described in the application and claims, unless otherwise stated, the term “about” means within an acceptable error range for the particular value. The term “about” can have the meaning as commonly understood by one of ordinary skill in the art. The term “about” can refer to ±10%. The term “about” can refer to ±5%.

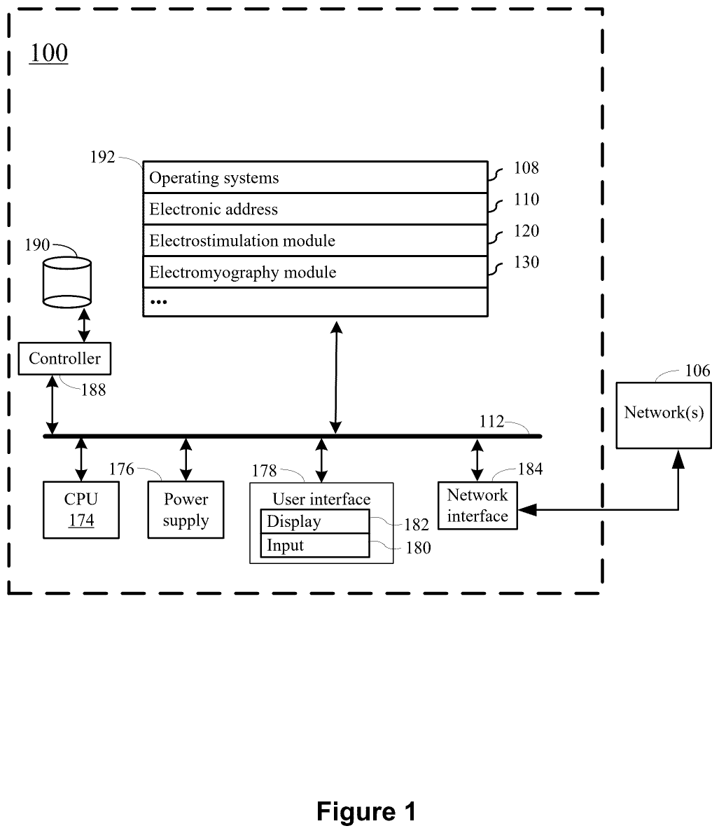

In the present disclosure, unless expressly stated otherwise, descriptions of devices and systems will include implementations of one or more electronic devices. For instance, and for purposes of illustration in FIG. 1, an electronic device 100 is represented as single device that includes all the functionality of the electronic device 100. However, the present disclosure is not limited thereto. For instance, the functionality of the electronic device 100 may be spread across any number of networked computers and/or reside on each of several networked computers and/or by hosted on one or more virtual machines and/or containers at a remote location accessible across a communications network (e.g., networks 106). One skilled in the art of the present disclosure will appreciate that a wide array of different computer topologies is possible for the electronic device 100, and other devices and systems of the preset disclosure, and that all such topologies are within the scope of the present disclosure. As such, the exemplary topology shown in FIG. 1 merely serves to describe the features of an embodiment of the present disclosure in a manner that will be readily understood to one skilled in the art.

In general, the present disclosure provides systems, methods, and devices for producing circuits with deformable substrates, in which the circuits allow for electronic communication between various circuit components of a circuit when the circuit is subjected to a strain.

Referring to FIGS. 1 through 4, a system for forming a deformable electrical communication between a first and second circuit component is provided. More specifically, FIG. 1 depicts a block diagram of an electronic device (e.g., electronic device 100) according to some embodiments of the present disclosure.

In some embodiments, the communication networks 106 optionally includes the Internet, one or more local area networks (LANs), one or more wide area networks (WANs), other types of networks, or a combination of such networks.

Examples of communication networks 106 include the World Wide Web (WWW), an intranet and/or a wireless network, such as a cellular telephone network, a wireless local area network (LAN) and/or a metropolitan area network (MAN), and other devices by wireless communication. The wireless communication optionally uses any of a plurality of communications standards, protocols and technologies, including Global System for Mobile Communications (GSM), Enhanced Data GSM Environment (EDGE), high-speed downlink packet access (HSDPA), high-speed uplink packet access (HSUPA), Evolution, Data-Only (EV-DO), HSPA, HSPA+, Dual-Cell HSPA (DC-HSPDA), long term evolution (LTE), near field communication (NFC), wideband code division multiple access (W-CDMA), code division multiple access (CDMA), time division multiple access (TDMA), Bluetooth, Wireless Fidelity (Wi-Fi) (e.g., IEEE 802.11a, IEEE 802.11ac, IEEE 802.11ax, IEEE 802.11b, IEEE 802.11g and/or IEEE 802.11n), voice over Internet Protocol (VoIP), Wi-MAX, a protocol for e-mail (e.g., Internet message access protocol (IMAP) and/or post office protocol (POP)), instant messaging (e.g., extensible messaging and presence protocol (XMPP), Session Initiation Protocol for Instant Messaging and Presence Leveraging Extensions (SIMPLE), Instant Messaging and Presence Service (IMPS)), and/or Short Message Service (SMS), or any other suitable communication protocol, including communication protocols not yet developed as of the filing date of this document.

In various embodiments, the electronic device 100 includes one or more processing units (CPUs) 174, a network or other communications interface 184, and a memory 192.

The memory 192 includes high-speed random access memory, such as DRAM, SRAM, DDR RAM, or other random access solid state memory devices, and optionally also includes non-volatile memory, such as one or more magnetic disk storage devices, optical disk storage devices, flash memory devices, or other non-volatile solid state storage devices. The memory 192 may optionally include one or more storage devices remotely located from the CPU(s) 174. The memory 192, or alternatively the non-volatile memory device(s) within memory 192, includes a non-transitory computer readable storage medium. Access to memory 192 by other components of the electronic device 100, such as the CPU(s) 174, is, optionally, controlled by a controller. In some embodiments, the memory 192 can include mass storage that is remotely located with respect to the CPU(s) 174. In other words, some data stored in the memory 192 may in fact be hosted on devices that are external to the electronic device 100, but that can be electronically accessed by the electronic device 100 over an Internet, intranet, or other form of communication network 106 or electronic cable using communication interface 184.

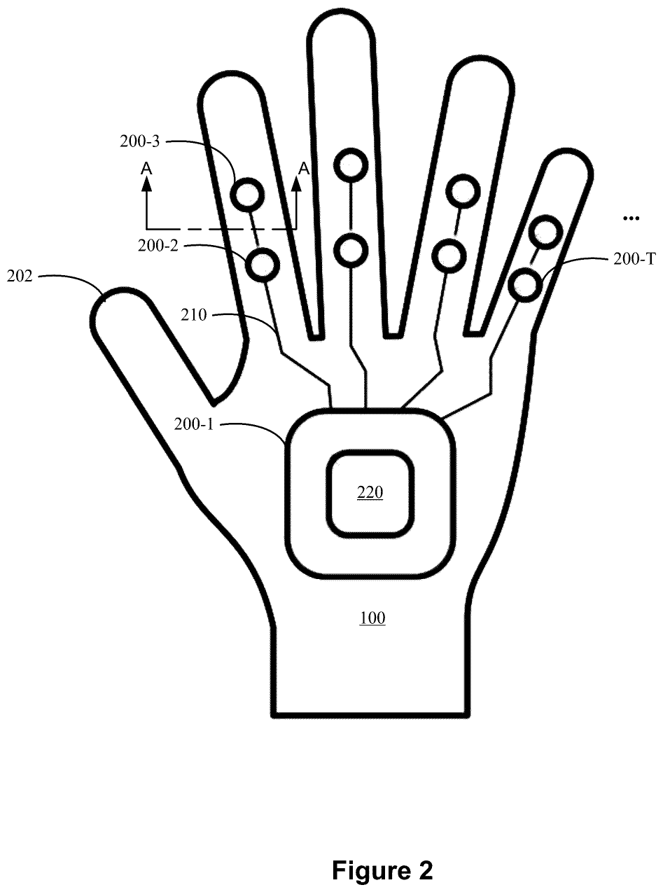

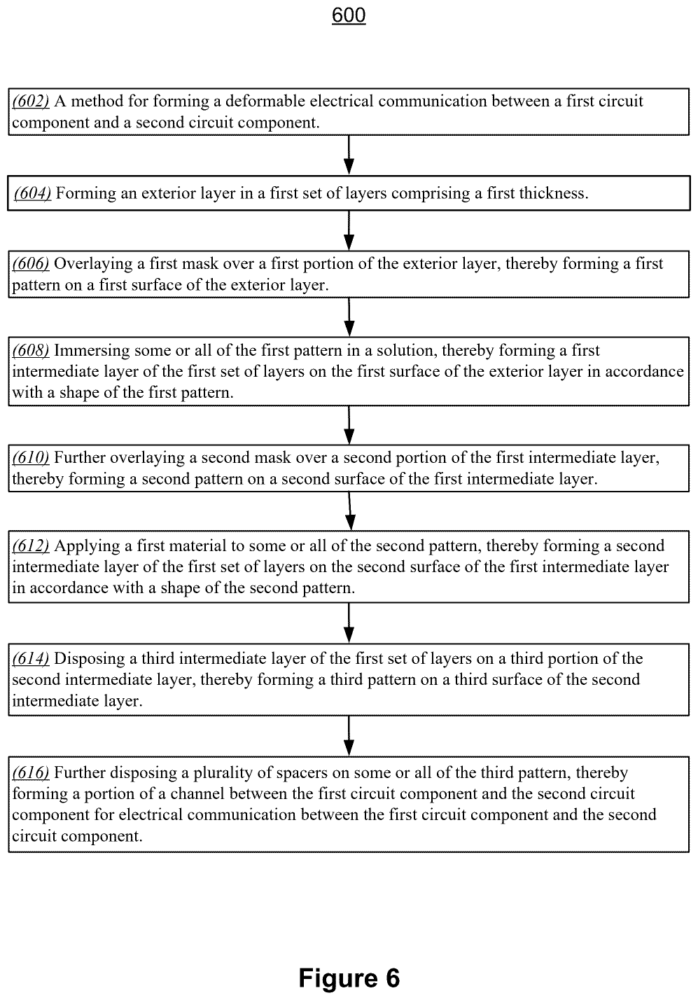

In some embodiments, the memory 192 of the electronic device 100 stores:
an optional operating system 108 (e.g., ANDROID, iOS, DARWIN, RTXC, LINUX, UNIX, OS X, WINDOWS, or an embedded operating system such as VxWorks) that includes procedures for handling various basic system services;
an electronic address 110 associated with the electronic device 100 that identifies the electronic device 100;
optionally, an electrostimulation module that stores one or more logic functions (e.g., one or more logic functions of FIG. 6) for generating and/or communicating one or more electronic signals to one or more circuit components (e.g., circuit component 200-1 of FIG. 2, circuit component 200-2 of FIG. 2, circuit component 200-3 of FIG. 2, circuit component 200-T of FIG. 2, etc.); and
optionally, an electromyography module that stores one or more logic functions (e.g., one or more logic functions of FIG. 6) for evaluation one or more electronic signals received from the one or more circuit components (e.g., circuit component 200-1 of FIG. 2, circuit component 200-2 of FIG. 2, circuit component 200-3 of FIG. 2, circuit component 200-T of FIG. 2, etc.).

In some embodiments, an electronic address 110 is associated with the electronic device 100. The electronic address 110 is utilized to identify the electronic device 100 at least uniquely from other devices and components, such as though communicated with through the communications network 106.

Each of the above identified modules and applications correspond to a set of executable instructions for performing one or more functions described above and the methods described in the present disclosure (e.g., the computer-implemented methods and other information processing methods described herein; method 600 of FIG. 6; etc.). These modules (e.g., sets of instructions) need not be implemented as separate software programs, procedures or modules, and thus various subsets of these modules are, optionally, combined or otherwise re-arranged in various embodiments of the present disclosure. In some embodiments, the memory 192 optionally stores a subset of the modules and data structures identified above. Furthermore, in some embodiments, the memory 192 stores additional modules and data structures not described above.

It should be appreciated that the electronic device 100 of FIG. 1 is only one example of an electronic device 100, and that electronic device 100 optionally has more or fewer components than shown, optionally combines two or more components, or optionally has a different configuration or arrangement of the components. The various components shown in FIG. 1 are implemented in hardware, software, firmware, or a combination thereof, including one or more signal processing and/or application specific integrated circuits.

For instance, referring briefly to FIG. 2, in some embodiments, the electronic device 100 is a garment that is worn by a subject, such as around a wrist, hand, finger, neck, waist, ankle or combination thereof of the subject. However, the present disclosure is not limited thereto. For instance, in some embodiments, the electronic device 100 is a garment accessory worn but the subject, such as a pair of glasses (e.g., smart glasses) or a wristwatch (e.g., smart watch) worn by the subject.

In some embodiments, the electronic device 100 includes a circuit that further includes two or more circuit components 200. For instance, in some embodiments, a circuit component 200 of a circuit of the electronic device 100 includes a terminal, an energy source (e.g., power supply 176 of FIG. 1), an interconnect (e.g., a line interconnect, such as a wire), a load (e.g., a device such as display 182 of FIG. 1, a sensor, etc.), a controller (e.g., switch, CPU 174 of FIG. 1), or a combination thereof. As a non-limiting example, in some embodiments, the circuit component 200 includes a terminal, resistor, transistor, capacitor, inductor, transformer, diode, sensor, or combination thereof. In some embodiments, the first circuit component 200-1 is the same type of component as the second circuit component 200-1 (e.g., both the first circuit component 200-1 and the second circuit component 200-2 include a load, both the first circuit component 200-1 and the second circuit component 200-2 include a conductor, etc.). However, the present disclosure is not limited thereto.

In some embodiments, the first circuit component 200-1 and the second circuit component 200-2 form part of an active-matrix array. For instance, in some embodiments, the first circuit component 200-1 or the second circuit component 200-2 is a transistor, electrode, or capacitor disposed on a deformable substrate 202 of the electronic device 100, and the other of the first circuit component 200-1 or the second circuit component 200-2 is different than the transistor, the electrode, or the capacitor of the first circuit component 200-1 or the second circuit component 200-2.

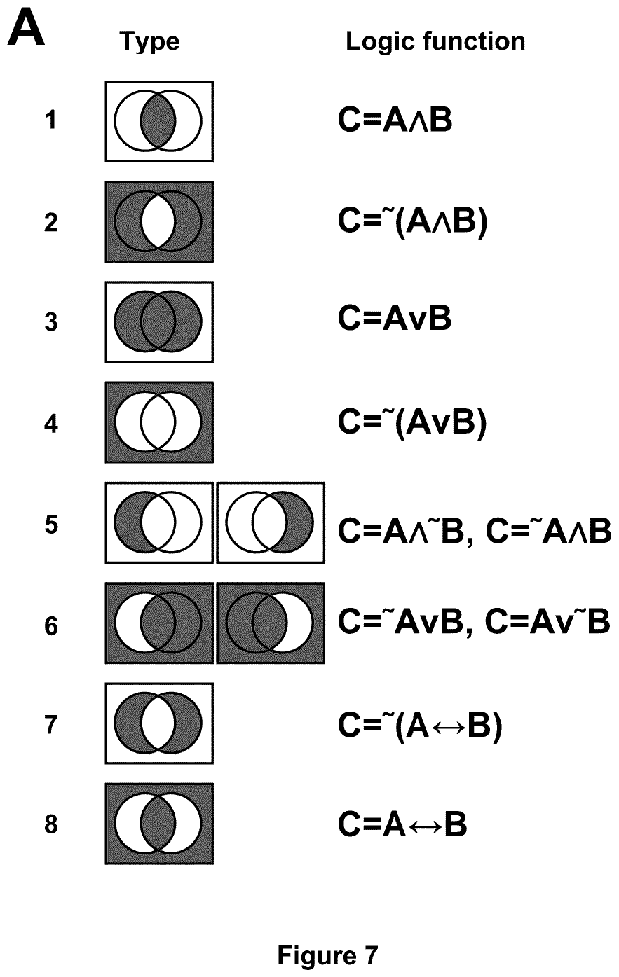

In some embodiments, the first circuit component 200-1 and the second circuit component 200-2 are part of a transistor switch. For instance, in some embodiments, the transistor switch is configured to control an electronical communication through the electronic device 100 using a logic function, such as an OR logic function based on either a cutoff or saturation of the electronical communication. In some embodiments, two or more transistor switches are arranged (e.g., in series and/or parallel) in order to implement a logic function, such as one or more logic functions of FIG. 7.

In some embodiments, the electronic device 100 includes between 2 and 10 million circuit components 200 (e.g., first circuit component 200-1, second circuit component 200-2, . . . , circuit component T 200-T), between 2 and 1 million circuit components 200, between 2 and 100,000 circuit components 200, between 2 and 10,000 circuit components 200, between 2 and 1,000 circuit components 200, between 2 and 100 circuit components 200, between 2 and 10 circuit components 200, between 5 and 10 million circuit components 200, between 5 and 1 million circuit components 200, between 5 and 100,000 circuit components 200, between 5 and 10,000 circuit components 200, between 5 and 1,000 circuit components 200, between 5 and 100 circuit components 200, between 5 and 10 circuit components 200, between 10 and 10 million circuit components 200 (e.g., first circuit component 200-1, second circuit component 200-10, . . . , circuit component T 200-T), between 10 and 1 million circuit components 200, between 10 and 100,000 circuit components 200, between 10 and 10,000 circuit components 200, between 10 and 1,000 circuit components 200, between 10 and 100 circuit components 200, between 500 and 10 million circuit components 200, between 500 and 1 million circuit components 200, between 500 and 100,000 circuit components 200, between 500 and 10,000 circuit components 200, between 500 and 1,000 circuit components 200, between 5,000 and 10 million circuit components 200 (e.g., first circuit component 200-1, second circuit component 200-2, . . . , circuit component T 200-N, in which T is less than or equal to 10 million), between 5,000 and 1 million circuit components 200, between 5,000 and 100,000 circuit components 200, or between 5,000 and 10,000 circuit components 200.

In some embodiments, the electronic device 100 includes at least 2 circuit components 200, at least 3 circuit components 200, at least 5 circuit components 200, at least 10 circuit components 200, at least 50 circuit components 200, at least 100 circuit components 200, at least 500 circuit components 200, at least 1,000 circuit components 200, at least 5,000 circuit components 200, at least 10,000 circuit components 200, at least 25,000 circuit components 200, at least 40,000 circuit components 200, at least 100,000 circuit components 200, at least 250,000 circuit components 200, at least 500,000 circuit components 200, at least 1 million circuit components 200, at least 5 million circuit components 200, or at least 10 million circuit components 200. In some embodiments, the electronic device 100 includes at most 2 circuit components 200, at most 3 circuit components 200, at most 5 circuit components 200, at most 10 circuit components 200, at most 50 circuit components 200, at most 100 circuit components 200, at most 500 circuit components 200, at most 1,000 circuit components 200, at most 5,000 circuit components 200, at most 10,000 circuit components 200, at most 25,000 circuit components 200, at most 40,000 circuit components 200, at most 100,000 circuit components 200, at most 250,000 circuit components 200, at most 500,000 circuit components 200, at most 1 million circuit components 200, at most 5 million circuit components 200, or at most 10 million circuit components 200.

Accordingly, the electronic device 100 of the present disclosure is capable of incorporating a variety of numbers of circuit components 200, which allows providing electronic devices 100 of high complexity, such as wearable garment electronic devices 100, with deformable substrates 202 that permit continuous electronic communication between two or more circuit components 200 of the electronic device 100 when the electronic device 100 is physically deformed.

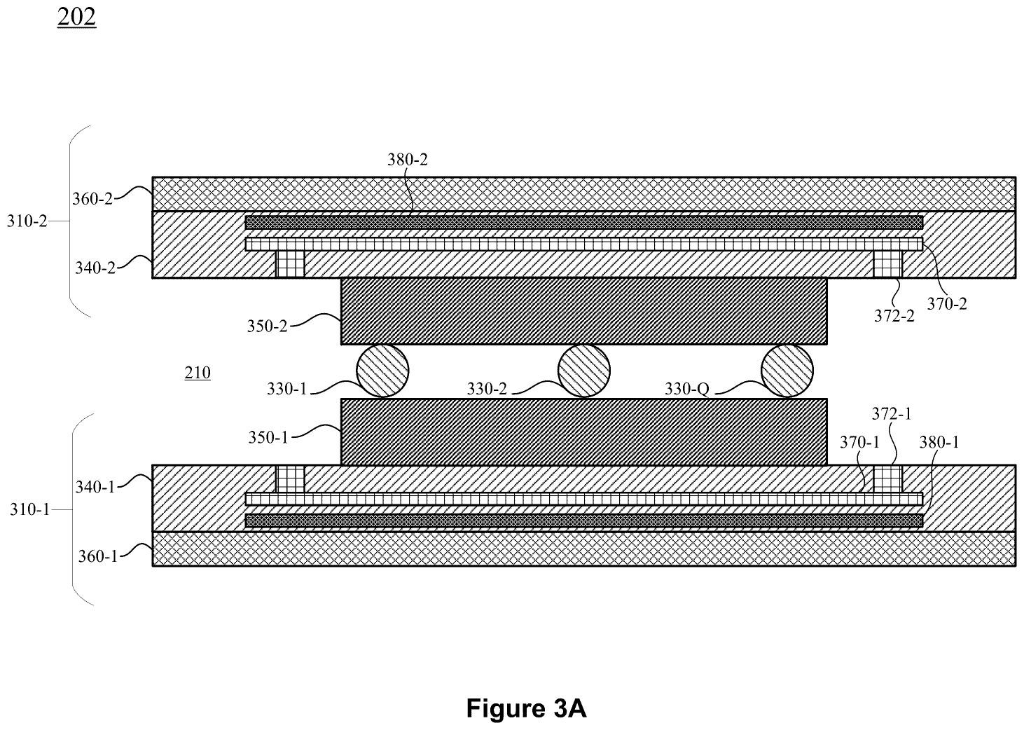

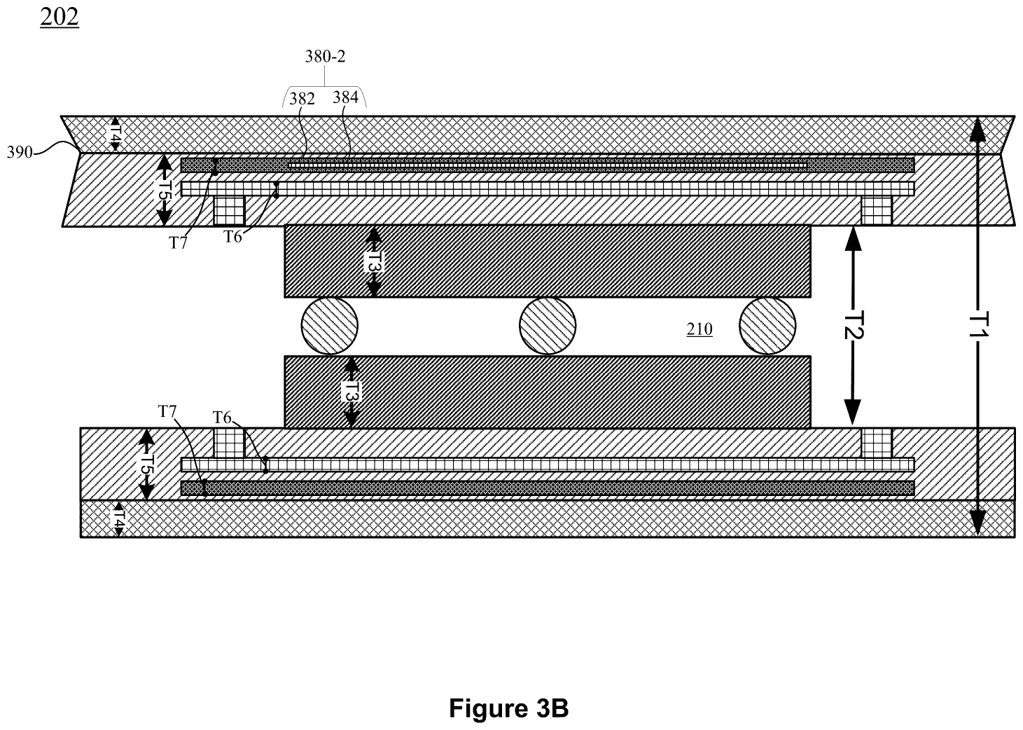

In some embodiments, each respective circuit component 200 is disposed adjacent to, on, (not shown in FIG. 3B) or within a corresponding portion of the deformable substrate 202. For instance, referring to FIG. 3B, in some embodiments, the electronic device 100 includes a first circuit component 200-1 that is disposed within a first portion of the deformable substrate 202. Moreover, in some embodiments, the electronic device 100 includes a second circuit component 200-2 that is adjacent to, on, or within the second portion of the deformable substrate 202. Accordingly, the first portion and the second portion of the deformable substrate 202 and/or one or more layers between the first portion and the second portion of the deformable substrate 202, or any combination thereof (e.g., both the first and second portion of the deformable substrate 202 as illustrated in FIG. 3A) include a gap, or span, that requires carrying electrical communication therethrough between the first circuit component 200-1 and the second circuit component 200-2.

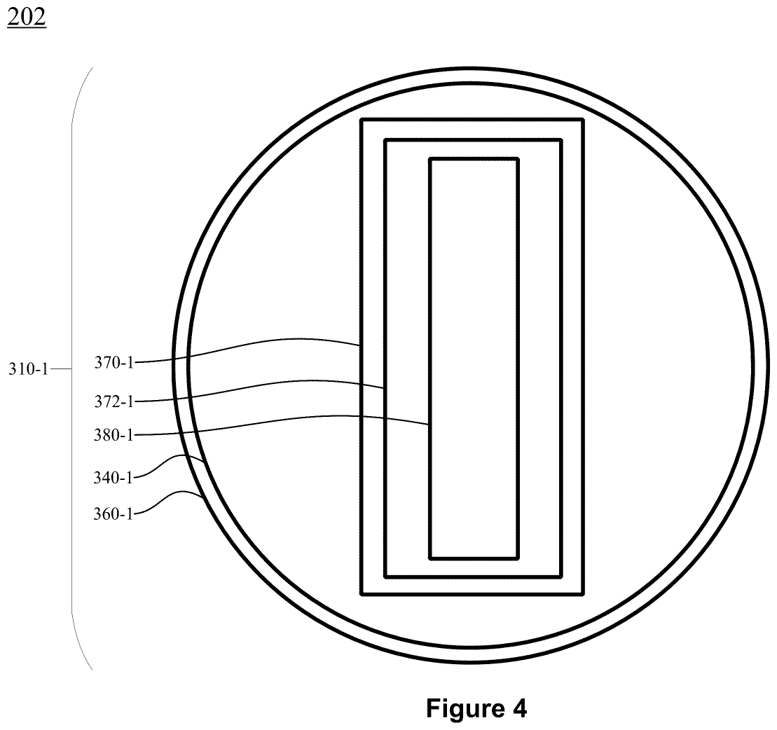

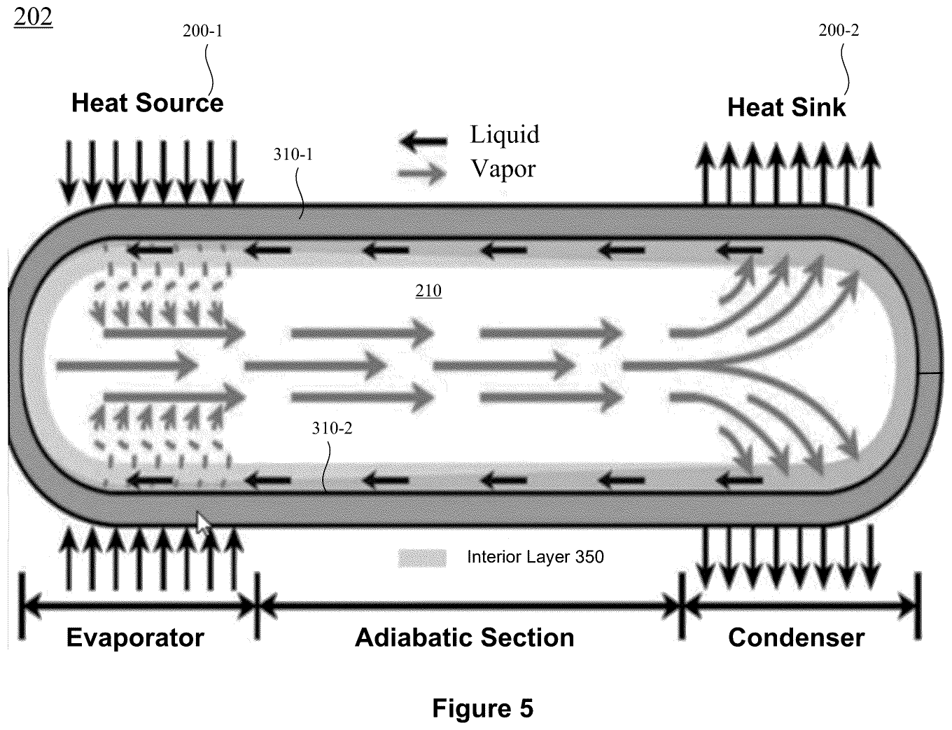

The electronic device 100 includes the deformable substrate (e.g., deformable substrate 202 of FIG. 2, deformable substrate 202 of FIG. 3A, deformable substrate 202 of FIG. 3B, deformable substrate 202 of FIG. 4, deformable substrate 202 of FIG. 5, deformable substrate 202 of method 600 of FIG. 6, etc.).

In some embodiments, the deformable substrate 202 includes a supporting material upon which or within which an object (e.g., an electronic circuit) is fabricated or attached to or is on. In some embodiments, the deformable substrate 202 or a portion of the deformable substrate 202 is processed (e.g., patterned) during manufacture of the object. In some embodiments, the deformable substrate 202 remains substantially unchanged when the object is formed upon or within the deformable substrate 202.

In some embodiments, the deformable substrate 202 is rigid or flexible, stretchable or non-stretchable, thick or thin (e.g., in form of a sheet or a film), removable (e.g., the deformable substrate 202 functions as a sacrificial layer that can be at least partially removed when desired or needed) or non-removable, or any combination thereof.

For instance, in some embodiments, the deformable substrate 202 or at least a portion of the deformable substrate is flexible, bendable, stretchable, inflatable, or the like. For instance, in some embodiments, the deformable substrate 202 or at least a portion of the deformable substrate (e.g., a layer) is made with a material having a Young's Modulus lower than about 0.5 Giga-Pascals (GPa), lower than about 0.4 GPa, lower than about 0.3 GPa, or lower than about 0.2 GPa. Such a material allows the deformable substrate 202 or a portion of the deformable substrate 202 to deform (e.g., bend, stretch, elongate, rotate, or the like) under pressure, strain, torsion, or a combination.

In some embodiments, the deformable substrate 202 includes a layer or a portion made of a relatively rigid material. For instance, in some embodiments, the deformable substrate includes a layer or a portion made of a material having Young's Modulus higher than about 0.5 GPa, higher than about 1.0 GPa, higher than about 2.0 GPa, higher than about 3.0 GPa, higher than 4.0 GPa, or higher than about 5.0 GPa. Examples of materials with relatively higher Young's Modulus include, but are not limited to, polyethylene, PEEK, polyester, aramid, composite, glass epoxy, polyethylene naphalate, and polyimide. As a non-limiting example, in some embodiments, the electronic device 100 includes one or more circuit components 200 that include a substrate formed from a first material, such as a polyimide (PI), which forms a first layer of the deformable substrate 202. However, the present disclosure is not limited thereto.

The deformable substrate 202 includes a circuit (e.g., circuit 220 of FIG. 2, etc.). In some embodiments, the circuit 220 includes a printed circuit board (PCB). For instance, in some embodiments, the circuit 220 includes one or more flexible printed circuits (FPCs). By utilizing the FPC with the circuit 220, the electronic device 100 of the present disclosure is provided with improved durability since substantially all of the electronic device 100 is formed of or on a deformable material. However, the present disclosure is not limited thereto. Moreover, in some embodiments, by utilizing one or more FPCs with the circuit 220, the electronic device 100 of the present disclosure is capable of incorporated one or more conventional FPC components that benefit from the additional stretchability (e.g., elastic elongation) gained through interfacing with the deformable substrate 202 of the present disclosure.

In some embodiments, a first thickness of the deformable substrate 202 (e.g., thickness T1 of FIG. 3B) is between 8 microns (μm) and 2,500 μm, between 8 μm and 2,000 μm, between 8 μm and 1,500 μm, between 8 μm and 1,000 μm, between 8 μm and 500 μm, between 8 μm and 250 μm, 50 μm and 2,500 μm, between 50 μm and 2,000 μm, between 50 μm and 1,500 μm, between 50 μm and 1,000 μm, between 50 μm and 500 μm, between 50 μm and 250 μm, 300 μm and 2,500 μm, between 300 μm and 2,000 μm, between 300 μm and 1,500 μm, between 300 μm and 1,000 μm, between 300 μm and 500 μm, 900 μm and 2,500 μm, between 900 μm and 2,000 μm, between 900 μm and 1,500 μm, between 900 μm and 1,000 μm, 1,200 μm and 2,500 μm, between 1,200 μm and 2,000 μm, between 1,200 μm and 1,500 μm, 2100 μm and 2,500 μm. In some embodiments, the first thickness T1 of the deformable substrate is at least 5 μm, at least 8 μm, at least 10 μm, at least 15 μm, at least 50 μm, at least 150 μm, at least 250 μm, at least 500 μm, at least 750 μm, at least 1,000 μm, at least 1,250 μm, at least 1,500 μm, at least 1,750 μm, at least 2,000 μm, at least 2,250 μm, or at least 2,500 μm. In some embodiments, the first thickness T1 of the deformable substrate is at most 5 μm, at most 8 μm, at most 10 μm, at most 15 μm, at most 50 μm, at most 150 μm, at most 250 μm, at most 500 μm, at most 750 μm, at most 1,000 μm, at most 1,250 μm, at most 1,500 μm, at most 1,750 μm, at most 2,000 μm, at most 2,250 μm, or at most 2,500 μm.

In some embodiments, the deformable substrate 202 includes a plurality of layers, such as one or more sets of layers in the plurality of layers, which yields a multilayered deformable substrate 202 and, thus, adding additional dimensionality to the electronic device 100. For instance, in some embodiments, the deformable substrate 202 includes between 4 layers and 20 layers, between 4 layers and 16 layers, between 4 layers and 12 layers, between 4 layers and 8 layers, between 6 layers and 20 layers, between 6 layers and 16 layers, between 6 layers and 12 layers, between 6 layers and 8 layers, between 8 layers and 20 layers, between 8 layers and 16 layers, between 8 layers and 12 layers, between 10 layers and 20 layers, between 10 layers and 16 layers, between 10 layers and 12 layers, between 12 layers and 20 layers, between 12 layers and 16 layers, between 14 layers and 20 layers, between 14 layers and 16 layers, between 16 layers and 20 layers, or between 18 layers and 20 layers. In some embodiments, the deformable substrate 202 includes at least 4 layers, at least 6 layers, at least 8 layers, at least 10 layers, at least 12 layers, at least 14 layers, at least 16 layers, at least 18 layers, or at least 20 layers. In some embodiments, the deformable substrate 202 includes at most 4 layers, at most 6 layers, at most 8 layers, at most 10 layers, at most 12 layers, at most 14 layers, at most 16 layers, at most 18 layers, or at most 20 layers.

For instance, in some embodiments, the deformable substrate 202 includes a stretchable first layer and a rigid second layer. In some embodiments, a first layer of the deformable substrate 202 is capable of elastic elongation and a second layer of the deformable substrate 202 is capable of plastic elongation only. However, the present disclosure in not limited thereto.

In some embodiments, the deformable substrate 202 includes two or more sets of layers (e.g., first set of layers 310-1 of FIG. 3A, second set of layers 310-2 of FIG. 3A, first set of layers 310-1 of FIG. 3B, second set of layers 310-2 of FIG. 3B, etc.). For instance, referring to FIG. 3, in some embodiments, the deformable substrate 202 includes a first set of layers 310-1 and a second set of layers 310-2. In some embodiments, the first set of layers 310-1 opposes or substantially opposes the second set of layers 310-2, such that a channel (e.g., channel 210 of FIG. 2, channel 210 of FIG. 3A) is formed interposing between the first and second set of layers.

In some embodiments, the first set of layers 310-1 includes a plurality of layers, which provides for the multilayered deformable substrate 202 and thus adds additional dimensionality to the electronic device 100. For instance, in some embodiments, the first set of layers 310-1 includes between 3 layers and 20 layers, between 3 layers and 16 layers, between 3 layers and 12 layers, between 3 layers and 8 layers, between 3 or 5 layers, between 6 layers and 20 layers, between 6 layers and 16 layers, between 6 layers and 12 layers, between 6 layers and 8 layers, between 8 layers and 20 layers, between 8 layers and 16 layers, between 8 layers and 12 layers, between 10 layers and 20 layers, between 10 layers and 16 layers, between 10 layers and 12 layers, between 12 layers and 20 layers, between 12 layers and 16 layers, between 14 layers and 20 layers, between 14 layers and 16 layers, between 16 layers and 20 layers, or between 18 layers and 20 layers. In some embodiments, the first set of layers 310-1 includes at least 3 layers, at least 4 layers, at least 6 layers, at least 8 layers, at least 10 layers, at least 12 layers, at least 14 layers, at least 16 layers, at least 18 layers, or at least 20 layers. In some embodiments, the first set of layers 310-1 includes at most 3 layers, at most 4 layers, at most 6 layers, at most 8 layers, at most 10 layers, at most 12 layers, at most 14 layers, at most 16 layers, at most 18 layers, or at most 20 layers.

In some embodiments, the first set of layers 310-1 and the second set of layers 310-2 are coplanar or substantially coplanar with each other. As a non-limiting example, in some embodiments, the first set of layers 310-1 includes a first surface, such as a first planar surface, a first substantially planar surface, a first curved surface, a first round surface (e.g., a first edge having a first radius of curvature greater than zero), one or more first sharp edges, or any combination thereof, and the second set of layers 310-2 includes a second surface, such as a second planar surface, a second substantially planar surface, a second curved surface, a second round surface (e.g., a second edge having a second radius of curvature greater than zero), one or more second sharp edges, or any combination thereof that is coplanar or substantially coplanar to the first surface, such as the first planar surface, the first substantially planar surface, the first curved surface, the first round surface, the one or more first sharp edges, or the combination thereof for a length of the deformable substrate 202. However, the present disclosure is not limited thereto.

Moreover, the deformable substrate 202 includes a channel (e.g., channel 210 of FIG. 2, channel 210 of FIG. 3A, channel 210 of FIG. 3B, channel 210 of FIG. 5, etc.). For instance, in some embodiments, the first set of layers 310-1 opposes the second set of layers 310-2 such that the channel 210 is encapsulated by the first and second set of layers. Additionally, in some such embodiments, the channel 210 is bounded by an interior layer of the first set of layers 310-1 (e.g., first interior layer 350-1 of first set of layers 310-1 of FIG. 3A, etc.) and a second interior layer of the second set of layers 310-2 (e.g., second interior layer 350-2 of second set of layers 310-2 of FIG. 3A, etc.). For instance, in some embodiments, the interior layer 350-1 of the first set of layers 310-1 and the interior layer 350-2 of the second set of layers 310-2 each includes an interior face that faces the channel 210 and an exterior face that opposes (faces away from) the channel 210. Accordingly, the first set of layers 310-1 and the second set of layers 310-2 allow for the formation of the channel 210 in a closed-form shape, which prevents fluid communication between the interior of the channel 210 and the outer environment, such as the atmosphere surrounding the electronic device 100 and/or sweat generated by the subject when using the electronic device 100. However, the present disclosure is not limited thereto.

For instance, in some embodiments, the channel 210 is configured to accommodate a medium, which is enclosed within the interior volume of the deformable substrate 202 formed by at least the channel 210. Moreover, in some such embodiments, the medium accommodated by the substrate is a fluid (e.g., liquid, gas, or multi-phase material) or a porous solid, which allows for the transfer of heat and mass through the channel. As a non-limiting example, in some embodiments, the medium of the channel 210 includes water, such as deionized water or distilled water. However, the present disclosure is not limited thereto. For instance, in some embodiments, the medium of the channel includes a non-polar fluid, such as mineral oil or the like. Accordingly, in some embodiments, the channel 210 forms an internal cavity between the first set of layers 310-1 and the second set of layers 310-2 that allows for the accommodation of mediums within the channel such as porous structures and/or working fluids (e.g., water) for utilization in heat mass transfer through the electronic device 100.

In some embodiments, the channel 210 is configured to span a length of the deformable substrate 202, such as a first length extending between a first portion of the first circuit component 200-1 and as second portion of the second circuit component 200-2 of the electronic device 100. For instance, in some embodiments, the length of the channel 210 is between 1 millimeter (mm) and 100 centimeters (cm), between 1 mm and 75 cm, between 1 mm and 50 cm, between 1 mm and 10 cm, between 1 mm and 1 cm, between 1 cm and 100 cm, between 1 cm and 75 cm, between 1 cm and 50 cm, between 1 cm and 10 cm, between 20 cm and 100 cm, between 20 cm and 75 cm, between 20 cm and 50 cm, between 40 cm and 100 cm, between 40 cm and 75 cm, between 40 cm and 50 cm, or between 70 cm and 100 cm. In some embodiments, the length of the channel 210 is at least 1 mm, at least 5 mm, at least 10 mm, at least 5 cm, at least 10 cm, at least 20 cm, at least 30 at least 40 cm, at least 50 cm, at least 60 cm, at least 70 cm, at least 80 cm, at least 90 cm, or at least 1 meter. In some embodiments, the length of the channel 210 is at most 1 mm, at most 5 mm, at most 10 mm, at most 5 cm, at most 10 cm, at most 20 cm, at most 30 at most 40 cm, at most 50 cm, at most 60 cm, at most 70 cm, at most 80 cm, at most 90 cm, or at most 1 meter. For instance, in some embodiments, the length of the channel 210 is configured to extend between two or more joints of one or more limbs or digits of the subject, such as between a finger and wrist of the subject. However, the present disclosure is not limited thereto.

In some embodiments, a second thickness of the channel 210 (e.g., T2 of FIG. 3B) is between 100 μm and 1,000 μm. In some embodiments, the thickness T2 of the channel 210 refers to a nominal (e.g., mean or average) diameter less than a diameter or a width threshold of a cross-section of the channel 210. A cross section of the channel 210 can be, but does not necessarily have to be, a circle. For instance, in some embodiments, the cross section of the channel 210 can be any regular closed form shape such as a circle or polygon of the form N-gon, where here N is a positive integer of 3 or greater, or an irregular closed form shape, or the like.

For instance, in some embodiments, the nominal diameter or a width of a cross-section T2 of the channel 210 is between 100 μm and 1,000 μm, between 110 μm and 975 μm, between 110 μm and 950 μm, between 110 μm and 925 μm, between 110 μm and 900 μm, between 110 μm and 875 μm, between 110 μm and 850 μm, between 110 μm and 825 μm, between 110 μm and 800 μm, between 110 μm and 775 μm, between 110 μm and 750 μm, between 110 μm and 725 μm, between 110 μm and 700 μm, between 110 μm and 675 μm, between 110 μm and 650 μm, between 110 μm and 625 μm, between 110 μm and 600 μm, between 110 μm and 575 μm, between 110 μm and 550 μm, between 110 μm and 525 μm, between 110 μm and 500 μm, between 110 μm and 475 μm, between 110 μm and 450 μm, between 110 μm and 425 μm, between 110 μm and 400 μm, between 110 μm and 375 μm, between 110 μm and 350 μm, between 110 μm and 325 μm, between 110 μm and 300 μm, between 110 μm and 275 μm, between 110 μm and 250 μm, between 110 μm and 225 μm, between 110 μm and 200 μm, between 110 μm and 175 μm, between 110 μm and 150 μm, between 110 μm and 125 μm, between 130 μm and 975 μm, between 130 μm and 950 μm, between 130 μm and 925 μm, between 130 μm and 900 μm, between 130 μm and 875 μm, between 130 μm and 850 μm, between 130 μm and 825 μm, between 130 μm and 800 μm, between 130 μm and 775 μm, between 130 μm and 750 μm, between 130 μm and 725 μm, between 130 μm and 700 μm, between 130 μm and 675 μm, between 130 μm and 650 μm, between 130 μm and 625 μm, between 130 μm and 600 μm, between 130 μm and 575 μm, between 130 μm and 550 μm, between 130 μm and 525 μm, between 130 μm and 500 μm, between 130 μm and 475 μm, between 130 μm and 450 μm, between 130 μm and 425 μm, between 130 μm and 400 μm, between 130 μm and 375 μm, between 130 μm and 350 μm, between 130 μm and 325 μm, between 130 μm and 300 μm, between 130 μm and 275 μm, between 130 μm and 250 μm, between 130 μm and 225 μm, between 130 μm and 200 μm, between 130 μm and 175 μm, between 130 μm and 150 μm, between 150 μm and 975 μm, between 150 μm and 950 μm, between 150 μm and 925 μm, between 150 μm and 900 μm, between 150 μm and 875 μm, between 150 μm and 850 μm, between 150 μm and 825 μm, between 150 μm and 800 μm, between 150 μm and 775 μm, between 150 μm and 750 μm, between 150 μm and 725 μm, between 150 μm and 700 μm, between 150 μm and 675 μm, between 150 μm and 650 μm, between 150 μm and 625 μm, between 150 μm and 600 μm, between 150 μm and 575 μm, between 150 μm and 550 μm, between 150 μm and 525 μm, between 150 μm and 500 μm, between 150 μm and 475 μm, between 150 μm and 450 μm, between 150 μm and 425 μm, between 150 μm and 400 μm, between 150 μm and 375 μm, between 150 μm and 350 μm, between 150 μm and 325 μm, between 150 μm and 300 μm, between 150 μm and 275 μm, between 150 μm and 250 μm, between 150 μm and 225 μm, between 150 μm and 200 μm, between 150 μm and 175 μm, between 170 μm and 975 μm, between 170 μm and 950 μm, between 170 μm and 925 μm, between 170 μm and 900 μm, between 170 μm and 875 μm, between 170 μm and 850 μm, between 170 μm and 825 μm, between 170 μm and 800 μm, between 170 μm and 775 μm, between 170 μm and 750 μm, between 170 μm and 725 μm, between 170 μm and 700 μm, between 170 μm and 675 μm, between 170 μm and 650 μm, between 170 μm and 625 μm, between 170 μm and 600 μm, between 170 μm and 575 μm, between 170 μm and 550 μm, between 170 μm and 525 μm, between 170 μm and 500 μm, between 170 μm and 475 μm, between 170 μm and 450 μm, between 170 μm and 425 μm, between 170 μm and 400 μm, between 170 μm and 375 μm, between 170 μm and 350 μm, between 170 μm and 325 μm, between 170 μm and 300 μm, between 170 μm and 275 μm, between 170 μm and 250 μm, between 170 μm and 225 μm, between 170 μm and 200 μm, between 170 μm and 175 μm, between 190 μm and 975 μm, between 190 μm and 950 μm, between 190 μm and 925 μm, between 190 μm and 900 μm, between 190 μm and 875 μm, between 190 μm and 850 μm, between 190 μm and 825 μm, between 190 μm and 800 μm, between 190 μm and 775 μm, between 190 μm and 750 μm, between 190 μm and 725 μm, between 190 μm and 700 μm, between 190 μm and 675 μm, between 190 μm and 650 μm, between 190 μm and 625 μm, between 190 μm and 600 μm, between 190 μm and 575 μm, between 190 μm and 550 μm, between 190 μm and 525 μm, between 190 μm and 500 μm, between 190 μm and 475 μm, between 190 μm and 450 μm, between 190 μm and 425 μm, between 190 μm and 400 μm, between 190 μm and 375 μm, between 190 μm and 350 μm, between 190 μm and 325 μm, between 190 μm and 300 μm, between 190 μm and 275 μm, between 190 μm and 250 μm, between 190 μm and 225 μm, between 190 μm and 200 μm, between 210 μm and 975 μm, between 210 μm and 950 μm, between 210 μm and 925 μm, between 210 μm and 900 μm, between 210 μm and 875 μm, between 210 μm and 850 μm, between 210 μm and 825 μm, between 210 μm and 800 μm, between 210 μm and 775 μm, between 210 μm and 750 μm, between 210 μm and 725 μm, between 210 μm and 700 μm, between 210 μm and 675 μm, between 210 μm and 650 μm, between 210 μm and 625 μm, between 210 μm and 600 μm, between 210 μm and 575 μm, between 210 μm and 550 μm, between 210 μm and 525 μm, between 210 μm and 500 μm, between 210 μm and 475 μm, between 210 μm and 450 μm, between 210 μm and 425 μm, between 210 μm and 400 μm, between 210 μm and 375 μm, between 210 μm and 350 μm, between 210 μm and 325 μm, between 210 μm and 300 μm, between 210 μm and 275 μm, between 210 μm and 250 μm, between 210 μm and 225 μm, between 230 μm and 975 μm, between 230 μm and 950 μm, between 230 μm and 925 μm, between 230 μm and 900 μm, between 230 μm and 875 μm, between 230 μm and 850 μm, between 230 μm and 825 μm, between 230 μm and 800 μm, between 230 μm and 775 μm, between 230 μm and 750 μm, between 230 μm and 725 μm, between 230 μm and 700 μm, between 230 μm and 675 μm, between 230 μm and 650 μm, between 230 μm and 625 μm, between 230 μm and 600 μm, between 230 μm and 575 μm, between 230 μm and 550 μm, between 230 μm and 525 μm, between 230 μm and 500 μm, between 230 μm and 475 μm, between 230 μm and 450 μm, between 230 μm and 425 μm, between 230 μm and 400 μm, between 230 μm and 375 μm, between 230 μm and 350 μm, between 230 μm and 325 μm, between 230 μm and 300 μm, between 230 μm and 275 μm, between 230 μm and 250 μm, between 250 μm and 975 μm, between 250 μm and 950 μm, between 250 μm and 925 μm, between 250 μm and 900 μm, between 250 μm and 875 μm, between 250 μm and 850 μm, between 250 μm and 825 μm, between 250 μm and 800 μm, between 250 μm and 775 μm, between 250 μm and 750 μm, between 250 μm and 725 μm, between 250 μm and 700 μm, between 250 μm and 675 μm, between 250 μm and 650 μm, between 250 μm and 625 μm, between 250 μm and 600 μm, between 250 μm and 575 μm, between 250 μm and 550 μm, between 250 μm and 525 μm, between 250 μm and 500 μm, between 250 μm and 475 μm, between 250 μm and 450 μm, between 250 μm and 425 μm, between 250 μm and 400 μm, between 250 μm and 375 μm, between 250 μm and 350 μm, between 250 μm and 325 μm, between 250 μm and 300 μm, between 250 μm and 275 μm, between 270 μm and 975 μm, between 270 μm and 950 μm, between 270 μm and 925 μm, between 270 μm and 900 μm, between 270 μm and 875 μm, between 270 μm and 850 μm, between 270 μm and 825 μm, between 270 μm and 800 μm, between 270 μm and 775 μm, between 270 μm and 750 μm, between 270 μm and 725 μm, between 270 μm and 700 μm, between 270 μm and 675 μm, between 270 μm and 650 μm, between 270 μm and 625 μm, between 270 μm and 600 μm, between 270 μm and 575 μm, between 270 μm and 550 μm, between 270 μm and 525 μm, between 270 μm and 500 μm, between 270 μm and 475 μm, between 270 μm and 450 μm, between 270 μm and 425 μm, between 270 μm and 400 μm, between 270 μm and 375 μm, between 270 μm and 350 μm, between 270 μm and 325 μm, between 270 μm and 300 μm, between 270 μm and 275 μm, between 290 μm and 975 μm, between 290 μm and 950 μm, between 290 μm and 925 μm, between 290 μm and 900 μm, between 290 μm and 875 μm, between 290 μm and 850 μm, between 290 μm and 825 μm, between 290 μm and 800 μm, between 290 μm and 775 μm, between 290 μm and 750 μm, between 290 μm and 725 μm, between 290 μm and 700 μm, between 290 μm and 675 μm, between 290 μm and 650 μm, between 290 μm and 625 μm, between 290 μm and 600 μm, between 290 μm and 575 μm, between 290 μm and 550 μm, between 290 μm and 525 μm, between 290 μm and 500 μm, between 290 μm and 475 μm, between 290 μm and 450 μm, between 290 μm and 425 μm, between 290 μm and 400 μm, between 290 μm and 375 μm, between 290 μm and 350 μm, between 290 μm and 325 μm, between 290 μm and 300 μm, between 310 μm and 975 μm, between 310 μm and 950 μm, between 310 μm and 925 μm, between 310 μm and 900 μm, between 310 μm and 875 μm, between 310 μm and 850 μm, between 310 μm and 825 μm, between 310 μm and 800 μm, between 310 μm and 775 μm, between 310 μm and 750 μm, between 310 μm and 725 μm, between 310 μm and 700 μm, between 310 μm and 675 μm, between 310 μm and 650 μm, between 310 μm and 625 μm, between 310 μm and 600 μm, between 310 μm and 575 μm, between 310 μm and 550 μm, between 310 μm and 525 μm, between 310 μm and 500 μm, between 310 μm and 475 μm, between 310 μm and 450 μm, between 310 μm and 425 μm, between 310 μm and 400 μm, between 310 μm and 375 μm, between 310 μm and 350 μm, between 310 μm and 325 μm, between 330 μm and 975 μm, between 330 μm and 950 μm, between 330 μm and 925 μm, between 330 μm and 900 μm, between 330 μm and 875 μm, between 330 μm and 850 μm, between 330 μm and 825 μm, between 330 μm and 800 μm, between 330 μm and 775 μm, between 330 μm and 750 μm, between 330 μm and 725 μm, between 330 μm and 700 μm, between 330 μm and 675 μm, between 330 μm and 650 μm, between 330 μm and 625 μm, between 330 μm and 600 μm, between 330 μm and 575 μm, between 330 μm and 550 μm, between 330 μm and 525 μm, between 330 μm and 500 μm, between 330 μm and 475 μm, between 330 μm and 450 μm, between 330 μm and 425 μm, between 330 μm and 400 μm, between 330 μm and 375 μm, between 330 μm and 350 μm, between 350 μm and 975 μm, between 350 μm and 950 μm, between 350 μm and 925 μm, between 350 μm and 900 μm, between 350 μm and 875 μm, between 350 μm and 850 μm, between 350 μm and 825 μm, between 350 μm and 800 μm, between 350 μm and 775 μm, between 350 μm and 750 μm, between 350 μm and 725 μm, between 350 μm and 700 μm, between 350 μm and 675 μm, between 350 μm and 650 μm, between 350 μm and 625 μm, between 350 μm and 600 μm, between 350 μm and 575 μm, between 350 μm and 550 μm, between 350 μm and 525 μm, between 350 μm and 500 μm, between 350 μm and 475 μm, between 350 μm and 450 μm, between 350 μm and 425 μm, between 350 μm and 400 μm, between 350 μm and 375 μm, between 370 μm and 975 μm, between 370 μm and 950 μm, between 370 μm and 925 μm, between 370 μm and 900 μm, between 370 μm and 875 μm, between 370 μm and 850 μm, between 370 μm and 825 μm, between 370 μm and 800 μm, between 370 μm and 775 μm, between 370 μm and 750 μm, between 370 μm and 725 μm, between 370 μm and 700 μm, between 370 μm and 675 μm, between 370 μm and 650 μm, between 370 μm and 625 μm, between 370 μm and 600 μm, between 370 μm and 575 μm, between 370 μm and 550 μm, between 370 μm and 525 μm, between 370 μm and 500 μm, between 370 μm and 475 μm, between 370 μm and 450 μm, between 370 μm and 425 μm, between 370 μm and 400 μm, between 370 μm and 375 μm, between 390 μm and 975 μm, between 390 μm and 950 μm, between 390 μm and 925 μm, between 390 μm and 900 μm, between 390 μm and 875 μm, between 390 μm and 850 μm, between 390 μm and 825 μm, between 390 μm and 800 μm, between 390 μm and 775 μm, between 390 μm and 750 μm, between 390 μm and 725 μm, between 390 μm and 700 μm, between 390 μm and 675 μm, between 390 μm and 650 μm, between 390 μm and 625 μm, between 390 μm and 600 μm, between 390 μm and 575 μm, between 390 μm and 550 μm, between 390 μm and 525 μm, between 390 μm and 500 μm, between 390 μm and 475 μm, between 390 μm and 450 μm, between 390 μm and 425 μm, between 390 μm and 400 μm, between 410 μm and 975 μm, between 410 μm and 950 μm, between 410 μm and 925 μm, between 410 μm and 900 μm, between 410 μm and 875 μm, between 410 μm and 850 μm, between 410 μm and 825 μm, between 410 μm and 800 μm, between 410 μm and 775 μm, between 410 μm and 750 μm, between 410 μm and 725 μm, between 410 μm and 700 μm, between 410 μm and 675 μm, between 410 μm and 650 μm, between 410 μm and 625 μm, between 410 μm and 600 μm, between 410 μm and 575 μm, between 410 μm and 550 μm, between 410 μm and 525 μm, between 410 μm and 500 μm, between 410 μm and 475 μm, between 410 μm and 450 μm, between 410 μm and 425 μm, between 410 μm and 400 μm, between 430 μm and 975 μm, between 430 μm and 950 μm, between 430 μm and 925 μm, between 430 μm and 900 μm, between 430 μm and 875 μm, between 430 μm and 850 μm, between 430 μm and 825 μm, between 430 μm and 800 μm, between 430 μm and 775 μm, between 430 μm and 750 μm, between 430 μm and 725 μm, between 430 μm and 700 μm, between 430 μm and 675 μm, between 430 μm and 650 μm, between 430 μm and 625 μm, between 430 μm and 600 μm, between 430 μm and 575 μm, between 430 μm and 550 μm, between 430 μm and 525 μm, between 430 μm and 500 μm, between 430 μm and 475 μm, between 430 μm and 450 μm, between 450 μm and 975 μm, between 450 μm and 950 μm, between 450 μm and 925 μm, between 450 μm and 900 μm, between 450 μm and 875 μm, between 450 μm and 850 μm, between 450 μm and 825 μm, between 450 μm and 800 μm, between 450 μm and 775 μm, between 450 μm and 750 μm, between 450 μm and 725 μm, between 450 μm and 700 μm, between 450 μm and 675 μm, between 450 μm and 650 μm, between 450 μm and 625 μm, between 450 μm and 600 μm, between 450 μm and 575 μm, between 450 μm and 550 μm, between 450 μm and 525 μm, between 450 μm and 500 μm, between 450 μm and 475 μm, between 470 μm and 975 μm, between 470 μm and 950 μm, between 470 μm and 925 μm, between 470 μm and 900 μm, between 470 μm and 875 μm, between 470 μm and 850 μm, between 470 μm and 825 μm, between 470 μm and 800 μm, between 470 μm and 775 μm, between 470 μm and 750 μm, between 470 μm and 725 μm, between 470 μm and 700 μm, between 470 μm and 675 μm, between 470 μm and 650 μm, between 470 μm and 625 μm, between 470 μm and 600 μm, between 470 μm and 575 μm, between 470 μm and 550 μm, between 470 μm and 525 μm, between 470 μm and 500 μm, between 470 μm and 475 μm, between 490 μm and 975 μm, between 490 μm and 950 μm, between 490 μm and 925 μm, between 490 μm and 900 μm, between 490 μm and 875 μm, between 490 μm and 850 μm, between 490 μm and 825 μm, between 490 μm and 800 μm, between 490 μm and 775 μm, between 490 μm and 750 μm, between 490 μm and 725 μm, between 490 μm and 700 μm, between 490 μm and 675 μm, between 490 μm and 650 μm, between 490 μm and 625 μm, between 490 μm and 600 μm, between 490 μm and 575 μm, between 490 μm and 550 μm, between 490 μm and 525 μm, between 490 μm and 500 μm, between 510 μm and 975 μm, between 510 μm and 950 μm, between 510 μm and 925 μm, between 510 μm and 900 μm, between 510 μm and 875 μm, between 510 μm and 850 μm, between 510 μm and 825 μm, between 510 μm and 800 μm, between 510 μm and 775 μm, between 510 μm and 750 μm, between 510 μm and 725 μm, between 510 μm and 700 μm, between 510 μm and 675 μm, between 510 μm and 650 μm, between 510 μm and 625 μm, between 510 μm and 600 μm, between 510 μm and 575 μm, between 510 μm and 550 μm, between 510 μm and 525 μm, between 530 μm and 975 μm, between 530 μm and 950 μm, between 530 μm and 925 μm, between 530 μm and 900 μm, between 530 μm and 875 μm, between 530 μm and 850 μm, between 530 μm and 825 μm, between 530 μm and 800 μm, between 530 μm and 775 μm, between 530 μm and 750 μm, between 530 μm and 725 μm, between 530 μm and 700 μm, between 530 μm and 675 μm, between 530 μm and 650 μm, between 530 μm and 625 μm, between 530 μm and 600 μm, between 530 μm and 575 μm, between 530 μm and 550 μm, between 550 μm and 975 μm, between 550 μm and 950 μm, between 550 μm and 925 μm, between 550 μm and 900 μm, between 550 μm and 875 μm, between 550 μm and 850 μm, between 550 μm and 825 μm, between 550 μm and 800 μm, between 550 μm and 775 μm, between 550 μm and 750 μm, between 550 μm and 725 μm, between 550 μm and 700 μm, between 550 μm and 675 μm, between 550 μm and 650 μm, between 550 μm and 625 μm, between 550 μm and 600 μm, between 550 μm and 575 μm, between 570 μm and 975 μm, between 570 μm and 950 μm, between 570 μm and 925 μm, between 570 μm and 900 μm, between 570 μm and 875 μm, between 570 μm and 850 μm, between 570 μm and 825 μm, between 570 μm and 800 μm, between 570 μm and 775 μm, between 570 μm and 750 μm, between 570 μm and 725 μm, between 570 μm and 700 μm, between 570 μm and 675 μm, between 570 μm and 650 μm, between 570 μm and 625 μm, between 570 μm and 600 μm, between 570 μm and 575 μm, between 590 μm and 975 μm, between 590 μm and 950 μm, between 590 μm and 925 μm, between 590 μm and 900 μm, between 590 μm and 875 μm, between 590 μm and 850 μm, between 590 μm and 825 μm, between 590 μm and 800 μm, between 590 μm and 775 μm, between 590 μm and 750 μm, between 590 μm and 725 μm, between 590 μm and 700 μm, between 590 μm and 675 μm, between 590 μm and 650 μm, between 590 μm and 625 μm, between 590 μm and 600 μm, between 610 μm and 975 μm, between 610 μm and 950 μm, between 610 μm and 925 μm, between 610 μm and 900 μm, between 610 μm and 875 μm, between 610 μm and 850 μm, between 610 μm and 825 μm, between 610 μm and 800 μm, between 610 μm and 775 μm, between 610 μm and 750 μm, between 610 μm and 725 μm, between 610 μm and 700 μm, between 610 μm and 675 μm, between 610 μm and 650 μm, between 610 μm and 625 μm, between 630 μm and 975 μm, between 630 μm and 950 μm, between 630 μm and 925 μm, between 630 μm and 900 μm, between 630 μm and 875 μm, between 630 μm and 850 μm, between 630 μm and 825 μm, between 630 μm and 800 μm, between 630 μm and 775 μm, between 630 μm and 750 μm, between 630 μm and 725 μm, between 630 μm and 700 μm, between 630 μm and 675 μm, between 630 μm and 650 μm, between 650 μm and 975 μm, between 650 μm and 950 μm, between 650 μm and 925 μm, between 650 μm and 900 μm, between 650 μm and 875 μm, between 650 μm and 850 μm, between 650 μm and 825 μm, between 650 μm and 800 μm, between 650 μm and 775 μm, between 650 μm and 750 μm, between 650 μm and 725 μm, between 650 μm and 700 μm, between 650 μm and 675 μm, between 670 μm and 975 μm, between 670 μm and 950 μm, between 670 μm and 925 μm, between 670 μm and 900 μm, between 670 μm and 875 μm, between 670 μm and 850 μm, between 670 μm and 825 μm, between 670 μm and 800 μm, between 670 μm and 775 μm, between 670 μm and 750 μm, between 670 μm and 725 μm, between 670 μm and 700 μm, between 670 μm and 675 μm, between 690 μm and 975 μm, between 690 μm and 950 μm, between 690 μm and 925 μm, between 690 μm and 900 μm, between 690 μm and 875 μm, between 690 μm and 850 μm, between 690 μm and 825 μm, between 690 μm and 800 μm, between 690 μm and 775 μm, between 690 μm and 750 μm, between 690 μm and 725 μm, between 690 μm and 700 μm, between 710 μm and 975 μm, between 710 μm and 950 μm, between 710 μm and 925 μm, between 710 μm and 900 μm, between 710 μm and 875 μm, between 710 μm and 850 μm, between 710 μm and 825 μm, between 710 μm and 800 μm, between 710 μm and 775 μm, between 710 μm and 750 μm, between 710 μm and 725 μm, between 730 μm and 975 μm, between 730 μm and 950 μm, between 730 μm and 925 μm, between 730 μm and 900 μm, between 730 μm and 875 μm, between 730 μm and 850 μm, between 730 μm and 825 μm, between 730 μm and 800 μm, between 730 μm and 775 μm, between 730 μm and 750 μm, between 750 μm and 975 μm, between 750 μm and 950 μm, between 750 μm and 925 μm, between 750 μm and 900 μm, between 750 μm and 875 μm, between 750 μm and 850 μm, between 750 μm and 825 μm, between 750 μm and 800 μm, between 750 μm and 775 μm, between 770 μm and 975 μm, between 770 μm and 950 μm, between 770 μm and 925 μm, between 770 μm and 900 μm, between 770 μm and 875 μm, between 770 μm and 850 μm, between 770 μm and 825 μm, between 770 μm and 800 μm, between 770 μm and 775 μm, between 790 μm and 975 μm, between 790 μm and 950 μm, between 790 μm and 925 μm, between 790 μm and 900 μm, between 790 μm and 875 μm, between 790 μm and 850 μm, between 790 μm and 825 μm, between 790 μm and 800 μm, between 810 μm and 975 μm, between 810 μm and 950 μm, between 810 μm and 925 μm, between 810 μm and 900 μm, between 810 μm and 875 μm, between 810 μm and 850 μm, between 810 μm and 825 μm, between 830 μm and 975 μm, between 830 μm and 950 μm, between 830 μm and 925 μm, between 830 μm and 900 μm, between 830 μm and 875 μm, between 830 μm and 850 μm, between 850 μm and 975 μm, between 850 μm and 950 μm, between 850 μm and 925 μm, between 850 μm and 900 μm, between 850 μm and 875 μm, between 870 μm and 975 μm, between 870 μm and 950 μm, between 870 μm and 925 μm, between 870 μm and 900 μm, between 870 μm and 875 μm, between 890 μm and 975 μm, between 890 μm and 950 μm, between 890 μm and 925 μm, between 890 μm and 900 μm, between 910 μm and 975 μm, between 910 μm and 950 μm, between 910 μm and 925 μm, between 930 μm and 975 μm, between 930 μm and 950 μm, between 950 μm and 975 μm, or between 970 μm and 975 μm.

In some embodiments, the nominal diameter or width of a cross-section T2 of the channel 210 is at least 100 μm, at least 105 μm, at least 110 μm, at least 115 μm, at least 120 μm, at least 125 μm, at least 130 μm, at least 135 μm, at least 140 μm, at least 145 μm, at least 150 μm, at least 155 μm, at least 160 μm, at least 165 μm, at least 170 μm, at least 175 μm, at least 180 μm, at least 185 μm, at least 190 μm, at least 195 μm, at least 200 μm, at least 205 μm, at least 210 μm, at least 215 μm, at least 220 μm, at least 225 μm, at least 230 μm, at least 235 μm, at least 240 μm, at least 245 μm, at least 250 μm, at least 255 μm, at least 260 μm, at least 265 μm, at least 270 μm, at least 275 μm, at least 280 μm, at least 285 μm, at least 290 μm, at least 295 μm, at least 300 μm, at least 305 μm, at least 310 μm, at least 315 μm, at least 320 μm, at least 325 μm, at least 330 μm, at least 335 μm, at least 340 μm, at least 345 μm, at least 350 μm, at least 355 μm, at least 360 μm, at least 365 μm, at least 370 μm, at least 375 μm, at least 380 μm, at least 385 μm, at least 390 μm, at least 395 μm, at least 400 μm, at least 405 μm, at least 410 μm, at least 415 μm, at least 420 μm, at least 425 μm, at least 430 μm, at least 435 μm, at least 440 μm, at least 445 μm, at least 450 μm, at least 455 μm, at least 460 μm, at least 465 μm, at least 470 μm, at least 475 μm, at least 480 μm, at least 485 μm, at least 490 μm, at least 495 μm, at least 500 μm, at least 505 μm, at least 510 μm, at least 515 μm, at least 520 μm, at least 525 μm, at least 530 μm, at least 535 μm, at least 540 μm, at least 545 μm, at least 550 μm, at least 555 μm, at least 560 μm, at least 565 μm, at least 570 μm, at least 575 μm, at least 580 μm, at least 585 μm, at least 590 μm, at least 595 μm, at least 600 μm, at least 605 μm, at least 610 μm, at least 615 μm, at least 620 μm, at least 625 μm, at least 630 μm, at least 635 μm, at least 640 μm, at least 645 μm, at least 650 μm, at least 655 μm, at least 660 μm, at least 665 μm, at least 670 μm, at least 675 μm, at least 680 μm, at least 685 μm, at least 690 μm, at least 695 μm, at least 700 μm, at least 705 μm, at least 710 μm, at least 715 μm, at least 720 μm, at least 725 μm, at least 730 μm, at least 735 μm, at least 740 μm, at least 745 μm, at least 750 μm, at least 755 μm, at least 760 μm, at least 765 μm, at least 770 μm, at least 775 μm, at least 780 μm, at least 785 μm, at least 790 μm, at least 795 μm, at least 800 μm, at least 805 μm, at least 810 μm, at least 815 μm, at least 820 μm, at least 825 μm, at least 830 μm, at least 835 μm, at least 840 μm, at least 845 μm, at least 850 μm, at least 855 μm, at least 860 μm, at least 865 μm, at least 870 μm, at least 875 μm, at least 880 μm, at least 885 μm, at least 890 μm, at least 895 μm, at least 900 μm, at least 905 μm, at least 910 μm, at least 915 μm, at least 920 μm, at least 925 μm, at least 930 μm, at least 935 μm, at least 940 μm, at least 945 μm, at least 950 μm, at least 955 μm, at least 960 μm, at least 965 μm, at least 970 μm, at least 975 μm, at least 980 μm, at least 985 μm, at least 990 μm, at least 995 μm, or at least 1,000 μm.

In some embodiments, the nominal diameter or width of a cross-section T2 of the channel 210 is at most 100 μm, at most 105 μm, at most 110 μm, at most 115 μm, at most 120 μm, at most 125 μm, at most 130 μm, at most 135 μm, at most 140 μm, at most 145 μm, at most 150 μm, at most 155 μm, at most 160 μm, at most 165 μm, at most 170 μm, at most 175 μm, at most 180 μm, at most 185 μm, at most 190 μm, at most 195 μm, at most 200 μm, at most 205 μm, at most 210 μm, at most 215 μm, at most 220 μm, at most 225 μm, at most 230 μm, at most 235 μm, at most 240 μm, at most 245 μm, at most 250 μm, at most 255 μm, at most 260 μm, at most 265 μm, at most 270 μm, at most 275 μm, at most 280 μm, at most 285 μm, at most 290 μm, at most 295 μm, at most 300 μm, at most 305 μm, at most 310 μm, at most 315 μm, at most 320 μm, at most 325 μm, at most 330 μm, at most 335 μm, at most 340 μm, at most 345 μm, at most 350 μm, at most 355 μm, at most 360 μm, at most 365 μm, at most 370 μm, at most 375 μm, at most 380 μm, at most 385 μm, at most 390 μm, at most 395 μm, at most 400 μm, at most 405 μm, at most 410 μm, at most 415 μm, at most 420 μm, at most 425 μm, at most 430 μm, at most 435 μm, at most 440 μm, at most 445 μm, at most 450 μm, at most 455 μm, at most 460 μm, at most 465 μm, at most 470 μm, at most 475 μm, at most 480 μm, at most 485 μm, at most 490 μm, at most 495 μm, at most 500 μm, at most 505 μm, at most 510 μm, at most 515 μm, at most 520 μm, at most 525 μm, at most 530 μm, at most 535 μm, at most 540 μm, at most 545 μm, at most 550 μm, at most 555 μm, at most 560 μm, at most 565 μm, at most 570 μm, at most 575 μm, at most 580 μm, at most 585 μm, at most 590 μm, at most 595 μm, at most 600 μm, at most 605 μm, at most 610 μm, at most 615 μm, at most 620 μm, at most 625 μm, at most 630 μm, at most 635 μm, at most 640 μm, at most 645 μm, at most 650 μm, at most 655 μm, at most 660 μm, at most 665 μm, at most 670 μm, at most 675 μm, at most 680 μm, at most 685 μm, at most 690 μm, at most 695 μm, at most 700 μm, at most 705 μm, at most 710 μm, at most 715 μm, at most 720 μm, at most 725 μm, at most 730 μm, at most 735 μm, at most 740 μm, at most 745 μm, at most 750 μm, at most 755 μm, at most 760 μm, at most 765 μm, at most 770 μm, at most 775 μm, at most 780 μm, at most 785 μm, at most 790 μm, at most 795 μm, at most 800 μm, at most 805 μm, at most 810 μm, at most 815 μm, at most 820 μm, at most 825 μm, at most 830 μm, at most 835 μm, at most 840 μm, at most 845 μm, at most 850 μm, at most 855 μm, at most 860 μm, at most 865 μm, at most 870 μm, at most 875 μm, at most 880 μm, at most 885 μm, at most 890 μm, at most 895 μm, at most 900 μm, at most 905 μm, at most 910 μm, at most 915 μm, at most 920 μm, at most 925 μm, at most 930 μm, at most 935 μm, at most 940 μm, at most 945 μm, at most 950 μm, at most 955 μm, at most 960 μm, at most 965 μm, at most 970 μm, at most 975 μm, at most 980 μm, at most 985 μm, at most 990 μm, at most 995 μm, or at least 1,000 μm.

Moreover, in some embodiments, the interior layer 350-1 of the first set of layers 310-1 and/or the interior layer 350-2 of the second set of layers 310-2 each includes a wicking composition. For instance, in some embodiments, the wicking composition of the interior layer 350-1 of the first set of layers 310-1 and/or the interior layer 350-2 of the second set of layers 310-2 allows for conveyance (e.g., transfer, flow, etc.) of the medium within the channel 210 between the first circuit component 200-1 and the second circuit component 200-2 via the interior layer 350.

As a non-limiting example, in some embodiments, the wicking composition provides porosity to the interior layer 350 that allows for the interior layer 350 to absorb or draw the medium through the channel 210 of the deformable substrate 202 by capillary action, which is caused by cohesion of molecules of the medium, and the adhesion of such molecules on the surface of the interior layer 350. As such, having the porous wicking composition provides for increased surface area of the surface of the interior layer 350 that adheres to the molecules of the medium, which allows for transfer of the medium when the adhesion is greater than the cohesion, the medium wets the surface of the interior layer 350 and traverse the surface. Accordingly, in some embodiments, a material wets a surface (e.g., surface of deformable substrate 202) when the adhesion of molecules of the material at the surface of the deformable substrate 202 is greater than the cohesion of the molecules at an interior of the material.

In some embodiments, the porosity of the wicking composition is between 50% and 99%, between 50% and 95%, between 50% and 90%, between 50% and 85%, between 50% and 80%, between 50% and 75%, between 50% and 70%, between 50% and 65%, between 50% and 60%, between 50% and 55%, between 55% and 99%, between 55% and 95%, between 55% and 90%, between 55% and 85%, between 55% and 80%, between 55% and 75%, between 55% and 70%, between 55% and 65%, between 55% and 60%, between 60% and 99%, between 60% and 95%, between 60% and 90%, between 60% and 85%, between 60% and 80%, between 60% and 75%, between 60% and 70%, between 60% and 65%, between 60% and 60%, between 60% and 55%, between 65% and 99%, between 65% and 95%, between 65% and 90%, between 65% and 85%, between 65% and 80%, between 65% and 75%, between 65% and 70%, between 70% and 99%, between 70% and 95%, between 70% and 90%, between 70% and 85%, between 70% and 80%, between 70% and 75%, between 75% and 99%, between 75% and 95%, between 75% and 90%, between 75% and 85%, between 75% and 80%, between 80% and 99%, between 80% and 95%, between 80% and 90%, between 80% and 85%, between 85% and 99%, between 85% and 95%, between 85% and 90%, between 90% and 99%, between 90% and 95%, or between 95% and 99%. In some embodiments, the porosity of the wicking composition is at least 50%, at least 55%, at least 60%, at least 65%, at least 70%, at least 75%, at least 80%, at least 85%, at least 90%, at least 95%, or at least 99%. In some embodiments, the porosity of the wicking composition is at most 50%, at most 55%, at most 60%, at most 65%, at most 70%, at most 75%, at most 80%, at most 85%, at most 90%, at most 95%, or at most 99%.

In some embodiments, the interior layer 350-1 of the first set of layers 310-1 and the interior layer 350-2 of the second set of layers 310-2 includes PDMS, polyvinyl alcohol (PVA), polyethylene glycol (PEG), hydroxyethyl methacrylate (HEMA), one or more polymer mesh weaves, one or more non-woven fiber mats, one or more surface modified hydrophobic polymers, polyolefin, one or more surface modified elastomers, or a combination thereof. For instance, in some embodiments, the interior layer 350 includes one or more natural fiber reinforced compositions, such as felt, which allows for wicking of the medium through the channel 210.

In some embodiments, the interior layer 350-1 of the first set of layers 310-1 and the interior layer 350-2 of the second set of layers 310-2 includes a contact angle of less than 50 degrees (°) when interfacing with a different composition, which allows for the different composition to wet the surface of the interior layer 350-1 of the first set of layers 310-1 and the surface of the interior layer 350-2 of the second set of layers 310-2. For instance, in some embodiments, the first interior layer 350-1 of the first set of layers 310-1 and/or the interior layer 350-2 of the second set of layers 310-2 includes PDMS, PV, PEG, HEMA, the one or more polymer mesh weaves, the one or more non-woven fiber mats, the one or more surface modified hydrophobic polymers, the polyolefin, the one or more surface modified elastomers, or the combination thereof and the contact angle is the angle at which the liquid-vapor interface meets the surface of the first interior layer 350-1 of the first set of layers 310-1 and/or the interior layer 350-2 of the second set of layers 310-2.

In some embodiments, the contact angle between the different composition and the interior layer 350-1 of the first set of layers 310-1 and the interior layer 350-2 of the second set of layers 310-2 is between 1% and 50%, 1% and 40%, 1% and 30%, 1% and 20%, 1% and 10%, 1% and 5%, between 5% and 50%, 5% and 40%, 5% and 30%, 5% and 20%, 5% and 10%, between 15% and 50%, 15% and 40%, 15% and 30%, 15% and 20%, between 25% and 50%, 25% and 40%, 25% and 30%, between 35% and 50%, 35% and 40%, or between 45% and 50%. In some embodiments, the contact angle between the different composition and the interior layer 350-1 of the first set of layers 310-1 and the interior layer 350-2 of the second set of layers 310-2 is at least 1%, at least 5%, at least 10%, at least 15%, at least 20%, at least 25%, at least 30%, at least 35%, at least 40%, at least 45%, or at least 50%. In some embodiments, the contact angle between the different composition and the interior layer 350-1 of the first set of layers 310-1 and the interior layer 350-2 of the second set of layers 310-2 is at most 1%, at most 5%, at most 10%, at most 15%, at most 20%, at most 25%, at most 30%, at most 35%, at most 40%, at most 45%, or at most 50%.

In some such embodiments, the different composition is the medium accommodated by the channel 210.

In some embodiments, the interior layer 350-1 of the first set of layers 310-1 and the interior layer 350-2 of the second set of layers 310-2 covers the medium of the channel 210 from the first end portion of the channel 210 to the second end portion of the channel 210, such as from the right hand side of FIG. 3A to the left hand side of FIG. 3A, or from the first circuit component 200-1 or the second circuit component 200-2, or the like.

In some embodiments, the interior layer 350-1 of the first set of layers 310-1 and/or the interior layer 350-2 of the second set of layers 310-2 is configured to maintain conductivity through the deformable substrate 202, including through the channel 210, with resistance under at most 50 Ohms per cm (Ω/cm), at most 100 Ohms per cm (Ω/cm), or at most 150 Ohms per cm (Ω/cm) when subjected to 100% strain. Accordingly, in some such embodiments, since the deformable substrate 202 is capable of maintaining conductivity when subjected to 100% strain through the interior layer 350 of each set of layers 310, the deformable substrate 202 is capable of being utilized in wearable electronic device 100 that physically deforms when worn by the subject.

For instance, in some embodiments, the interior layer 350-1 of the first set of layers 310-1 and/or the interior layer 350-2 of the second set of layers 310-2 is configured to maintain conductivity with resistance of between 0.1 Ω/cm and 100 Ω/cm, between 0.1 Ω/cm and 90 Ω/cm, between 0.1 Ω/cm and 700 Ω/cm, between 0.1 Ω/cm and 50 Ω/cm, between 0.1 Ω/cm and 40 Ω/cm, between 0.1 Ω/cm and 30 Ω/cm, between 0.1 Ω/cm and 25 Ω/cm, between 0.1 Ω/cm and 20 Ω/cm, between 0.1 Ω/cm and 10 Ω/cm, between 0.1 Ω/cm and 5 Ω/cm, between 0.1 Ω/cm and 3 Ω/cm, between 0.5 Ω/cm and 100 Ω/cm, between 0.5 Ω/cm and 90 Ω/cm, between 0.5 Ω/cm and 70 Ω/cm, between 0.5 Ω/cm and 50 Ω/cm, between 0.5 Ω/cm and 40 Ω/cm, between 0.5 Ω/cm and 30 Ω/cm, between 0.5 Ω/cm and 25 Ω/cm, between 0.5 Ω/cm and 20 Ω/cm, between 0.5 Ω/cm and 10 Ω/cm, between 0.5 Ω/cm and 5 Ω/cm, between 0.5 Ω/cm and 3 Ω/cm, between 1 Ω/cm and 100 Ω/cm, between 1 Ω/cm and 90 Ω/cm, between 1 Ω/cm and 70 Ω/cm, between 1 Ω/cm and 50 Ω/cm, between 1 Ω/cm and 40 Ω/cm, between 1 Ω/cm and 30 Ω/cm, between 1 Ω/cm and 25 Ω/cm, between 1 Ω/cm and 20 Ω/cm, between 1 Ω/cm and 10 Ω/cm, between 1 Ω/cm and 5 Ω/cm, between 1 Ω/cm and 3 Ω/cm, between 2.5 Ω/cm and 100 Ω/cm, between 2.5 Ω/cm and 90 Ω/cm, between 2.5 Ω/cm and 70 Ω/cm, between 2.5 Ω/cm and 50 Ω/cm, between 2.5 Ω/cm and 40 Ω/cm, between 2.5 Ω/cm and 30 Ω/cm, between 2.5 Ω/cm and 25 Ω/cm, between 2.5 Ω/cm and 20 Ω/cm, between 2.5 Ω/cm and 10 Ω/cm, between 2.5 Ω/cm and 5 Ω/cm, between 2.5 Ω/cm and 3 Ω/cm, between 8 Ω/cm and 100 Ω/cm, between 8 Ω/cm and 90 Ω/cm, between 8 Ω/cm and 70 Ω/cm, between 8 Ω/cm and 50 Ω/cm, between 8 Ω/cm and 40 Ω/cm, between 8 Ω/cm and 30 Ω/cm, between 8 Ω/cm and 25 Ω/cm, between 8 Ω/cm and 20 Ω/cm, between 8 Ω/cm and 10 Ω/cm, between 13 Ω/cm and 100 Ω/cm, between 13 Ω/cm and 90 Ω/cm, between 13 Ω/cm and 70 Ω/cm, between 13 Ω/cm and 50 Ω/cm, between 13 Ω/cm and 40 Ω/cm, between 13 Ω/cm and 30 Ω/cm, between 13 Ω/cm and 25 Ω/cm, between 13 Ω/cm and 20 Ω/cm, between 25 Ω/cm and 100 Ω/cm, between 25 Ω/cm and 90 Ω/cm, between 25 Ω/cm and 70 Ω/cm, between 25 Ω/cm and 50 Ω/cm, between 25 Ω/cm and 40 Ω/cm, between 25 Ω/cm and 30 Ω/cm, between 45 Ω/cm and 100 Ω/cm, between 45 Ω/cm and 90 Ω/cm, between 45 Ω/cm and 70 Ω/cm, between 45 Ω/cm and 50 Ω/cm, between 60 Ω/cm and 100 Ω/cm, between 60 Ω/cm and 90 Ω/cm, between 60 Ω/cm and 70 Ω/cm, between 85 Ω/cm and 100 Ω/cm, or between 85 Ω/cm and 90 Ω/cm when the deformable substrate 202 is subjected to 100% strain.

In some embodiments, the interior layer 350-1 of the first set of layers 310-1 and/or the interior layer 350-2 of the second set of layers 310-2 is configured to maintain conductivity, including through the channel 210, with resistance of at least 0.1 Ω/cm, at least 0.4 Ω/cm, at least 0.8 Ω/cm, at least 1 Ω/cm, at least 1.5 Ω/cm, at least 2 Ω/cm, at least 2.5 Ω/cm, at least 3 Ω/cm, at least 3.5 Ω/cm, at least 4 Ω/cm, at least 4.5 Ω/cm, at least 5 Ω/cm, at least 5.5 Ω/cm, at least 6 Ω/cm, at least 6.5 Ω/cm, at least 7 Ω/cm, at least 7.5 Ω/cm, at least 8 Ω/cm, at least 8.5 Ω/cm, at least 9 Ω/cm, at least 9.5 Ω/cm, at least 10 Ω/cm, at least 10.5 Ω/cm, at least 11 Ω/cm, at least 11.5 Ω/cm, at least 12 Ω/cm, at least 12.5 Ω/cm, at least 13 Ω/cm, at least 13.5 Ω/cm, at least 14 Ω/cm, at least 14.5 Ω/cm, at least 15 Ω/cm, at least 15.5 Ω/cm, at least 16 Ω/cm, at least 16.5 Ω/cm, at least 17 Ω/cm, at least 17.5 Ω/cm, at least 18 Ω/cm, at least 18.5 Ω/cm, at least 19 Ω/cm, at least 19.5 Ω/cm, at least 20 Ω/cm, at least 20.5 Ω/cm, at least 21 Ω/cm, at least 21.5 Ω/cm, at least 22 Ω/cm, at least 22.5 Ω/cm, at least 23 Ω/cm, at least 23.5 Ω/cm, at least 24 Ω/cm, at least 24.5 Ω/cm, at least 25 Ω/cm, at least 25.5 Ω/cm, at least 26 Ω/cm, at least 26.5 Ω/cm, at least 27 Ω/cm, at least 27.5 Ω/cm, at least 28 Ω/cm, at least 28.5 Ω/cm, at least 29 Ω/cm, at least 29.5 Ω/cm, at least 30 Ω/cm, at least 30.5 Ω/cm, at least 31 Ω/cm, at least 31.5 Ω/cm, at least 32 Ω/cm, at least 32.5 Ω/cm, at least 33 Ω/cm, at least 33.5 Ω/cm, at least 34 Ω/cm, at least 34.5 Ω/cm, at least 35 Ω/cm, at least 35.5 Ω/cm, at least 36 Ω/cm, at least 36.5 Ω/cm, at least 37 Ω/cm, at least 37.5 Ω/cm, at least 38 Ω/cm, at least 38.5 Ω/cm, at least 39 Ω/cm, at least 39.5 Ω/cm, at least 40 Ω/cm, at least 40.5 Ω/cm, at least 41 Ω/cm, at least 41.5 Ω/cm, at least 42 Ω/cm, at least 42.5 Ω/cm, at least 43 Ω/cm, at least 43.5 Ω/cm, at least 44 Ω/cm, at least 44.5 Ω/cm, at least 45 Ω/cm, at least 45.5 Ω/cm, at least 46 Ω/cm, at least 46.5 Ω/cm, at least 47 Ω/cm, at least 47.5 Ω/cm, at least 48 Ω/cm, at least 48.5 Ω/cm, at least 49 Ω/cm, at least 49.5 Ω/cm, at least 50 Ω/cm, at least 50.5 Ω/cm, at least 51 Ω/cm, at least 51.5 Ω/cm, at least 52 Ω/cm, at least 52.5 Ω/cm, at least 53 Ω/cm, at least 53.5 Ω/cm, at least 54 Ω/cm, at least 54.5 Ω/cm, at least 55 Ω/cm, at least 55.5 Ω/cm, at least 56 Ω/cm, at least 56.5 Ω/cm, at least 57 Ω/cm, at least 57.5 Ω/cm, at least 58 Ω/cm, at least 58.5 Ω/cm, at least 59 Ω/cm, at least 59.5 Ω/cm, at least 60 Ω/cm, at least 60.5 Ω/cm, at least 61 Ω/cm, at least 61.5 Ω/cm, at least 62 Ω/cm, at least 62.5 Ω/cm, at least 63 Ω/cm, at least 63.5 Ω/cm, at least 64 Ω/cm, at least 64.5 Ω/cm, at least 65 Ω/cm, at least 65.5 Ω/cm, at least 66 Ω/cm, at least 66.5 Ω/cm, at least 67 Ω/cm, at least 67.5 Ω/cm, at least 68 Ω/cm, at least 68.5 Ω/cm, at least 69 Ω/cm, at least 69.5 Ω/cm, at least 70 Ω/cm, at least 70.5 Ω/cm, at least 71 Ω/cm, at least 71.5 Ω/cm, at least 72 Ω/cm, at least 72.5 Ω/cm, at least 73 Ω/cm, at least 73.5 Ω/cm, at least 74 Ω/cm, at least 74.5 Ω/cm, at least 75 Ω/cm, at least 75.5 Ω/cm, at least 76 Ω/cm, at least 76.5 Ω/cm, at least 77 Ω/cm, at least 77.5 Ω/cm, at least 78 Ω/cm, at least 78.5 Ω/cm, at least 79 Ω/cm, at least 79.5 Ω/cm, at least 80 Ω/cm, at least 80.5 Ω/cm, at least 81 Ω/cm, at least 81.5 Ω/cm, at least 82 Ω/cm, at least 82.5 Ω/cm, at least 83 Ω/cm, at least 83.5 Ω/cm, at least 84 Ω/cm, at least 84.5 Ω/cm, at least 85 Ω/cm, at least 85.5 Ω/cm, at least 86 Ω/cm, at least 86.5 Ω/cm, at least 87 Ω/cm, at least 87.5 Ω/cm, at least 88 Ω/cm, at least 88.5 Ω/cm, at least 89 Ω/cm, at least 89.5 Ω/cm, at least 90 Ω/cm, at least 90.5 Ω/cm, at least 91 Ω/cm, at least 91.5 Ω/cm, at least 92 Ω/cm, at least 92.5 Ω/cm, at least 93 Ω/cm, at least 93.5 Ω/cm, at least 94 Ω/cm, at least 94.5 Ω/cm, at least 95 Ω/cm, at least 95.5 Ω/cm, at least 96 Ω/cm, at least 96.5 Ω/cm, at least 97 Ω/cm, at least 97.5 Ω/cm, at least 98 Ω/cm, at least 98.5 Ω/cm, at least 99 Ω/cm, at least 99.5 Ω/cm, or at least 100 Ω/cm when the deformable substrate 202 is subjected to 100% strain.

In some embodiments, the interior layer 350-1 of the first set of layers 310-1 and/or the interior layer 350-2 of the second set of layers 310-2 is configured to maintain conductivity with resistance, including through channel 320, of at most 0.1 Ω/cm, at most 0.4 Ω/cm, at most 0.8 Ω/cm, at most 1 Ω/cm, at most 1.5 Ω/cm, at most 2 Ω/cm, at most 2.5 Ω/cm, at most 3 Ω/cm, at most 3.5 Ω/cm, at most 4 Ω/cm, at most 4.5 Ω/cm, at most 5 Ω/cm, at most 5.5 Ω/cm, at most 6 Ω/cm, at most 6.5 Ω/cm, at most 7 Ω/cm, at most 7.5 Ω/cm, at most 8 Ω/cm, at most 8.5 Ω/cm, at most 9 Ω/cm, at most 9.5 Ω/cm, at most 10 Ω/cm, at most 10.5 Ω/cm, at most 11 Ω/cm, at most 11.5 Ω/cm, at most 12 Ω/cm, at most 12.5 Ω/cm, at most 13 Ω/cm, at most 13.5 Ω/cm, at most 14 Ω/cm, at most 14.5 Ω/cm, at most 15 Ω/cm, at most 15.5 Ω/cm, at most 16 Ω/cm, at most 16.5 Ω/cm, at most 17 Ω/cm, at most 17.5 Ω/cm, at most 18 Ω/cm, at most 18.5 Ω/cm, at most 19 Ω/cm, at most 19.5 Ω/cm, at most 20 Ω/cm, at most 20.5 Ω/cm, at most 21 Ω/cm, at most 21.5 Ω/cm, at most 22 Ω/cm, at most 22.5 Ω/cm, at most 23 Ω/cm, at most 23.5 Ω/cm, at most 24 Ω/cm, at most 24.5 Ω/cm, at most 25 Ω/cm, at most 25.5 Ω/cm, at most 26 Ω/cm, at most 26.5 Ω/cm, at most 27 Ω/cm, at most 27.5 Ω/cm, at most 28 Ω/cm, at most 28.5 Ω/cm, at most 29 Ω/cm, at most 29.5 Ω/cm, at most 30 Ω/cm, at most 30.5 Ω/cm, at most 31 Ω/cm, at most 31.5 Ω/cm, at most 32 Ω/cm, at most 32.5 Ω/cm, at most 33 Ω/cm, at most 33.5 Ω/cm, at most 34 Ω/cm, at most 34.5 Ω/cm, at most 35 Ω/cm, at most 35.5 Ω/cm, at most 36 Ω/cm, at most 36.5 Ω/cm, at most 37 Ω/cm, at most 37.5 Ω/cm, at most 38 Ω/cm, at most 38.5 Ω/cm, at most 39 Ω/cm, at most 39.5 Ω/cm, at most 40 Ω/cm, at most 40.5 Ω/cm, at most 41 Ω/cm, at most 41.5 Ω/cm, at most 42 Ω/cm, at most 42.5 Ω/cm, at most 43 Ω/cm, at most 43.5 Ω/cm, at most 44 Ω/cm, at most 44.5 Ω/cm, at most 45 Ω/cm, at most 45.5 Ω/cm, at most 46 Ω/cm, at most 46.5 Ω/cm, at most 47 Ω/cm, at most 47.5 Ω/cm, at most 48 Ω/cm, at most 48.5 Ω/cm, at most 49 Ω/cm, at most 49.5 Ω/cm, at most 50 Ω/cm, at most 50.5 Ω/cm, at most 51 Ω/cm, at most 51.5 Ω/cm, at most 52 Ω/cm, at most 52.5 Ω/cm, at most 53 Ω/cm, at most 53.5 Ω/cm, at most 54 Ω/cm, at most 54.5 Ω/cm, at most 55 Ω/cm, at most 55.5 Ω/cm, at most 56 Ω/cm, at most 56.5 Ω/cm, at most 57 Ω/cm, at most 57.5 Ω/cm, at most 58 Ω/cm, at most 58.5 Ω/cm, at most 59 Ω/cm, at most 59.5 Ω/cm, at most 60 Ω/cm, at most 60.5 Ω/cm, at most 61 Ω/cm, at most 61.5 Ω/cm, at most 62 Ω/cm, at most 62.5 Ω/cm, at most 63 Ω/cm, at most 63.5 Ω/cm, at most 64 Ω/cm, at most 64.5 Ω/cm, at most 65 Ω/cm, at most 65.5 Ω/cm, at most 66 Ω/cm, at most 66.5 Ω/cm, at most 67 Ω/cm, at most 67.5 Ω/cm, at most 68 Ω/cm, at most 68.5 Ω/cm, at most 69 Ω/cm, at most 69.5 Ω/cm, at most 70 Ω/cm, at most 70.5 Ω/cm, at most 71 Ω/cm, at most 71.5 Ω/cm, at most 72 Ω/cm, at most 72.5 Ω/cm, at most 73 Ω/cm, at most 73.5 Ω/cm, at most 74 Ω/cm, at most 74.5 Ω/cm, at most 75 Ω/cm, at most 75.5 Ω/cm, at most 76 Ω/cm, at most 76.5 Ω/cm, at most 77 Ω/cm, at most 77.5 Ω/cm, at most 78 Ω/cm, at most 78.5 Ω/cm, at most 79 Ω/cm, at most 79.5 Ω/cm, at most 80 Ω/cm, at most 80.5 Ω/cm, at most 81 Ω/cm, at most 81.5 Ω/cm, at most 82 Ω/cm, at most 82.5 Ω/cm, at most 83 Ω/cm, at most 83.5 Ω/cm, at most 84 Ω/cm, at most 84.5 Ω/cm, at most 85 Ω/cm, at most 85.5 Ω/cm, at most 86 Ω/cm, at most 86.5 Ω/cm, at most 87 Ω/cm, at most 87.5 Ω/cm, at most 88 Ω/cm, at most 88.5 Ω/cm, at most 89 Ω/cm, at most 89.5 Ω/cm, at most 90 Ω/cm, at most 90.5 Ω/cm, at most 91 Ω/cm, at most 91.5 Ω/cm, at most 92 Ω/cm, at most 92.5 Ω/cm, at most 93 Ω/cm, at most 93.5 Ω/cm, at most 94 Ω/cm, at most 94.5 Ω/cm, at most 95 Ω/cm, at most 95.5 Ω/cm, at most 96 Ω/cm, at most 96.5 Ω/cm, at most 97 Ω/cm, at most 97.5 Ω/cm, at most 98 Ω/cm, at most 98.5 Ω/cm, at most 99 Ω/cm, at most 99.5 Ω/cm, or at most 100 Ω/cm when the deformable substrate 202 subjected to 100% strain.

In some embodiments, the interior layer 350-1 of the first set of layers 310-1 and/or the interior layer 350-2 of the second set of layers 310-2, including the medium of the channel 210, is free of degradation in conductivity when the deformable substrate 202 is bent, such as bent around a cylinder. In some embodiments, t the interior layer 350-1 of the first set of layers 310-1 and/or the interior layer 350-2 of the second set of layers 310-2, including the medium of the channel 210, is free of degradation in conductivity when the deformable substrate 202 is that has a radius of between 2 and 25 centimeters (cm), between 2 cm and 10 cm, between 2 cm and 8 cm, between 2 cm and 6 cm, between 2 cm and 4 cm, 4 cm and 10 cm, between 4 cm and 8 cm, between 4 cm and 6 cm, between 6 cm and 10 cm, between 6 cm and 8 cm, between 8 cm and 10 cm, between 10 cm and 25 cm, between 10 cm and 20 cm, between 15 cm and 25 cm, or between 15 cm and 20 cm for a period of time and then released. In some embodiments, the radius of the cylinder is at least 2 cm, at least 3 cm, at least 4 cm, at least 5 cm, at least 6 cm, at least 7 cm, at least 8 cm, at least 9 cm, at least 10 cm, at least 11 cm, at least 12 cm, at least 13 cm, at least 14 cm, at least 15 cm, at least 16 cm, at least 17 cm, at least 18 cm, at least 19 cm, at least 20 cm, at least 21 cm, at least 22 cm, at least 23 cm, at least 24 cm, or at least 25 cm. In some embodiments, the radius of the cylinder is at most 2 cm, at most 3 cm, at most 4 cm, at most 5 cm, at most 6 cm, at most 7 cm, at most 8 cm, at most 9 cm, at most 10 cm, at most 11 cm, at most 12 cm, at most 13 cm, at most 14 cm, at most 15 cm, at most 16 cm, at most 17 cm, at most 18 cm, at most 19 cm, at most 20 cm, at most 21 cm, at most 22 cm, at most 23 cm, at most 24 cm, or at most 25 cm. In some embodiments, the cylinder is similar or substantially similar to the size of a human wrist, such as a first diameter associated with an adult male wrist size or a second diameter associated with an adult woman wrist size. For instance, in some embodiments, the cylinder has a diameter of about 17.42 plus or minus (±) 0.83 cm, or 15.12 cm±0.69 cm, in which the diameter of the cylinder is determined at a point perpendicular to the longitudinal axis of the cylinder.

In some embodiments, the period of time is between 10 seconds and 5 minutes, between 10 seconds and 4 minutes, between 10 seconds and 3 minutes, between 10 seconds and 2 minutes, between 10 seconds and 1 minute, between 10 seconds and 30 seconds, between 30 seconds and 5 minutes, between 10 seconds and 4 minutes, between 10 seconds and 3 minutes, between 10 seconds and 2 minutes, between 10 seconds and 1 minute, between 1 minute and 5 minutes, between 1 minute and 4 minutes, between 1 minute and 3 minutes, between 1 minute and 2 minutes, or between 3 minutes and 5 minutes. In some embodiments, the period of time is at least 10 seconds, at least 20 seconds, at least 30 seconds, at least 60 seconds, at least 1.5 minutes, at least 2 minutes, at least 2.5 minutes, at least 3 minutes, at least 3.5 minutes, at least 4 minutes, at least 4.5 minutes, or at least 5 minutes. In some embodiments, the period of time is at most 10 seconds, at most 20 seconds, at most 30 seconds, at most 60 seconds, at most 1.5 minutes, at most 2 minutes, at most 2.5 minutes, at most 3 minutes, at most 3.5 minutes, at most 4 minutes, at most 4.5 minutes, or at most 5 minutes. However, the present disclosure is not limited thereto. In some embodiments, the period of time is between 5 minutes and 2 hours, between 30 minutes and 2 hours, or between 45 minutes and 90 minutes. Accordingly, the deformable substrate 202 of the present disclosure is capable of providing electronic communication free of degradation in conductivity through the channel 210 when subjected to prolonged elongation for an extended period of time, which allows for the deformable substrate 202 to be incorporated into every-day use electronic devices 100.

In some embodiments, the interior layer 350-1 of the first set of layers 310-1 and/or the interior layer 350-2 of the second set of layers 310-2 is free of degradation in conductivity when a first conductivity of the interior layer 350-1 of the first set of layers 310-1 and/or the interior layer 350-2 of the second set of layers 310-2 before bending and a second conductivity of the interior layer 350-1 of the first set of layers 310-1 and/or the interior layer 350-2 of the second set of layers 310-2 after or during bending is substantially the same. For instance, in some embodiments, the interior layer 350-1 of the first set of layers 310-1 and/or the interior layer 350-2 of the second set of layers 310-2 is free of degradation when the second conductivity satisfies a threshold ratio in comparison against the first conductivity of the interior layer 350-1 of the first set of layers 310-1 and/or the interior layer 350-2 of the second set of layers 310-2. In some embodiments, the threshold ratio is between 0.99 and 1.01, between 0.995 and 1.005, or between 0.999 and 1.001. In some embodiments, the threshold ratio is at least 0.95, at least 0.96, at least 0.97, at least 0.98, at least 0.99, at least 0.999, at least 0.9999, at least 1, at least 1.0001, at least 1.001, at least 1.01, at least 1.02, at least 1.03, at least 1.04, at least 1.05, or at least 1.1. In some embodiments, the threshold ratio is at most 0.95, at most 0.96, at most 0.97, at most 0.98, at most 0.99, at most 0.999, at most 0.9999, at most 1, at most 1.0001, at most 1.001, at most 1.01, at most 1.02, at most 1.03, at most 1.04, at most 1.05, or at most 1.1.

In some embodiments, the strain (ε) is defined as a function of a change in gauge length (δ) against an original gauge length (L), such as:

$$ε = \frac{δ}{L} .$$

For instance, in some embodiments, a strain of X % means a change in length of the deformable substrate 202 as a function of an original length of the deformable substrate 202, where X is a number between 0 and 100. In some embodiments, the strain of X % means a change in width of the deformable substrate 202 as a function of an original width of the deformable substrate 202. In some embodiments, the strain of X % means a change in depth of the deformable substrate 202 as a function of an original depth of the deformable substrate 202. As a non-limiting example, if an original length of the deformable substrate 202 is 10 cm and is subjected to 100% strain to stretch to a new length of 20 cm. However, the present disclosure is not limited thereto.

In some embodiments, the strain is uniaxial or biaxial. In some embodiments, each axis in the biaxial direction is parallel to gravity, substantially parallel to gravity, perpendicular to gravity, or substantially perpendicular to gravity.

In some embodiments, the deformable substrate 202 is configured to maintain conductivity through the interior layer 350-1 of the first set of layers 310-1 and/or the interior layer 350-2 of the second set of layers 310-2, including through the channel 210, when subjected to at least 15,000 strain cycles.

For instance, in some embodiments, the deformable substrate 202 is configured to maintain conductivity through the interior layer 350-1 of the first set of layers 310-1 and/or the interior layer 350-2 of the second set of layers 310-2, including through the channel 210, when subjected to between 2 strain cycles and 30,000 strain cycles, between 2 strain cycles and 20,000 strain cycles, between 2 strain cycles and 15,000 strain cycles, between 2 strain cycles and 10,000 strain cycles, between 2 strain cycles and 6,000 strain cycles, between 2 strain cycles and 4,000 strain cycles, between 2 strain cycles and 1,000 strain cycles, between 2 strain cycles and 700 strain cycles, between 2 strain cycles and 500 strain cycles, between 2 strain cycles and 100 strain cycles, between 50 strain cycles and 30,000 strain cycles, between 50 strain cycles and 20,000 strain cycles, between 50 strain cycles and 15,000 strain cycles, between 50 strain cycles and 10,000 strain cycles, between 50 strain cycles and 6,000 strain cycles, between 50 strain cycles and 4,000 strain cycles, between 50 strain cycles and 1,000 strain cycles, between 50 strain cycles and 700 strain cycles, between 50 strain cycles and 500 strain cycles, between 50 strain cycles and 100 strain cycles, between 850 strain cycles and 30,000 strain cycles, between 850 strain cycles and 20,000 strain cycles, between 850 strain cycles and 15,000 strain cycles, between 850 strain cycles and 10,000 strain cycles, between 850 strain cycles and 6,000 strain cycles, between 850 strain cycles and 4,000 strain cycles, between 850 strain cycles and 1,000 strain cycles, between 2,000 strain cycles and 30,000 strain cycles, between 2,000 strain cycles and 20,000 strain cycles, between 2,000 strain cycles and 15,000 strain cycles, between 2,000 strain cycles and 10,000 strain cycles, between 2,000 strain cycles and 6,000 strain cycles, between 2,000 strain cycles and 4,000 strain cycles, between 7,000 strain cycles and 30,000 strain cycles, between 7,000 strain cycles and 20,000 strain cycles, between 7,000 strain cycles and 15,000 strain cycles, between 7,000 strain cycles and 10,000 strain cycles, between 12,000 strain cycles and 30,000 strain cycles, between 12,000 strain cycles and 20,000 strain cycles, between 12,000 strain cycles and 15,000 strain cycles, between 17,000 strain cycles and 30,000 strain cycles, or between 17,000 strain cycles and 20,000 strain cycles.

In some embodiments, the deformable substrate 202 is configured to maintain conductivity through the interior layer 350-1 of the first set of layers 310-1 and/or the interior layer 350-2 of the second set of layers 310-2, including through the channel 210, when subjected to at least 10 cycles, at least 50 cycles, at least 100 cycles, at least 200 cycles, at least 500 cycles, at least 1,000 cycles, at least 2,000 cycles, at least 3,000 cycles, at least 4,000 cycles, at least 5,000 cycles, at least 6,000 cycles, at least 7,000 cycles, at least 8,000 cycles, at least 9,000 cycles, at least 10,000 cycles, at least 11,000 cycles, at least 12,000 cycles, at least 13,000 cycles, at least 14,000 cycles, at least 15,000 cycles, at least 16,000 cycles, at least 17,000 cycles, at least 18,000 cycles, at least 19,000 cycles, at least 20,000 cycles, at least 21,000 cycles, at least 22,000 cycles, at least 23,000 cycles, at least 24,000 cycles, at least 25,000 cycles, at least 26,000 cycles, at least 27,000 cycles, at least 28,000 cycles, at least 29,000 cycles, or at least 30,000 cycles. In some embodiments, the deformable substrate 202 is configured to maintain conductivity through the interior layer 350-1 of the first set of layers 310-1 and/or the interior layer 350-2 of the second set of layers 310-2, including through the channel 210, when subjected to at most 10 cycles, at most 50 cycles, at most 100 cycles, at most 200 cycles, at most 500 cycles, at most 1,000 cycles, at most 2,000 cycles, at most 3,000 cycles, at most 4,000 cycles, at most 5,000 cycles, at most 6,000 cycles, at most 7,000 cycles, at most 8,000 cycles, at most 9,000 cycles, at most 10,000 cycles, at most 11,000 cycles, at most 12,000 cycles, at most 13,000 cycles, at most 14,000 cycles, at most 15,000 cycles, at most 16,000 cycles, at most 17,000 cycles, at most 18,000 cycles, at most 19,000 cycles, at most 20,000 cycles, at most 21,000 cycles, at most 22,000 cycles, at most 23,000 cycles, at most 24,000 cycles, at most 25,000 cycles, at most 26,000 cycles, at most 27,000 cycles, at most 28,000 cycles, at most 29,000 cycles, or at most 30,000 cycles.

In some embodiments, a cycle is completed when the deformable substrate 202 satisfies a threshold strain. In some embodiments, the threshold strain is between 25% and 200%, between 25% and 195%, between 25% and 190%, between 25% and 185%, between 25% and 180%, between 25% and 175%, between 25% and 170%, between 25% and 165%, between 25% and 160%, between 25% and 155%, between 25% and 150%, between 25% and 145%, between 25% and 140%, between 25% and 135%, between 25% and 130%, between 25% and 125%, between 25% and 120%, between 25% and 115%, between 25% and 110%, between 25% and 105%, between 25% and 100%, between 25% and 95%, between 25% and 90%, between 25% and 85%, between 25% and 80%, between 25% and 75%, between 25% and 70%, between 25% and 65%, between 25% and 60%, between 25% and 55%, between 25% and 50%, between 25% and 100%, between 25% and 95%, between 25% and 90%, between 25% and 85%, between 25% and 80%, between 25% and 75%, between 25% and 70%, between 25% and 65%, between 25% and 60%, between 25% and 55%, between 25% and 50%, between 35% and 200%, between 35% and 195%, between 35% and 190%, between 35% and 185%, between 35% and 180%, between 35% and 175%, between 35% and 170%, between 35% and 165%, between 35% and 160%, between 35% and 155%, between 35% and 150%, between 35% and 145%, between 35% and 140%, between 35% and 135%, between 35% and 130%, between 35% and 125%, between 35% and 120%, between 35% and 115%, between 35% and 110%, between 35% and 105%, between 35% and 100%, between 35% and 95%, between 35% and 90%, between 35% and 85%, between 35% and 80%, between 35% and 75%, between 35% and 70%, between 35% and 65%, between 35% and 60%, between 35% and 55%, between 35% and 50%, between 45% and 200%, between 45% and 195%, between 45% and 190%, between 45% and 185%, between 45% and 180%, between 45% and 175%, between 45% and 170%, between 45% and 165%, between 45% and 160%, between 45% and 155%, between 45% and 150%, between 45% and 145%, between 45% and 140%, between 45% and 135%, between 45% and 130%, between 45% and 125%, between 45% and 120%, between 45% and 115%, between 45% and 110%, between 45% and 105%, between 45% and 100%, between 45% and 95%, between 45% and 90%, between 45% and 85%, between 45% and 80%, between 45% and 75%, between 45% and 70%, between 45% and 65%, between 45% and 60%, between 45% and 55%, between 45% and 50%, between 55% and 200%, between 55% and 195%, between 55% and 190%, between 55% and 185%, between 55% and 180%, between 55% and 175%, between 55% and 170%, between 55% and 165%, between 55% and 160%, between 55% and 155%, between 55% and 150%, between 55% and 145%, between 55% and 140%, between 55% and 135%, between 55% and 130%, between 55% and 125%, between 55% and 120%, between 55% and 115%, between 55% and 110%, between 55% and 105%, between 55% and 100%, between 55% and 95%, between 55% and 90%, between 55% and 85%, between 55% and 80%, between 55% and 75%, between 55% and 70%, between 55% and 65%, between 55% and 60%, between 65% and 200%, between 65% and 195%, between 65% and 190%, between 65% and 185%, between 65% and 180%, between 65% and 175%, between 65% and 170%, between 65% and 165%, between 65% and 160%, between 65% and 155%, between 65% and 150%, between 65% and 145%, between 65% and 140%, between 65% and 135%, between 65% and 130%, between 65% and 125%, between 65% and 120%, between 65% and 115%, between 65% and 110%, between 65% and 105%, between 65% and 100%, between 65% and 95%, between 65% and 90%, between 65% and 85%, between 65% and 80%, between 65% and 75%, between 65% and 70%, between 75% and 200%, between 75% and 195%, between 75% and 190%, between 75% and 185%, between 75% and 180%, between 75% and 175%, between 75% and 170%, between 75% and 165%, between 75% and 160%, between 75% and 155%, between 75% and 150%, between 75% and 145%, between 75% and 140%, between 75% and 135%, between 75% and 130%, between 75% and 125%, between 75% and 120%, between 75% and 115%, between 75% and 110%, between 75% and 105%, between 75% and 100%, between 75% and 95%, between 75% and 90%, between 75% and 85%, between 75% and 80%, between 85% and 200%, between 85% and 195%, between 85% and 190%, between 85% and 185%, between 85% and 180%, between 85% and 175%, between 85% and 170%, between 85% and 165%, between 85% and 160%, between 85% and 155%, between 85% and 150%, between 85% and 145%, between 85% and 140%, between 85% and 135%, between 85% and 130%, between 85% and 125%, between 85% and 120%, between 85% and 115%, between 85% and 110%, between 85% and 105%, between 85% and 100%, between 85% and 95%, between 85% and 90%, between 95% and 200%, between 95% and 195%, between 95% and 190%, between 95% and 185%, between 95% and 180%, between 95% and 175%, between 95% and 170%, between 95% and 165%, between 95% and 160%, between 95% and 155%, between 95% and 150%, between 95% and 145%, between 95% and 140%, between 95% and 135%, between 95% and 130%, between 95% and 125%, between 95% and 120%, between 95% and 115%, between 95% and 110%, between 95% and 105%, between 95% and 100%, between 140% and 200%, between 140% and 195%, between 140% and 190%, between 140% and 185%, between 140% and 180%, between 140% and 175%, between 140% and 170%, between 140% and 165%, between 140% and 160%, between 140% and 155%, between 140% and 150%, between 140% and 145%, between 180% and 200%, between 180% and 195%, between 180% and 190%, or between 180% and 185%.

In some embodiments, the threshold strain is at least 25%, at least 30%, at least 35%, at least 40%, at least 45%, at least 50%, at least 55%, at least 60%, at least 65%, at least 70%, at least 75%, at least 80%, at least 85%, at least 90%, at least 95%, at least 99%, or at least 100%, at least 125%, at least 130%, at least 135%, at least 140%, at least 145%, at least 150%, at least 155%, at least 160%, at least 165%, at least 170%, at least 175%, at least 180%, at least 185%, at least 190%, at least 195%, at least 199%, or at least 200%. In some embodiments, the threshold strain is at most 25%, at most 30%, at most 35%, at most 40%, at most 45%, at most 50%, at most 55%, at most 60%, at most 65%, at most 70%, at most 75%, at most 80%, at most 85%, at most 90%, at most 95%, at most 99%, at most 100%, at most 125%, at most 130%, at most 135%, at most 140%, at most 145%, at most 150%, at most 155%, at most 160%, at most 165%, at most 170%, at most 175%, at most 180%, at most 185%, at most 190%, at most 195%, at most 199%, or at most 200%.

Accordingly, the deformable substrate 202 is stretchable when the strain is applied therein, while also maintaining the shape of the channel 210.

In some embodiments, a third thickness of the interior layer 350-1 of the first set of layers 310-1 and/or the interior layer 350-2 of the second set of layers 310-2 (e.g., T3 of FIG. 3B) is between 1 μm and 500 μm, between 1 μm and 450 μm, between 1 μm and 400 μm, between 1 μm and 350 μm, between 1 μm and 300 μm, between 1 μm and 250 μm, between 1 μm and 200 μm, between 1 μm and 150 μm, between 1 μm and 100 μm, between 1 μm and 50 μm, between 1 μm and 10 μm, between 2 μm and 500 μm, between 2 μm and 450 μm, between 2 μm and 400 μm, between 2 μm and 350 μm, between 2 μm and 300 μm, between 2 μm and 250 μm, between 2 μm and 200 μm, between 2 μm and 150 μm, between 2 μm and 100 μm, between 2 μm and 50 μm, between 2 μm and 10 μm, between 3 μm and 500 μm, between 3 μm and 450 μm, between 3 μm and 400 μm, between 3 μm and 350 μm, between 3 μm and 300 μm, between 3 μm and 250 μm, between 3 μm and 200 μm, between 3 μm and 150 μm, between 3 μm and 100 μm, between 3 μm and 50 μm, between 3 μm and 10 μm, between 4 μm and 500 μm, between 4 μm and 450 μm, between 4 μm and 400 μm, between 4 μm and 350 μm, between 4 μm and 300 μm, between 4 μm and 250 μm, between 4 μm and 200 μm, between 4 μm and 150 μm, between 4 μm and 100 μm, between 4 μm and 50 μm, between 4 μm and 10 μm, between 5 μm and 500 μm, between 5 μm and 450 μm, between 5 μm and 400 μm, between 5 μm and 350 μm, between 5 μm and 300 μm, between 5 μm and 250 μm, between 5 μm and 200 μm, between 5 μm and 150 μm, between 5 μm and 100 μm, between 5 μm and 50 μm, between 5 μm and 10 μm, between 6 μm and 500 μm, between 6 μm and 450 μm, between 6 μm and 400 μm, between 6 μm and 350 μm, between 6 μm and 300 μm, between 6 μm and 250 μm, between 6 μm and 200 μm, between 6 μm and 150 μm, between 6 μm and 100 μm, between 6 μm and 50 μm, between 6 μm and 10 μm, between 10 μm and 500 μm, between 10 μm and 450 μm, between 10 μm and 400 μm, between 10 μm and 350 μm, between 10 μm and 300 μm, between 10 μm and 250 μm, between 10 μm and 200 μm, between 10 μm and 150 μm, between 10 μm and 100 μm, between 10 μm and 90 μm, between 10 μm and 50 μm, between 75 μm and 500 μm, between 75 μm and 450 μm, between 75 μm and 400 μm, between 75 μm and 350 μm, between 75 μm and 300 μm, between 75 μm and 250 μm, between 75 μm and 200 μm, between 75 μm and 150 μm, between 75 μm and 100 μm, between 150 μm and 500 μm, between 150 μm and 450 μm, between 150 μm and 400 μm, between 150 μm and 350 μm, between 150 μm and 300 μm, between 150 μm and 250 μm, between 150 μm and 200 μm, between 225 μm and 500 μm, between 225 μm and 450 μm, between 225 μm and 400 μm, between 225 μm and 350 μm, between 225 μm and 300 μm, between 225 μm and 250 μm, between 300 μm and 550 μm, between 300 μm and 500 μm, between 300 μm and 450 μm, between 300 μm and 400 μm, between 300 μm and 350 μm between 375 μm and 500 μm, between 375 μm and 450 μm, between 375 μm and 400 μm, or between 450 μm and 500 μm.

In some embodiments, the thickness T3 of the interior layer 350-1 of the first set of layers 310-1 and/or the interior layer 350-2 of the second set of layers 310-2 changes as a function of length and/or depth of the deformable substrate 202. For instance, in some embodiments, the width of the interior layer 350-1 of the first set of layers 310-1 and/or the interior layer 350-2 of the second set of layers 310-2 is at least 1, 2, 3, 5, 10, 15, 20, or 25 percent larger at one point in the length of the interior layer 350-1 of the first set of layers 310-1 and/or the interior layer 350-2 of the second set of layers 310-2 as it is at a second point in the length of the interior layer 350-1 of the first set of layers 310-1 and/or the interior layer 350-2 of the second set of layers 310-2. In some embodiments, the first point in the length of the interior layer 350-1 of the first set of layers 310-1 and/or the interior layer 350-2 of the second set of layers 310-2 is the first point at which the interior layer 350-1 of the first set of layers 310-1 and/or the interior layer 350-2 of the second set of layers 310-2 has the largest cross-section and the second point is the point at which the interior layer 350-1 of the first set of layers 310-1 and/or the interior layer 350-2 of the second set of layers 310-2 has the smallest cross-section. In some embodiments, the thickness of t the interior layer 350-1 of the first set of layers 310-1 and/or the interior layer 350-2 of the second set of layers 310-2 does not appreciably or measurably change as a function of length and/or depth of the interior layer 350-1 of the first set of layers 310-1 and/or the interior layer 350-2 of the second set of layers 310-2.

In some embodiments, the thickness T3 of the interior layer 350-1 of the first set of layers 310-1 and/or the interior layer 350-2 of the second set of layers 310-2 is at least 1 μm, at least 2 μm, at least 3 μm, at least 4 μm, at least 5 μm, at least 6 μm, at least 10 μm, at least 15 μm, at least 20 μm, at least 25 μm, at least 30 μm, at least 35 μm, at least 40 μm, at least 45 μm, at least 50 μm, at least 55 μm, at least 60 μm, at least 65 μm, at least 70 μm, at least 75 μm, at least 80 μm, at least 85 μm, at least 90 μm, at least 95 μm, at least 100 μm, at least 105 μm, at least 110 μm, at least 115 μm, at least 120 μm, at least 125 μm, at least 130 μm, at least 135 μm, at least 140 μm, at least 145 μm, at least 150 μm, at least 155 μm, at least 160 μm, at least 165 μm, at least 170 μm, at least 175 μm, at least 180 μm, at least 185 μm, at least 190 μm, at least 195 μm, at least 200 μm, at least 205 μm, at least 210 μm, at least 215 μm, at least 220 μm, at least 225 μm, at least 230 μm, at least 235 μm, at least 240 μm, at least 245 μm, at least 250 μm, at least 255 μm, at least 260 μm, at least 265 μm, at least 270 μm, at least 275 μm, at least 280 μm, at least 285 μm, at least 290 μm, at least 295 μm, at least 300 μm, at least 305 μm, at least 310 μm, at least 315 μm, at least 320 μm, at least 325 μm, at least 330 μm, at least 335 μm, at least 340 μm, at least 345 μm, at least 350 μm, at least 355 μm, at least 360 μm, at least 365 μm, at least 370 μm, at least 375 μm, at least 380 μm, at least 385 μm, at least 390 μm, at least 395 μm, at least 400 μm, at least 405 μm, at least 410 μm, at least 415 μm, at least 420 μm, at least 425 μm, at least 430 μm, at least 435 μm, at least 440 μm, at least 445 μm, at least 450 μm, at least 455 μm, at least 460 μm, at least 465 μm, at least 470 μm, at least 475 μm, at least 480 μm, at least 485 μm, at least 490 μm, at least 495 μm, or at least 500 μm.

In some embodiments, the thickness T3 of the thickness of the interior layer 350-1 of the first set of layers 310-1 and/or the interior layer 350-2 of the second set of layers 310-2 is at most 1 μm, at most 2 μm, at most 3 μm, at most 4 μm, at most 5 μm, at most 6 μm, at most 10 μm, at most 15 μm, at most 20 μm, at most 25 μm, at most 30 μm, at most 35 μm, at most 40 μm, at most 45 μm, at most 50 μm, at most 55 μm, at most 60 μm, at most 65 μm, at most 70 μm, at most 75 μm, at most 80 μm, at most 85 μm, at most 90 μm, at most 95 μm, at most 100 μm, at most 105 μm, at most 110 μm, at most 115 μm, at most 120 μm, at most 125 μm, at most 130 μm, at most 135 μm, at most 140 μm, at most 145 μm, at most 150 μm, at most 155 μm, at most 160 μm, at most 165 μm, at most 170 μm, at most 175 μm, at most 180 μm, at most 185 μm, at most 190 μm, at most 195 μm, at most 200 μm, at most 205 μm, at most 210 μm, at most 215 μm, at most 220 μm, at most 225 μm, at most 230 μm, at most 235 μm, at most 240 μm, at most 245 μm, at most 250 μm, at most 255 μm, at most 260 μm, at most 265 μm, at most 270 μm, at most 275 μm, at most 280 μm, at most 285 μm, at most 290 μm, at most 295 μm, at most 300 μm, at most 305 μm, at most 310 μm, at most 315 μm, at most 320 μm, at most 325 μm, at most 330 μm, at most 335 μm, at most 340 μm, at most 345 μm, at most 350 μm, at most 355 μm, at most 360 μm, at most 365 μm, at most 370 μm, at most 375 μm, at most 380 μm, at most 385 μm, at most 390 μm, at most 395 μm, at most 400 μm, at most 405 μm, at most 410 μm, at most 415 μm, at most 420 μm, at most 425 μm, at most 430 μm, at most 435 μm, at most 440 μm, at most 445 μm, at most 450 μm, at most 455 μm, at most 460 μm, at most 465 μm, at most 470 μm, at most 475 μm, at most 480 μm, at most 485 μm, at most 490 μm, at most 495 μm, or at most 500 μm.

In some embodiments, the deformable substrate 202 further includes a plurality of spacers (e.g., first spacer 330-1 of FIG. 3A, second spacer 330-2 of FIG. 3A, . . . , spacer Q 330-Q of FIG. 3A, etc.). In some embodiments, the plurality of spacers 330 is disposed within the channel 210, which allows for the plurality of spacers 330 to occupy the interior volume of the channel 210 together with the medium. For instance, in some embodiments, the plurality of spacers 330 is dispersed within the medium in the channel 210, which prevents collapse of the channel 210 when the deformable substrate 202 is elongated and/or compressed. However, the present disclosure is not limited thereto. For instance, in some embodiments, the plurality of spacers 330 is disposed within the channel 210 such that the plurality of spacers 330 contact the first set of layers 310-1 and the second set of layers 310-2. For instance, referring briefly to FIG. 3A, in some embodiments, the plurality of spacers 330 contact the interior surface of the interior layer 350-1 of the first set of layers 310-1 and the interior surface of the interior layer 350-2 of the second set of layers 310-2. In some such embodiment, by having the plurality of spacers 330 contact the interior surface of the interior layer 350-1 of the first set of layers 310-1 and the interior surface of the interior layer 350-2 of the second set of layers 310-2, the interior of the channel is not closed when the deformable substrate 202 is subjected to strain and/or compressed, which allows for the medium to transfer through the interior layer 350 during deformation of the deformable substrate 202.

In some embodiments, at least one spacer 330 of the plurality of spacers 330 is spherical, substantially spherical, spheroidal, or substantially spheroidal. In some such embodiments, the spherical, substantially spherical, spheroidal, or substantially spheroidal at least one spacer 330 allows for significant deformation (e.g., strain) of the deformable substrate without risk that one or more sharp edges of the at least one spacer 330 punctures either a portion of the first set of layers 310-1 or a portion of the second set of layers 310-2. In some embodiments, the plurality of spacers 330 includes one or more stents. In some embodiments, the plurality of spacers 330 includes one or more protrusions, such as one or more protrusions formed on the interior surface of the interior layer 350 and/or the intermediate layer 340 of a respective set of layers 310 of the deformable substrate 202.

In some embodiments, a fourth thickness of the exterior layer 360-1 of the first set of layers 310-1 or the exterior layer 360-2 of the second set of layers 310-2 (e.g., T4 of FIG. 3B) is between 1 μm and 200 μm. For instance, in some embodiments, the thickness T4 of the exterior layer 360-1 of the first set of layers 310-1 or the exterior layer 360-2 of the second set of layers 360-2 is between 1 μm and 200 μm, between 1 μm and 175 μm, between 1 μm and 150 μm, between 1 μm and 125 μm, between 1 μm and 100 μm, between 1 μm and 75 μm, between 1 μm and 50 μm, between 1 μm and 25 μm, between 5 μm and 200 μm, between 5 μm and 175 μm, between 5 μm and 150 μm, between 5 μm and 125 μm, between 5 μm and 100 μm, between 5 μm and 75 μm, between 5 μm and 50 μm, between 5 μm and 25 μm, between 5 μm and 10 μm, between 10 μm and 200 μm, between 10 μm and 175 μm, between 10 μm and 150 μm, between 10 μm and 125 μm, between 10 μm and 100 μm, between 10 μm and 75 μm, between 10 μm and 50 μm, between 10 μm and 25 μm, between 30 μm and 200 μm, between 30 μm and 175 μm, between 30 μm and 150 μm, between 30 μm and 125 μm, between 30 μm and 100 μm, between 30 μm and 75 μm, between 30 μm and 50 μm, between 50 μm and 200 μm, between 50 μm and 175 μm, between 50 μm and 150 μm, between 50 μm and 125 μm, between 50 μm and 100 μm, between 50 μm and 75 μm, between 70 μm and 200 μm, between 70 μm and 175 μm, between 70 μm and 150 μm, between 70 μm and 125 μm, between 70 μm and 100 μm, between 70 μm and 75 μm, between 90 μm and 200 μm, between 90 μm and 175 μm, between 90 μm and 150 μm, between 90 μm and 125 μm, between 90 μm and 100 μm, between 110 μm and 200 μm, between 110 μm and 175 μm, between 110 μm and 150 μm, between 110 μm and 125 μm, between 130 μm and 200 μm, between 130 μm and 175 μm, between 130 μm and 150 μm, between 150 μm and 200 μm, between 150 μm and 175 μm, between 170 μm and 200 μm, between 170 μm and 175 μm, or between 190 μm and 200 μm.

In some embodiments, the thickness T4 of the exterior layer 360-1 of the first set of layers 310-1 or the exterior layer 360-2 of the second set of layers 360-2 is at least 1 μm, at least 5 μm, at least 10 μm, at least 15 μm, at least 20 μm, at least 25 μm, at least 30 μm, at least 35 μm, at least 40 μm, at least 45 μm, at least 50 μm, at least 55 μm, at least 60 μm, at least 65 μm, at least 70 μm, at least 75 μm, at least 80 μm, at least 85 μm, at least 90 μm, at least 95 μm, at least 100 μm, at least 105 μm, at least 110 μm, at least 115 μm, at least 120 μm, at least 125 μm, at least 130 μm, at least 135 μm, at least 140 μm, at least 145 μm, at least 150 μm, at least 155 μm, at least 160 μm, at least 165 μm, at least 170 μm, at least 175 μm, at least 180 μm, at least 185 μm, at least 190 μm, at least 195 μm, or at least 200 μm.

In some embodiments, the thickness T4 of the exterior layer 360-1 of the first set of layers 310-1 or the exterior layer 360-2 of the second set of layers 360-2 is at most 1 μm, at most 5 μm, at most 10 μm, at most 15 μm, at most 20 μm, at most 25 μm, at most 30 μm, at most 35 μm, at most 40 μm, at most 45 μm, at most 50 μm, at most 55 μm, at most 60 μm, at most 65 μm, at most 70 μm, at most 75 μm, at most 80 μm, at most 85 μm, at most 90 μm, at most 95 μm, at most 100 μm, at most 105 μm, at most 110 μm, at most 115 μm, at most 120 μm, at most 125 μm, at most 130 μm, at most 135 μm, at most 140 μm, at most 145 μm, at most 150 μm, at most 155 μm, at most 160 μm, at most 165 μm, at most 170 μm, at most 175 μm, at most 180 μm, at most 185 μm, at most 190 μm, at most 195 μm, or at most 200 μm.

Furthermore, in some embodiments, the deformable substrate 202 includes a first intermediate layer of the first set of layers 310-1 (e.g., first intermediate layer 340-1 of first set of layers 310-1 of FIG. 3A) that overlays the exterior face of the interior layer 350-1 of the first set of layers 350-1, which provides support for the first interior layer 350-1. Moreover, in some such embodiments, the deformable substrate includes a first intermediate layer of the second set of layers 310-2 (e.g., first intermediate layer 340-2 of first set of layers 310-1 of FIG. 3A) that overlays the exterior face of the interior layer 350-2 of the second set of layers 310-2, which provides support for the second interior layer 350-2.

In some embodiments, the deformable substrate 202 includes an exterior layer of the first set of layers (e.g., exterior layer 360-1 of first set of layers 310-1 of FIG. 3) that overlays the first intermediate layer 340-1 of the first set of layers 310-1. Moreover, in some such embodiment, the deformable substrate 202 includes an exterior layer of the second set of layers (e.g., exterior layer 360-2 of second set of layers 310-2 of FIG. 3A) that overlays the first intermediate layer 340-2 of the second set of layers 310-2.

Moreover, the exterior layer 360-1 of the first set of layers 310-1 and the exterior layer 360-2 of the second set of layers 310-2 each includes a first polymeric composition. By utilizing the first polymeric composition for the exterior layer 360-1 of the first set of layers 310-1 and the exterior layer 360-2 of the second set of layers 310-2, an exterior surface of the deformable substrate 202 is provided with desired thermal stability, flexibility, adhesion properties, or a combination thereof. In some embodiments, the first polymeric composition has a Young's Modulus lower than about 0.1 GPa to provide enhanced flexibility and/or tackability. Examples of materials with low Young's Modulus include, but are not limited to elastomeric materials, viscoelastic polymeric materials, synthetic resins having low sliding performance, high corrosion resistance and high strength, such as silicone, medical grade polyurethane, thermoplastic polyurethane (TPU), polyethylene terephthalate (PET), polyimide (PI), polyphenylene sulfide (PPS) or fluorine-containing resin, polystyrene-block-polyisoprene-block-polystyrene (SIS), or a combination thereof. For instance, in some embodiments, the first polymeric composition of the exterior layer 340-1 of the first set of layers 310-1 and the exterior layer 340-2 of the second set of layers 310-2 includes silicon. Accordingly, the first polymeric material allows for the deformable substrate 202 to elongate and/or compress when a force is applied to the deformable substrate 202 while also maintaining the shape of the channel 210.

Additionally, in some embodiments, the first intermediate layer 340-1 of the first set of layers 310-1 and the first intermediate layer 340-2 of the second set of layers 310-2 each includes a second polymeric composition.

In some embodiments, the second polymeric composition includes a blended resin including: (i) a first siloxane polymer including a plurality of hydride-functional groups and (ii) a second siloxane polymer including a plurality of vinyl-functional groups. Furthermore, in some embodiments, the blended resin includes an hydroperoxide inhibitor that is configured to temporarily inhibit some, but not all, of the plurality of vinyl-functional groups from forming chemical crosslinks with the plurality of hydride-functional groups. Notably, in some embodiments, the hydroperoxide inhibitor is between 0.0001% and 0.5% by weight of the blended resin.

Additional details and information regarding the second polymeric composition is found at U.S. Pat. No. 11,780,966 B2, entitled “Partial-cure Bonding of Silicones through Temporary Inhibition,” filed Jul. 16, 2020, which is hereby incorporated by reference in its entirety for all purposes.

In some embodiments, a fifth thickness of the first intermediate layer 340-1 of the first set of layers 310-1 or the first intermediate layer 340-2 of the second set of layers 310-2 (e.g., T5 of FIG. 3B) is between 1 μm and 2,500 μm.

In some embodiments, the deformable substrate 202 further includes a second intermediate layer (e.g., second intermediate layer 370-1 of first set of layers 310-1 of FIG. 3A) that overlays an opening (e.g., opening 372-1) of the first intermediate layer 340-1 of the first set of layers 310. Moreover, a second intermediate layer of the second set of layers that overlays an opening of the first intermediate layer of the second set of layers.

In some embodiments, the second intermediate layer 370-1 of the first set of layers 310-1 or the second intermediate layer 370-2 of the second set of layers 310-2 includes a liquid metal. For instance, in some embodiments, the composition of the second intermediate layer 370-1 of the first set of layers 310-1 or the second intermediate layer 370-2 of the second set of layers 310-2 includes the liquid metal. In some embodiments, the liquid metal includes a gallium-based (Ga-based) alloy. For instance, in some embodiments, the liquid metal is gallium indium alloy (e.g., eutectic GaIn), gallium tin alloy, gallium indium tin alloy (e.g., Galinstan), gallium indium tin zinc alloy, or any combination thereof. In some embodiments, the gallium in the liquid metal is between about 75 and 95 percent by weight, between about 50 and 75 percent by weight, between about 25 and 50 percent by weight, or less than about 25 percent by weight of the liquid metal. In an embodiment, the gallium-based alloy is Ga75.5In24.5, Ga67In20.5Sn12.5, Ga75.5In24.5, Ga61In25Sn13Zn1, or any combination thereof. Ga75.5In24.5 has a melting point of about 15.5° C., Ga67In20.5Sn12.5 has a melting point of about 10.5° C., and Ga61In25Sn13Zn1 has a melting point of about 7.6° C. Accordingly, by including the liquid metal for the second intermediate layer 370-1 of the first set of layers 310-1 and the second intermediate layer 370-2 of the second set of layers 310-2, the second intermediate layer 370-1 of the first set of layers 310-1 and the second intermediate layer 370-2 of the second set of layers 310-2 are in fluid communication when the coupled together, such as by bonding the first set of layers 310-1 with the second set of layers 310-2. Accordingly, through this fluid communication, the first set of layers 310-1 and the second set of layers 310-2 remain in electronic communication even when the deformable substrate 202 is deformed, such as when subjected to strain or torsion. Moreover, by including liquid metal, the intermediate layer 350 remains in a liquid state at room temperature and/or when utilized (e.g., worn) by a subject.

In some embodiments, the second intermediate layer 340-1 of the first set of layers 310-1 or the second intermediate layer 340-2 of the second set of layers 310-2 includes a metal composite polymer. In some embodiments, the second intermediate layer 340-1 of the first set of layers 310-1 or the second intermediate layer 340-2 of the second set of layers 310-2 includes gallium. In some embodiments, the second intermediate layer 340-1 of the first set of layers 310-1 or the second intermediate layer 340-2 of the second set of layers 310-2 includes gallium indium alloy, gallium tin alloy, gallium indium tin alloy, gallium indium tin zinc alloy, or a combination thereof.

In some embodiments, a sixth thickness of the second intermediate layer 340-1 of the first set of layers 310-1 or the second intermediate layer 340-2 of the second set of layers 310-2 (e.g., T6 of FIG. 3B) is between 1 μm and 5 μm, between 1 μm and 4 μm, between 1 μm and 2 μm, between 1.5 μm and 5 μm, between 1.5 μm and 4 μm, between 1.5 μm and 2 μm, between 2 μm and 5 μm, between 2 μm and 4 μm, between 3 μm and 5 μm, between 3 μm and 4 μm, or between 4 μm and 5 μm. In some embodiments, the sixth thickness T6 of the second intermediate layer 340-1 of the first set of layers 310-1 or the second intermediate layer 340-2 of the second set of layers 310-2 is at least 1 μm, at least 1.2 μm, at least 1.5 μm, at least 1.7 μm, at least 2 μm, at least 2.2 μm, at least 2.5 μm, at least 2.7 μm, at least 3 μm, at least 3.2 μm, at least 3.5 μm, at least 3.7 μm, at least 4 μm, at least 4.2 μm, at least 4.5 μm, at least 4.7 μm, or at least 5 μm. In some embodiments, the sixth thickness T6 of the second intermediate layer 340-1 of the first set of layers 310-1 or the second intermediate layer 340-2 of the second set of layers 310-2 is at most 1 μm, at most 1.2 μm, at most 1.5 μm, at most 1.7 μm, at most 2 μm, at most 2.2 μm, at most 2.5 μm, at most 2.7 μm, at most 3 μm, at most 3.2 μm, at most 3.5 μm, at most 3.7 μm, at most 4 μm, at most 4.2 μm, at most 4.5 μm, at most 4.7 μm, at most 5 μm.

In some embodiments, the deformable substrate 202 includes a third intermediate layer of the first set of layers 310-1 (e.g., third intermediate layer 380-1 of first set of layers 310-1 FIG. 3B, etc.). In some such embodiments, the third intermediate layer 380-1 is disposed interposing between the first intermediate layer 350-1 of the first set of layers 310-1 and at least the exterior layer 360-2 of the first set of layers 310-1. For instance, in some embodiments, the third intermediate 350-1 is formed on an interior face of the exterior layer 360-1 of the first set of layers 310-1 that opposes the exterior face of the interior layer 350-1 of the first set of layers 310-1. However, the present disclosure is not limited thereto. Moreover, a third intermediate layer of the second set of layers 310-2 (e.g., third intermediate layer 380-2 of second set of layers 310-2 FIG. 3B, etc.) is disposed interposing between the first intermediate layer of the second set of layers and at least the exterior layer of the second set of layers. In some such embodiments, the third intermediate layer 380-1 of the first set of layers 310-1 or the third intermediate layer 380-2 of the second set of layers 310-2 includes a first composition that has an affinity for a second composition of the second intermediate layer 370-1 of the first set of layers 310-1 or the second intermediate layer 370-2 of the second set of layers 370-2.

In some embodiments, the first composition is metal. In some embodiments, the metal includes one or more alloys, two or more alloys, three or more alloys, or four or more alloys. In some embodiments, the metal includes at least one alloy, at least two alloys, at least three alloys, at least four alloys, or at least five alloys. In some embodiments, the metal includes at most one alloy, at most two alloys, at most three alloys, at most four alloys, or at most five alloys. For instance, in some embodiments, the first composition includes chromium, chromium alloy, copper, copper alloy, gallium, gallium(III) oxide, gallium indium alloy, gallium tin alloy, gallium indium tin alloy, gallium indium tin zinc alloy, or a combination thereof. Accordingly, by including chromium, the chromium alloy, copper, the copper alloy, gallium, gallium(III) oxide, gallium indium alloy, gallium tin alloy, gallium indium tin alloy, gallium indium tin zinc alloy, or the combination thereof in the first composition, the surface energy of the third intermediate layer 380 is lowered, which allows the third intermediate layer 380 to act as a seed layer (e.g., for forming the second intermediate layer 370)).

In some embodiments, a seventh thickness of the third intermediate layer 380-1 of the first set of layers 310-1 or the third intermediate layer 380-2 of the second set of layers 310-2 (e.g., thickness T7 of FIG. 3B) is between 5 nanometers (nm) and 500 nm, between 1 μm and 450 μm, between 1 μm and 400 μm, between 1 μm and 350 μm, between 1 μm and 300 μm, between 1 μm and 250 μm, between 1 μm and 200 μm, between 1 μm and 150 μm, between 1 μm and 100 μm, between 1 μm and 50 μm, between 1 μm and 10 μm, between 2 μm and 500 μm, between 2 μm and 450 μm, between 2 μm and 400 μm, between 2 μm and 350 μm, between 2 μm and 300 μm, between 2 μm and 250 μm, between 2 μm and 200 μm, between 2 μm and 150 μm, between 2 μm and 100 μm, between 2 μm and 50 μm, between 2 μm and 10 μm, between 3 μm and 500 μm, between 3 μm and 450 μm, between 3 μm and 400 μm, between 3 μm and 350 μm, between 3 μm and 300 μm, between 3 μm and 250 μm, between 3 μm and 200 μm, between 3 μm and 150 μm, between 3 μm and 100 μm, between 3 μm and 50 μm, between 3 μm and 10 μm, between 4 μm and 500 μm, between 4 μm and 450 μm, between 4 μm and 400 μm, between 4 μm and 350 μm, between 4 μm and 300 μm, between 4 μm and 250 μm, between 4 μm and 200 μm, between 4 μm and 150 μm, between 4 μm and 100 μm, between 4 μm and 50 μm, between 4 μm and 10 μm, between 5 μm and 500 μm, between 5 μm and 450 μm, between 5 μm and 400 μm, between 5 μm and 350 μm, between 5 μm and 300 μm, between 5 μm and 250 μm, between 5 μm and 200 μm, between 5 μm and 150 μm, between 5 μm and 100 μm, between 5 μm and 50 μm, between 5 μm and 10 μm, between 6 μm and 500 μm, between 6 μm and 450 μm, between 6 μm and 400 μm, between 6 μm and 350 μm, between 6 μm and 300 μm, between 6 μm and 250 μm, between 6 μm and 200 μm, between 6 μm and 150 μm, between 6 μm and 100 μm, between 6 μm and 50 μm, between 6 μm and 10 μm, between 10 μm and 500 μm, between 10 μm and 450 μm, between 10 μm and 400 μm, between 10 μm and 350 μm, between 10 μm and 300 μm, between 10 μm and 250 μm, between 10 μm and 200 μm, between 10 μm and 150 μm, between 10 μm and 100 μm, between 10 μm and 90 μm, between 10 μm and 50 μm, between 75 μm and 500 μm, between 75 μm and 450 μm, between 75 μm and 400 μm, between 75 μm and 350 μm, between 75 μm and 300 μm, between 75 μm and 250 μm, between 75 μm and 200 μm, between 75 μm and 150 μm, between 75 μm and 100 μm, between 150 μm and 500 μm, between 150 μm and 450 μm, between 150 μm and 400 μm, between 150 μm and 350 μm, between 150 μm and 300 μm, between 150 μm and 250 μm, between 150 μm and 200 μm, between 225 μm and 500 μm, between 225 μm and 450 μm, between 225 μm and 400 μm, between 225 μm and 350 μm, between 225 μm and 300 μm, between 225 μm and 250 μm, between 300 μm and 550 μm, between 300 μm and 500 μm, between 300 μm and 450 μm, between 300 μm and 400 μm, between 300 μm and 350 μm between 375 μm and 500 μm, between 375 μm and 450 μm, between 375 μm and 400 μm, or between 450 μm and 500 μm.

In some embodiments, the width of the interconnect is at least 1 μm, at least 2 μm, at least 3 μm, at least 4 μm, at least 5 μm, at least 6 μm, at least 10 μm, at least 15 μm, at least 20 μm, at least 25 μm, at least 30 μm, at least 35 μm, at least 40 μm, at least 45 μm, at least 50 μm, at least 55 μm, at least 60 μm, at least 65 μm, at least 70 μm, at least 75 μm, at least 80 μm, at least 85 μm, at least 90 μm, at least 95 μm, at least 100 μm, at least 105 μm, at least 110 μm, at least 115 μm, at least 120 μm, at least 125 μm, at least 130 μm, at least 135 μm, at least 140 μm, at least 145 μm, at least 150 μm, at least 155 μm, at least 160 μm, at least 165 μm, at least 170 μm, at least 175 μm, at least 180 μm, at least 185 μm, at least 190 μm, at least 195 μm, at least 200 μm, at least 205 μm, at least 210 μm, at least 215 μm, at least 220 μm, at least 225 μm, at least 230 μm, at least 235 μm, at least 240 μm, at least 245 μm, at least 250 μm, at least 255 μm, at least 260 μm, at least 265 μm, at least 270 μm, at least 275 μm, at least 280 μm, at least 285 μm, at least 290 μm, at least 295 μm, at least 300 μm, at least 305 μm, at least 310 μm, at least 315 μm, at least 320 μm, at least 325 μm, at least 330 μm, at least 335 μm, at least 340 μm, at least 345 μm, at least 350 μm, at least 355 μm, at least 360 μm, at least 365 μm, at least 370 μm, at least 375 μm, at least 380 μm, at least 385 μm, at least 390 μm, at least 395 μm, at least 400 μm, at least 405 μm, at least 410 μm, at least 415 μm, at least 420 μm, at least 425 μm, at least 430 μm, at least 435 μm, at least 440 μm, at least 445 μm, at least 450 μm, at least 455 μm, at least 460 μm, at least 465 μm, at least 470 μm, at least 475 μm, at least 480 μm, at least 485 μm, at least 490 μm, at least 495 μm, or at least 500 μm.

In some embodiments, the thickness T7 of the third intermediate layer 380-1 of the first set of layers 310-1 or the third intermediate layer 380-2 of the second set of layers 310-2 is at most 1 μm, at most 2 μm, at most 3 μm, at most 4 μm, at most 5 μm, at most 6 μm, at most 10 μm, at most 15 μm, at most 20 μm, at most 25 μm, at most 30 μm, at most 35 μm, at most 40 μm, at most 45 μm, at most 50 μm, at most 55 μm, at most 60 μm, at most 65 μm, at most 70 μm, at most 75 μm, at most 80 μm, at most 85 μm, at most 90 μm, at most 95 μm, at most 100 μm, at most 105 μm, at most 110 μm, at most 115 μm, at most 120 μm, at most 125 μm, at most 130 μm, at most 135 μm, at most 140 μm, at most 145 μm, at most 150 μm, at most 155 μm, at most 160 μm, at most 165 μm, at most 170 μm, at most 175 μm, at most 180 μm, at most 185 μm, at most 190 μm, at most 195 μm, at most 200 μm, at most 205 μm, at most 210 μm, at most 215 μm, at most 220 μm, at most 225 μm, at most 230 μm, at most 235 μm, at most 240 μm, at most 245 μm, at most 250 μm, at most 255 μm, at most 260 μm, at most 265 μm, at most 270 μm, at most 275 μm, at most 280 μm, at most 285 μm, at most 290 μm, at most 295 μm, at most 300 μm, at most 305 μm, at most 310 μm, at most 315 μm, at most 320 μm, at most 325 μm, at most 330 μm, at most 335 μm, at most 340 μm, at most 345 μm, at most 350 μm, at most 355 μm, at most 360 μm, at most 365 μm, at most 370 μm, at most 375 μm, at most 380 μm, at most 385 μm, at most 390 μm, at most 395 μm, at most 400 μm, at most 405 μm, at most 410 μm, at most 415 μm, at most 420 μm, at most 425 μm, at most 430 μm, at most 435 μm, at most 440 μm, at most 445 μm, at most 450 μm, at most 455 μm, at most 460 μm, at most 465 μm, at most 470 μm, at most 475 μm, at most 480 μm, at most 485 μm, at most 490 μm, at most 495 μm, or at most 500 μm.

In some embodiments, the third intermediate layer 380-1 of the first set of layers 310-1 includes a shell layer (e.g., shell layer 382 of third intermediate layer 380-2 of second set of layers 310-2 of FIG. 3B, etc.). In some such embodiments, the shell layer 382 includes gallium, gallium(III) oxide, gallium indium alloy, gallium tin alloy, gallium indium tin alloy, gallium indium tin zinc alloy, or a combination thereof. Moreover, the third intermediate layer 380-1 of the first set of layers 310-1 includes a core layer (e.g., core layer 384 of third intermediate layer 380-2 of second set of layers 310-2 of FIG. 3B, etc.). In some such embodiments, the core layer 384 further includes chromium, chromium alloy, copper, copper alloy, or a combination thereof. Furthermore, the third intermediate layer 380-2 of the second set of layers includes a shell layer 382 that further includes gallium, gallium(III) oxide, gallium indium alloy, gallium tin alloy, gallium indium tin alloy, gallium indium tin zinc alloy, or a combination thereof. Moreover, the third intermediate layer 380-2 of the second set of layers 310-2 that further includes a core layer 384 that further includes chromium, chromium alloy, copper, copper alloy, or a combination thereof.

In some embodiments, the third intermediate layer 380 includes chromium or chromium alloy and the thickness T7 of the third intermediate layer 380 is greater than 5 nm, greater than 10 nm, greater than 20 nm, or greater than 50 nm. In some embodiments, the third intermediate layer 380 includes copper or copper alloy and the thickness T7 of the third intermediate layer 380 is greater than 50 nm, greater than 100 nm, greater than 200 nm, or greater than 500 nm.

In some embodiments, an exterior surface of the deformable substrate 202 includes one or more folds, one or more creases, one or more openings, or a combination thereof. For instance, referring briefly to FIG. 3B, in some embodiments, an exterior surface of the exterior layer 360-1 of the first set of layers 310-1, the first intermediate layer 340-1 of the first set of layers 310-1, the exterior layer 360-2 of the second set of layers 310-2, the first intermediate layer 340-2 of the first set of layers 310-2, or a combination thereof includes one or more folds 390 that allow for the deformable substrate to change shapes and compressor and/or stretch when deformed in the Z-direction (e.g., perpendicular or substantially perpendicular to gravity). As a non-limiting example, in some embodiments, the one or more folds, the one or more creases, the one or more openings, or the combination thereof 390 define portions of the deformable substrate 202 that allow for in-plane and out-of-plane deformation, such as the one or more folds of origami or the one or more folds and the one or more openings of kirigami. such as stretchability. Moreover, in some embodiments, the one or more folds, the one or more creases, the one or more openings, or the combination thereof 390 is formed in an array on the exterior layer 360-1 of the first set of layers 310-1, the first intermediate layer 340-1 of the first set of layers 310-1, the exterior layer 360-2 of the second set of layers 310-2, the first intermediate layer 340-2 of the first set of layers 310-2, or the combination thereof, which allows for forming complex two-dimensional or three-dimensional patterns, such as hyperbolic paraboloid (e.g., with negative curvature, positive curvature, or mixed curvature, which allow for flat-folding, forming a saddle shape with negative Gaussian curvature upon non-planar bending, rotatable upon anti-symmetric out-of-plane deformation, or a combination thereof. For instance, in some embodiments, the one or more folds, the one or more creases, the one or more openings, or the combination thereof 390 is formed in a tessellated array, which is a tiling of a plane using one or more geometric shapes, hereinafter “tiles,” with no overlaps or gaps therebetween. For instance, in some implementations the tessellation of a region refers to the tiling of a plane, or surface, which defines the region (e.g., the tessellation of a plane in a two-dimensional polar coordinate system, the tessellation of a surface in a three-dimensional spherical coordinate system, etc.). Additional details and information regarding the use of origami or kirigami to define the one or more folds, the one or more creases, the one or more openings, or the combination thereof is found at Rafsanjani et al., 2017, “Buckling-induced kirigami,” Physical Review Letters, 118(8), pg. 084301; Choi et al., 2019, “Programming shape using kirigami tessellations,” Nature Materials, 18(9), pg. 999-1004, each of which is hereby incorporated by reference in its entirety for all purposes.

Accordingly, in some embodiments, the deformable substrate 202 of the present disclosure allows for thermal management for the electronic device 100 through the use of heat and mass transfer of the medium accommodated by the channel 210 through the interior layers 350 of the first set of layers 310-1 and the second set of layers 310-2. Moreover, in some such embodiments, due to the deformability of the deformable substrate, the thermal management provided therefrom is shape agnostic. Furthermore, in some embodiments, the deformable substrate 202 allows for forming gas barrier films that are operational when the deformable substrate is subjected to strain. Additionally, in some embodiments, the deformable substrate 202 has minimal thickness (e.g., T1, T2, T3, T4, T5, T6, T7, or a combination thereof of FIG. 3B), that allows for the deformable substrate 202 to be incorporated into wearable electronic devices 100, such as gloves, wristbands, eyewear (e.g., glasses, goggles, etc.), and the like. Moreover, in some such embodiments, even with the minimal thickness, the deformable substrate 202 of the present disclosure provides low water vapor transmission rates and oxygen transmission rates to permeation of the medium of the channel 210.

Now that a general topology of the electronic device 100 and the deformable substrate 202 has been described in accordance with various embodiments of the present disclosures, details regarding some processes in accordance with FIG. 6 will be described. Specifically, FIG. 6 illustrates a flow chart of methods (e.g., method 400) for forming a deformable electrical communication, in accordance with embodiments of the present disclosure.

Block 602. Referring to block 602 of FIG. 6, a method 600 for forming a deformable electrical communication between a first circuit component (e.g., circuit component 200-1 of FIG. 2, circuit component 200-2 of FIG. 2, circuit component 200-3 of FIG. 2, circuit component 200-T of FIG. 2, etc.) and a second circuit component (e.g., circuit component 200-1 of FIG. 2, circuit component 200-2 of FIG. 2, circuit component 200-3 of FIG. 2, circuit component 200-T of FIG. 2, etc.) is provided.

Block 604. Referring to block 604, in some embodiments, the method 600 includes forming an exterior layer in a first set of layers (e.g., exterior layer 360-1 of first set of layers 310-1 of FIG. 3A). Accordingly, the exterior layer 360-1 is formed having a first thickness (e.g., thickness T4 of FIG. 3B). In some embodiments, the exterior layer 360 forms a base substrate layer for a respective set of layers 310. For instance, referring briefly to FIG. 4, the exterior layer 360-1 of the first set of layers 310-1 is formed at lower end portion, or base, of the first set of layers 310-1, which allows for the exterior layer 360-1 to support other layers of the first set of layers 310-1 when forming the deformable substrate 202. However, the present disclosure is not limited thereto.

Block 606. Referring to block 606, in some embodiments, the method 600 includes overlaying a first mask over a first portion of the exterior layer 360. By overlaying the exterior layer 360 with the first mask, a first pattern on a first surface of the exterior layer 360 is formed by one or more openings of the first mask. For instance, referring briefly to FIG. 4, in some embodiments, the first pattern is a rectangular pattern, which forms a rectangular opening exposing the first portion of the first surface of the exterior layer 360, such as exposing to an environment or atmosphere.

Block 608. Referring to block 608, in some embodiments, the method 600 includes immersing some or all of the first pattern in a solution. In some embodiments, the solution is an acidic solution. For instance, as a non-limiting example, in some embodiments, the solution includes hydrochloric acid (HCl) (e.g., about 0.5 M HCl). Accordingly, by immersing some or all of the first pattern in the solution, the first surface of the exterior layer 380 has a third intermediate layer of the first set of layers 310-1 (e.g., third intermediate layer 380-1 of FIG. 3A, third intermediate layer 380-2 of FIG. 3A, third intermediate layer 380-2 of FIG. 3B, etc.) on the first surface of the exterior layer 360 in accordance with a shape of the first pattern. For instance, in some embodiments, the solution allows for a metal material of the third intermediate layer 380 to alloy with a second metal material in order to form the second intermediate layer 370 (e.g., the third intermediate layer 380 includes copper, the second metal material includes EGaIn, which forms the second intermediate layer 370 in the form of copper-gallium (CuGa₂)).

Block 610. Referring to block 610, in some embodiments, the method 600 includes further overlaying a second mask over a second portion of the third intermediate layer 380, which forms a second pattern on a second surface of the third intermediate layer 380. In some embodiments, the second pattern is different than the first pattern. In alternative embodiments, the second pattern is the same as the first pattern.

Block 612. Referring to block 612, in some embodiments, the method 600 includes applying a first material to some or all of the second pattern, which forms a second intermediate layer of the first set of layers 310-1 (e.g., second intermediate layer 370-1 of FIG. 3A, second intermediate layer 370-2 of FIG. 3A, etc.) on the second surface of the third intermediate layer 380 in accordance with a shape of the second pattern.

In some embodiments, the applying of the first material includes impinging a plurality of ions of the first material at the second pattern on the second surface of the third intermediate layer 380. Moreover, in some embodiments, the applying of the first material includes forming a coating of the first material over the second pattern on a second surface of the third intermediate layer 380. For instance, in some embodiments, the applying of the first material is performed by one or more mechanical surface modification techniques and/or one or more chemical surface modification techniques, such as by disposing the layer of the first material on the second surface of the third intermediate layer 380. For instance, in some embodiments, the layer of the first material is formed by hydrothermal treatment technique, micro-arc oxidation, plasma ion implantation (PII), plasma spraying, selective melting, sol-gel, sputtering, electrochemical deposition, or a combination thereof. As a non-limiting example, in some embodiments, application of the first material on the second surface of the third intermediate layer 380 includes sputtering by impinging a plurality of ions of the first material on the second surface of the third intermediate layer 380. In some embodiments, the sputtering is performed in a vacuum environment. Accordingly, in some embodiments, by impinging the plurality of ions of the first material on the second surface of the third intermediate layer 380, the thickness T6 of the second intermediate layer 370 is relatively small in comparison to the thickness T2 (e.g., smallest width in cases where a cross-section of the channel is irregular or other than circular, the diameter in cases where a cross-section of the channel is circular) of the channel 210. However, the present disclosure is not limited thereto. As such, in some embodiments, the first material includes liquid metal, such as gallium, which is applied over the surface of the third intermediate layer 380 and/or the second intermediate layer 370, such as in order to coat any pin holes in the third intermediate layer 380 and/or the second intermediate layer 370 and increase the amount of gallium-oxide (Ga₂O₃)

Block 614. Referring to block 614, in some embodiments, the method 600 includes disposing a first intermediate layer 340 of the first set of layers 310-1 on a third portion of the second intermediate layer 370. In some embodiments, the disposing of the first intermediate layer 340 forms a third pattern on a third surface of the second intermediate layer 370. In some embodiments, the third intermediate is bonded to the exterior layer 360 and/or the first intermediate layer 340, such as by SIS—ansiole evaporation based bonding.

Block 616. Referring to block 614, in some embodiments, the method 600 includes further disposing a plurality of spacers (e.g., plurality of spacers 330 of FIG. 3A) on some or all of the third pattern, which forms a portion of the channel 210 between the first circuit component 200-1 and the second circuit component 200-2 for electrical communication between the first circuit component 200-1 and the second circuit component 200-2. Furthermore, in some embodiments, the deformable substrate provides a radio-frequency (RF) shield and/or ground plane to mitigate interference of the electrical communication from other RF sources, such as a third circuit component of the electronic device 100.

### Example 1: Forming a Set of Layers of a Deformable Substrate

Referring to FIG. 4, a first set of layers 310-1 of a deformable substrate 202 configured for use as a vapor chamber was fabricated (e.g., method 600 of FIG. 6). In some embodiments, an exterior layer 360-1 was formed with a thickness T4 between 100 μm and 200 um (e.g., block 604 of FIG. 6). In some embodiments, the exterior layer 360-1 included a first polymeric composition of bluesil that was slot die coated over a 100 mm diameter wafer (e.g., block 604 of FIG. 6). In some embodiments, a dicing tape mask was on a surface of the exterior layer 360-1, such that the mask was applied in a first rectangular pattern of 30 mm wide by 90 mm long, which exposed a portion of the surface of the exterior layer 360-1 (e.g., block 606 of FIG. 6). In some embodiments, a third intermediate layer 380 that included a core layer 384 of chromium with a thickness of about 20 nm and a shell layer 382 of 200 nm Cu that were deposited using electron beam evaporation on the portion of the surface of the exterior layer 380-1. In some embodiments, the first set of layers 310-1 was then dip coated into a EGaIn bath with a 0.5 Mole solution that included hydrochloric acid (e.g., block 608 of FIG. 6). In some embodiments, another mask is applied leaving the EGaIn exposed again (e.g., block 610 of FIG. 6). In some embodiments, 40 passes of EGaIn was airbrushed over the surface of the third intermediate layer 380, which formed a second intermediate layer 370 (e.g., block 612 of FIG. 6). In some embodiments, the first set of layers 310-1 was then plasma treated at 50 Watts for 60 seconds (e.g., block 612 of FIG. 6). In some embodiments, a second polymeric composition (e.g., Bluesil with inhibitor) was then doctor blade coated over a surface of the second intermediate layer 370 to seal a portion of the first set of layers 310-1 (e.g., block 612 of FIG. 6). In some embodiments, about a 3 mm wide edge of the EGaIn is left exposed around the edge during inhibited bluesil capping to act as a seal. In some embodiments, after the inhibited bluesil was left to partially cure until tacky, an interior layer 350 with a thickness T2 of about 500 μm was placed onto the surface partially absorbing into the cap (e.g., block 614 of FIG. 6), in which the interior layer 350 included a wicking composition. In some embodiments, a plurality of spacers, in which each spacer in the plurality of spacers was a glass bead with a diameter of about 500 μm were placed over the interior layer 350 (e.g., block 616 of FIG. 6).

In some embodiments, the method 600 was repeated to produce a second set of layers 310-2. In some embodiments, the first set of layers 310-1 and the second set of layers 310-2 were coupled together using plasma bonding, which formed a channel 210 between the first set of layers 310-1 and the second set of layers 310-2. In some embodiments, the first set of layers 310-1 and the second set of layers 310-2 were coupled together using thermal bonding, gluing, or chemical bonding, which formed the channel 210 between the first set of layers 310-1 and the second set of layers 310-2. In some embodiments, a medium of distilled water was injected into the channel 210 during sealing of the first set of layers 310-1 and the second set of layers 310-2.

### Example 2: A Heat Transfer System within a Deformable Substrate

Referring to FIG. 5, in some embodiments, a deformable substrate 202 was configured as a vapor chamber that facilitated heat management through heat and mass transfer of a bi-phase medium accommodated by the deformable substrate 202. In some embodiments, the deformable substrate included a first set of layers 310-1 and a second set of layers 310-2. In some embodiments, the medium of the channel 210 contacted a heat source of a first electronic component 200-1, which evaporated the medium. The evaporated medium was transported through the channel 210 by way of an interior layer 350 of the first set of layers 310-1 and an interior layer 350 of the second set of layers 310-2, each of which included a wicking material. The evaporated medium was then cooled by the condenser, which removed heat from the medium and produced condensate within the channel 210. Accordingly, the deformable substrate 202 allows for transportation of the medium through the channel 210 that facilitated heat and mass transfer, such as in-plane transfer.

In some embodiments, the condenser was a body of the subject and/or the atmospheric environment.

### EXEMPLARY IMPLEMENTATIONS

Implementation 1. A deformable substrate includes a first set of layers; a second set of layers; a channel encapsulated by the first set of layers and the second set of layers; and a plurality of spacers within channel and contacting the first set of layers and the second set of layers. The channel is bounded by an interior layer of the first set of layers and an interior layer of the second set of layers. The interior layer of the first set of layers and the interior layer of the second set of layers each comprises a wicking composition and each comprises an interior face that faces the channel and an exterior face that opposes the channel. A first intermediate layer of the first set of layers overlays the exterior face of the interior layer of the first set of layers. A first intermediate layer of the second set of layers overlays the exterior face of the interior layer of the second set of layers. An exterior layer of the first set of layers overlays the first intermediate layer of the first set of layers. An exterior layer of the second set of layers overlays the first intermediate layer of the second set of layers. The exterior layer of the first set of layers and the exterior layer of the second set of layers each comprises a first polymeric composition. The first intermediate layer of the first set of layers and the first intermediate layer of the second set of layers each comprises a second polymeric composition.

Implementation 2. The deformable substrate of Implementation 1, in which the channel is configured to accommodate a medium, and wherein the medium is a fluid or a porous solid.

Implementation 3. The deformable substrate of Implementation 2, in which the medium of the channel comprises water.

Implementation 4. The deformable substrate of any preceding Implementation, in which the first set of layers and the second set of layers are coplanar with each other.

Implementation 5. The deformable substrate of any preceding Implementation, in which the porosity of the wicking composition is between 50% and 99%.

Implementation 6. The deformable substrate of any preceding Implementation, in which the first polymeric composition of the exterior layer of the first set of layers and the exterior layer of the second set of layers comprises silicon.

Implementation 7. The deformable substrate of any one of Implementations 1-5, in which the first polymeric composition comprises polydimethylsiloxane silicone (PDMS), polyurethane (PU), thermoplastic polyurethane (TPU), polystyrene-block-polyisoprene-block-polystyrene (SIS), or a combination thereof.

Implementation 8. The deformable substrate of any preceding Implementation, in which the interior layer of the first set of layers and the interior layer of the second set of layers comprises PDMS, polyvinyl alcohol (PVA), polyethylene glycol (PEG), hydroxyethyl methacrylate (HEMA), one or more polymer mesh weaves, one or more non-woven fiber mats, one or more surface modified hydrophobic polymers, polyolefin, one or more surface modified elastomers, or a combination thereof.

Implementation 9. The deformable substrate of any preceding Implementation, in which the interior layer of the first set of layers and the interior layer of the second set of layers comprises a contact angle of less than 50 degrees (°) when interfacing with a different composition.

Implementation 10. The deformable substrate of any preceding Implementation, in which the interior layer of the first set of layers and the interior layer of the second set of layers covers the medium from a first end portion of the channel to a second end portion of the channel.

Implementation 11. The deformable substrate of any preceding Implementation, in which the interior layer of the first set of layers and the interior layer of the second set of layers has a resistance under at most 100 Ohms per cm when the deformable substrate is subjected to 100% strain.

Implementation 12. The deformable substrate of Implementation 11, in which the interior layer of the first set of layers and the interior layer of the second set of layers maintains conductivity when subjected to at least 15,000 strain cycles.

Implementation 13. The deformable substrate of any one of Implementations 1-10, in which the interior layer of the first set of layers and the interior layer of the second set of layers has a resistance under at most 100 Ohms per cm when the deformable substrate is subjected to 100% strain at a first strain cycle, and under at most 100 Ohms per cm when subjected to 100% strain at a second strain cycle.

Implementation 14. The deformable substrate of Implementation 13, in which the second strain cycle is at least 15,000 strain cycles greater than the first strain cycle.

Implementation 15. The deformable substrate of any one of Implementations 11-14, in which the strain is uniaxial or biaxial.

Implementation 16. The deformable substrate of any preceding Implementation, in which a first thickness of the deformable substrate is between 8 microns (μm) and 2,500 μm.

Implementation 17. The deformable substrate of any preceding Implementation, in which a second thickness of the exterior layer of the first set of layers or the exterior layer of the second set of layers is between 1 μm and 200 μm.

Implementation 18. The deformable substrate of any preceding Implementation, in which a third thickness of the first intermediate layer of the first set of layers or the first intermediate layer of the second set of layers is between 1 μm and 2,500 μm.

Implementation 19. The deformable substrate of any preceding Implementation, in which a fourth thickness of the interior layer of the first set of layers and the interior layer of the second set of layers is between 1 μm and 500 μm.

Implementation 20. The deformable substrate of any preceding Implementation, in which the deformable substrate further comprises a second intermediate layer of the first set of layers that overlays an opening of the first intermediate layer of the first set of layers, and a second intermediate layer of the second set of layers that overlays an opening of the first intermediate layer of the second set of layers.

Implementation 21. The deformable substrate of Implementation 20, in which the second intermediate layer of the first set of layers or the second intermediate layer of the second set of layers comprises a liquid metal.

Implementation 22. The deformable substrate according to either of Implementations 20 or 21, in which the second intermediate layer of the first set of layers or the second intermediate layer of the second set of layers comprises a metal composite polymer.

Implementation 23. The deformable substrate according to any one of Implementations 20-22, in which the second intermediate layer of the first set of layers or the second intermediate layer of the second set of layers comprises gallium.

Implementation 24. The deformable substrate of Implementation 23, in which the second intermediate layer of the first set of layers or the second intermediate layer of the second set of layers comprises gallium indium alloy, gallium tin alloy, gallium indium tin alloy, gallium indium tin zinc alloy, or a combination thereof.

Implementation 25. The deformable substrate according to any one of Implementations 20-24, in which a fifth thickness of the second intermediate layer of the first set of layers or the second intermediate layer of the second set of layers is between 1 μm and 5 μm.

Implementation 26. The deformable substrate according to any one of Implementations 20-25, in which the deformable substrate comprises a third intermediate layer of the first set of layers disposed interposing between the first intermediate layer of the first set of layers and at least the exterior layer of the first set of layers, a third intermediate layer of the second set of layers disposed interposing between the first intermediate layer of the second set of layers and at least the exterior layer of the second set of layers, and wherein the third intermediate layer of the first set of layers or the third intermediate layer of the second set of layers comprises a first composition having an affinity for a second composition of the second intermediate layer of the first set of layers or the second intermediate layer of the second set of layers.

Implementation 27. The deformable substrate of Implementation 26, in which the first composition is a metal.

Implementation 28. The deformable substrate according to either of Implementations 26 or 27, in which the first composition comprises chromium, a chromium alloy, copper, a copper alloy, gallium, gallium(III) oxide, gallium indium alloy, gallium tin alloy, gallium indium tin alloy, gallium indium tin zinc alloy, or a combination thereof.

Implementation 29. The deformable substrate according to any one of Implementations 26-28, in which a sixth thickness of the third intermediate layer of the first set of layers or the third intermediate layer of the second set of layers is between 5 nanometers (nm) and 500 nm.

Implementation 30. The deformable substrate of any preceding Implementation, in which a seventh thickness of the channel is between 100 μm and 1,000 μm.

Implementation 31. The deformable substrate according to any one of Implementations 26-30, in which the third intermediate layer of the first set of layers comprises a shell layer comprising gallium, gallium(III) oxide, gallium indium alloy, gallium tin alloy, gallium indium tin alloy, gallium indium tin zinc alloy, or a combination thereof, and a core layer comprising chromium, chromium alloy, copper, copper alloy, or a combination thereof, and the third intermediate layer of the second set of layers comprises a shell layer comprising gallium, gallium(III) oxide, gallium indium alloy, gallium tin alloy, gallium indium tin alloy, gallium indium tin zinc alloy, or a combination thereof, and a core layer comprising chromium, chromium alloy, copper, copper alloy, or a combination thereof.

Implementation 32. The deformable substrate of any preceding Implementation, in which at least one spacer of the plurality of spacers is spherical, substantially spherical, spheroidal, or substantially spheroidal.

Implementation 33. The deformable substrate of any preceding Implementation, in which the plurality of spacers comprises one or more stents.

Implementation 34. The deformable substrate of any preceding Implementation, in which the plurality of spacers comprises one or more protrusions.

Implementation 35. The deformable substrate of any preceding Implementation, in which the exterior surface of the deformable substrate comprises one or more folds, one or more creases, one or more openings, or a combination thereof.

Implementation 36. A method for forming a deformable electrical communication between a first and second circuit component, the method comprising: forming an exterior layer in a first set of layers comprising a first thickness; overlaying a first mask over a first portion of the exterior layer, thereby forming a first pattern on a first surface of the exterior layer; immersing some or all of the first pattern in a solution, thereby forming a first intermediate layer of the first set of layers on the first surface of the exterior layer in accordance with a shape of the first pattern; further overlaying a second mask over a second portion of the first intermediate layer, thereby forming a second pattern on a second surface of the first intermediate layer; applying a first material to some or all of the second pattern, thereby forming a second intermediate layer of the first set of layers on the second surface of the first intermediate layer in accordance with a shape of the second pattern; disposing a third intermediate layer of the first set of layers on a third portion of the second intermediate layer, thereby forming a third pattern on a third surface of the second intermediate layer; and further disposing a plurality of spacers on some or all of the third pattern, thereby forming a portion of a channel between the first circuit component and the second circuit component for electrical communication between the first circuit component and the second circuit component.

Implementation 37. The method of Implementation 36, in which the applying of the first material comprises impinging a plurality of ions of the first material at the second pattern on the second surface of the first intermediate layer.

Implementation 37. The method of Implementation 36, in which the applying of the first material comprises forming a coating of the first material over the second pattern on the second surface of the first intermediate layer.

Implementation 38. A stretchable and soft multilayer structures for making a flexible and stretchable vapor chamber and one or more heat pipes that encompass porous structures (e.g., interior layer 350), gas barrier films (e.g., first set of layers 310-1 and second set of layers 310-2), stretchable substrates, open internal cavity (e.g., channel 210), and a working liquid (e.g., medium).

Implementation 39. The structure of Implementation 38, in which the porous structure is made out of PDMS, hydrophilic polymers such as (crosslinked) polyvinyl alcohol (PVA), polyethylene glycol (PEG), hydroxyethyl methacrylate (HEMA), polymer mesh weave, non-woven fiber mat, surface modified hydrophobic polymer such as polyolefins, or surface modified elastomers.

Implementation 40. The structure of either of Implementations 38-39, in which the porous structure has a contact angle of less than 50 degrees.

Implementation 41. The structure of any one of Implementations 38-40, in which the porous structure transports the working fluid from the condenser (e.g., first circuit component, body of subject, environment, etc.) to the evaporator (e.g., second circuit component) using capillary action.

Implementation 42. The structure of any one of Implementations 38-41, in which the porous structure is stretched under uniaxial or by biaxial deformation to strains greater than 1%, greater than 2%, greater than 5%, greater than 10%, greater than 50%, or greater than 100%.

Implementation 43. The structure of any one of Implementations 38-42, in which the stretchability is provided through structures such as folds, creases, and cuts with a kirigami pattern.

Implementation 44. The structure of any one of Implementations 38-43, in which the porosity of the porous structure is greater than 50%, 80%, or 95%.

Implementation 45. The structure of any one of Implementations 38-44, in which the porous structure has a thickness greater than 1 um, greater than 5 um, greater than 30 um, greater than 100 μm, or greater than 500 um.

Implementation 46. The structure of any one of Implementations 38-45, in which a gas barrier film structure (e.g., set of layers 310) includes a PDMS, PU, TPU, or SIS first substrate base layer (e.g., exterior layer 360), a thermally evaporated or sputtered chromium and copper seed layer (e.g., third intermediate layer 380), a dip coated liquid metal layer (e.g., second intermediate layer 370), an airbrushed liquid metal layer (e.g., second intermediate layer 370), or combination of thereof, a second exterior layer 360 that includes a PDMS, PU, TPU, or SIS second substrate to couple with the first substrate.

Implementation 47. The structure of any one of Implementations 38-46, in which the elastomer substrate (e.g., exterior layer 360 and/or first intermediate layer 340) in the gas barrier film includes PDMS, PU, TPU, or SIS.

Implementation 48. The structure of any one of Implementations 38-47, in which the substrate base layer (e.g., exterior layer 360) is slot die coated, stencil printed, or screen printed.

Implementation 49. The structure of any one of Implementations 38-48, in which the thickness of the substrate base layer (e.g., exterior layer 360) is greater than 1 um, greater than 10 um, greater than 100 μm, or greater than 200 um.

Implementation 50. The structure of any one of Implementations 38-49, in which the chromium seed layer (e.g., third intermediate layer 380, core layer 384 of FIG. 3B) is greater than 5 nm, greater than 10 nm, greater than 20 nm, or greater than 50 nm.

Implementation 51. The structure of any one of Implementations 38-50, in which the copper seed layer (e.g., third intermediate layer 380, shell layer 382 of FIG. 3B) is greater than 50 nm, greater than 100 nm, greater than 200 nm, or greater than 500 nm.

Implementation 52. The structure of any one of Implementations 38-51, in which the seeded film is dip coated into a solution of liquid metal (e.g., EGaIn) with a greater than 0.5 M HCl surface layer until the liquid metal has alloyed with the Cu layer to form a CuGa2 layer coated with EGaIn.

Implementation 53. The structure of any one of Implementations 38-52, in which liquid metal is airbrushed over the surface of the substrate base layer, the chromium seed layer, the copper seed layer, the coated seeded film layer, or a combination thereof in order to coat any pinholes and increase percent of Ga₂O₃.

Implementation 54. The structure of any one of Implementations 38-53, in which the entire active thickness of the substrate base layer, the chromium seed layer, the copper seed layer, the coated seeded film layer, or a combination thereof is less than 15 um.

Implementation 55. The structure of any one of Implementations 38-54, in which the gas barrier film cap layer (e.g., second set of layers 310-2) is made from the same Implementation as the base substrate layer, and is coated over the base substrate layer to seal the gas barrier film (e.g., deformable substrate 202).

Implementation 56. The structure of any one of Implementations 38-55, in which the gas barrier film layer (e.g., second set of layers 310-2) is bonded to the base substrate layer through plasma treatment, thermal bonding, gluing, chemical bonding, or a combination thereof.

Implementation 57. The structure of any one of Implementations 38-56, in which the deformable substrate is a vapor chamber or heat pipe made of two liquid metal based set of layers that includes porous wicking layers, glass bead spacers, and encapsulated in an elastomer.

Implementation 58. The structure of any one of Implementations 38-57, in which the wicking layers are bonded to the intermediate layer of the gas barrier film layer (e.g., set of layers 310) by SIS-ansiole evaporation based bonding.

Implementation 59. The structure of any one of Implementations 38-58, in which the SIS-Anisole solution is stencil printed over the plasma treated PDMS substrate and left to evaporate for 20 minutes.

Implementation 60. The structure of any one of Implementations 38-59, in which the wicking material is laid on top of the evaporating SIS-Anisole solution or tacky inhibited PDMS to partially absorb into the wicking structure and bond to the PDMS substrate.

Implementation 61. The structure of any one of Implementations 38-60, in which a plurality of 500 um glass spacing beads (e.g., spacers 330 of FIG. 3B) is disposed between the wicking layers to allow water vapor transport through the channel.

Implementation 62. The structure of any one of Implementations 38-61, in which plasma bonding is used to seal the set of layers together.

Implementation 63. The structure of any one of Implementations 38-62, in which water vapor is injected by syringe during the sealing.

Implementation 63. The structure of any one of Implementations 38-63, in which the channel is held open by the plurality of spacers, and wherein the plurality of spacers includes one or more spacing beads, one or more micropillars, or one or more stents.

Implementation 64. The structure of any one of Implementations 38-64, in which the channel thickness is greater than 100 um, greater than 200 um, greater than 300 μm, or greater than 500 um.

Implementation 69. The structure of any one of Implementations 38-65, in which the liquid metal based gas barrier film also acts an RF shield and ground plane to mitigate interference from other electronic RF sources.

### CONCLUSION

It is understood that the examples and embodiments described herein are for illustrative purposes only and that various modifications or changes in light thereof will be suggested to persons skilled in the art and are to be included within the spirit and purview of this application and scope of the appended claims. All publications, patents, and patent applications cited herein are hereby incorporated by reference in their entirety for all purposes.

What is claimed is:

1. A deformable substrate comprising:
a first set of layers;
a second set of layers;
a channel encapsulated by the first set of layers and the second set of layers; and
a plurality of spacers within channel and contacting the first set of layers and the second set of layers, wherein
the channel is bounded by an interior layer of the first set of layers and an interior layer of the second set of layers,
the interior layer of the first set of layers and the interior layer of the second set of layers each comprises a wicking composition and each comprises an interior face that faces the channel and an exterior face that opposes the channel,
a first intermediate layer of the first set of layers overlays the exterior face of the interior layer of the first set of layers,
a first intermediate layer of the second set of layers overlays the exterior face of the interior layer of the second set of layers,
an exterior layer of the first set of layers overlays the first intermediate layer of the first set of layers,
an exterior layer of the second set of layers overlays the first intermediate layer of the second set of layers,
the exterior layer of the first set of layers and the exterior layer of the second set of layers each comprises a first polymeric composition, and
the first intermediate layer of the first set of layers and the first intermediate layer of the second set of layers each comprises a second polymeric composition.

2. The deformable substrate of claim 1, wherein the porosity of the wicking composition is between 50% and 99%.

3. The deformable substrate of claim 1, wherein the first polymeric composition comprises polydimethylsiloxane silicone (PDMS), polyurethane (PU), thermoplastic polyurethane (TPU), polystyrene-block-polyisoprene-block-polystyrene (SIS), or a combination thereof.

4. The deformable substrate of claim 1, wherein the interior layer of the first set of layers and the interior layer of the second set of layers comprises PDMS, polyvinyl alcohol (PVA), polyethylene glycol (PEG), hydroxyethyl methacrylate (HEMA), one or more polymer mesh weaves, one or more non-woven fiber mats, one or more surface modified hydrophobic polymers, polyolefin, one or more surface modified elastomers, or a combination thereof.

5. The deformable substrate of claim 1, wherein the interior layer of the first set of layers and the interior layer of the second set of layers comprises a contact angle of less than 50 degrees (°) when interfacing with a different composition.

6. The deformable substrate of claim 1, wherein the interior layer of the first set of layers and the interior layer of the second set of layers covers the medium from a first end portion of the channel to a second end portion of the channel.

7. The deformable substrate of claim 1, wherein the interior layer of the first set of layers and the interior layer of the second set of layers has a resistance under at most 100 Ohms per cm when the deformable substrate is subjected to 100% strain, and wherein the interior layer of the first set of layers and the interior layer of the second set of layers maintains conductivity when subjected to at least 15,000 strain cycles.

8. The deformable substrate of claim 1, wherein the interior layer of the first set of layers and the interior layer of the second set of layers has a resistance under at most 100 Ohms per cm when the deformable substrate is subjected to 100% strain at a first strain cycle, and under at most 100 Ohms per cm when subjected to 100% strain at a second strain cycle, and the second strain cycle is at least 15,000 strain cycles greater than the first strain cycle.

9. The deformable substrate of claim 1, wherein a first thickness of the deformable substrate is between 8 microns (μm) and 2,500 μm.

10. The deformable substrate of claim 1, wherein a second thickness of the exterior layer of the first set of layers or the exterior layer of the second set of layers is between 1 μm and 200 μm.

11. The deformable substrate of claim 1, wherein a third thickness of the first intermediate layer of the first set of layers or the first intermediate layer of the second set of layers is between 1 μm and 2,500 μm.

12. The deformable substrate of claim 1, wherein a fourth thickness of the interior layer of the first set of layers and the interior layer of the second set of layers is between 1 μm and 500 μm.

13. The deformable substrate of claim 1, wherein the deformable substrate further comprises:
a second intermediate layer of the first set of layers that overlays an opening of the first intermediate layer of the first set of layers, and
a second intermediate layer of the second set of layers that overlays an opening of the first intermediate layer of the second set of layers.

14. The deformable substrate of claim 13, wherein the second intermediate layer of the first set of layers or the second intermediate layer of the second set of layers comprises gallium indium alloy, gallium tin alloy, gallium indium tin alloy, gallium indium tin zinc alloy, or a combination thereof.

15. The deformable substrate of claim 13, wherein a fifth thickness of the second intermediate layer of the first set of layers or the second intermediate layer of the second set of layers is between 1 μm and 5 μm.

16. The deformable substrate of claim 13, wherein the deformable substrate comprises:
a third intermediate layer of the first set of layers disposed interposing between the first intermediate layer of the first set of layers and at least the exterior layer of the first set of layers,
a third intermediate layer of the second set of layers disposed interposing between the first intermediate layer of the second set of layers and at least the exterior layer of the second set of layers, and
wherein the third intermediate layer of the first set of layers or the third intermediate layer of the second set of layers comprises a first composition having an affinity for a second composition of the second intermediate layer of the first set of layers or the second intermediate layer of the second set of layers.

17. The deformable substrate of claim 16, wherein a sixth thickness of the third intermediate layer of the first set of layers or the third intermediate layer of the second set of layers is between 5 nanometers (nm) and 500 nm.

18. The deformable substrate of claim 16, wherein
the third intermediate layer of the first set of layers comprises:
a shell layer comprising gallium, gallium(III) oxide, gallium indium alloy, gallium tin alloy, gallium indium tin alloy, gallium indium tin zinc alloy, or a combination thereof, and
a core layer comprising chromium, a chromium alloy, copper, a copper alloy, or a combination thereof, and
the third intermediate layer of the second set of layers comprises:
a shell layer comprising gallium, gallium(III) oxide, gallium indium alloy, gallium tin alloy, gallium indium tin alloy, gallium indium tin zinc alloy, or a combination thereof, and
a core layer comprising chromium, a chromium alloy, copper, a copper alloy, or a combination thereof.

19. The deformable substrate of claim 1, wherein the plurality of spacers comprises one or more stents.

20. The deformable substrate of claim 1, wherein an exterior surface of the deformable substrate comprises one or more folds, one or more creases, one or more openings, or a combination thereof.
